(19) United States
(12) Patent Application Publication
(10) Pub. No.: US 2016/0077142 A1
(43) Pub. Date: Mar. 17, 2016

(54) POWER ELECTRONICS DEVICE

(71) Applicant: KABUSHIKI KAISHA TOSHIBA, Tokyo (JP)

(72) Inventors: Fumiaki KANAYAMA, Kawasaki (JP); Yuusuke KOUNO, Tokyo (JP); Yasuyuki NISHIBAYASHI, Kawasaki (JP)

(21) Appl. No.: 14/853,148

(22) Filed: Sep. 14, 2015

(30) Foreign Application Priority Data
Sep. 16, 2014 (JP) 2014-188228

(51) Int. Cl. G01R 31/02; G01R 21/00

(52) U.S. Cl. CPC G01R 31/02; G01R 21/00

(57) ABSTRACT

According to one embodiment, a power electronics device has an output connected to an output of a different power electronics device by a power line. The power electronics device includes a detector to detect, from the power line or a space around the power electronics device, an electric power that the different power electronics device superimposes onto an output power, or at least one of an electric power, a sound, and an electromagnetic wave, each having a frequency of a carrier wave that the different power electronics device uses for power conversion. The power electronics device includes a determiner to determine a state of the different power electronics device based on a detection signal obtained through detection performed by the detector.

### CROSS-REFERENCE TO RELATED APPLICATIONS

This application is based upon and claims the benefit of priority from Japanese Patent Application No. 2014-188228, filed Sep. 16, 2014; the entire contents of which are incorporated herein by reference.

### FIELD

Embodiments described herein relate to a power electronics device.

### BACKGROUND

Dispersed power sources that connect photovoltaic generators or energy storages to electric power systems have been utilized. In a dispersed power supply system using these dispersed power sources, a plurality of power electronics devices take charge of a portion of required electric power output, enabling the supply of the electric power required to the electric power system. In such a dispersed power supply system, the power electronics devices need to recognize the action statuses of the other devices mutually and in real time.

To continue to supply a constant electric power to an electric power system even if one of a plurality of power electronics devices in a group stops, it is needed to change the shares of electric powers output by the respective power electronics devices in the group. For this reason, a mechanism to detect a stopping power electronics device is needed. In regard to this, it is conceivable, for example, to make power electronics devices have a communicating function to introduce a mechanism such as UPnP (Universal Plug and Play), which allows the power electronics devices to automatically detect the stop of the other power electronics device.

However, a UPnP-based method involves a problem in that a certain time is taken to detect the stop especially when a device suddenly stops. More specifically, a first power electronics device in a group takes a time about the length of a transmission interval of keep-alive announcement messages to detect the stop of a second power electronics device in the group, and an actual operation needs a time more than this, taking a dropped packet or a retransmission time period into account.

In contrast, the first power electronics device can increase the speed of detecting a stop by increasing a transmission frequency of the keep-alive announcement messages, but in this case, excessive loads are imposed on communications equipment during a normal period, which is undesirable. In particular, an increased number of power electronics devices forming a group explosively increase the amount of keep-alive announcement messages, which may disturb other communication.

### BRIEF DESCRIPTION OF THE DRAWINGS

FIG. 1 is a diagram showing the configuration of a power electronics system 1 in a first embodiment;

FIG. 2 is a diagram for illustrating an example of frequency assignment of high frequencies;

FIG. 3 is a diagram showing an example in which unavailable frequency bands are provided between blocks;

FIG. 4 is a diagram showing the configuration of a power electronics device 11 in the first embodiment;

FIG. 5 is a diagram showing the configuration of a controller 117 in the first embodiment;

FIG. 6 is a diagram showing a configuration example in the case of superimposing electric powers using capacitors that are separately provided at the output end of the power electronics device 11;

FIG. 7 is a diagram showing a configuration example in the case of superimposing electric powers using transformers that are separately provided at the output end of the power electronics device 11;

FIG. 8 is a circuit diagram in a configuration example of a detector 113 in the first embodiment;

FIG. 9 is a diagram showing an example of the flow in execution processing of initialization in the first embodiment;

FIG. 10 is a diagram showing the configuration of a power electronics system 2 in a second embodiment;

FIG. 11 is a diagram showing the configuration of a power electronics device 12 in the second embodiment;

FIG. 12 is a vector diagram of the voltages of superimposed powers output from power electronics devices 12a to 12c;

FIG. 13 is a diagram showing the configuration of a power electronics system 2b in a first modification of the second embodiment;

FIG. 14 is a vector diagram showing a first example of the voltages of superimposed powers output from power electronics devices 12a to 12d in the first modification of the second embodiment;

FIG. 15 is a vector diagram showing a second example of the voltages of superimposed powers output from the power electronics devices 12a to 12d in the first modification of the second embodiment;

FIG. 16 is a diagram into which the vector diagram of FIG. 15 is redrawn, where the superimposed power vectors of respective power electronics devices are connected;

FIG. 17 is a diagram into which the vector diagram of FIG. 14 is redrawn, where the superimposed power vectors of respective power electronics devices are connected;

FIG. 18 is a diagram showing an example of assigning the phases of superimposed powers at two frequencies f21 and f22;

FIG. 19 is a vector diagram showing an example of the voltages of superimposed powers output from the power electronics devices 12a to 12d at a plurality of frequencies;

FIG. 20 is a table showing the work/stop statuses of the four power electronics devices 12a to 12d and the cancelling statuses of frequencies of the corresponding respective superimposed powers;

FIG. 21 is a diagram showing the configuration of a power electronics system 2c in a second modification of the second embodiment;

FIG. 22 is a diagram showing the configuration of a power electronics device 121 in the second modification of the second embodiment;

FIG. 23 is a diagram showing the configuration of a controller 1173 in the second modification of the second embodiment;

FIG. 24 is a diagram showing the configuration of a power electronics system 3 in a third embodiment;

FIG. 25 is a diagram showing the configuration of a power electronics device 13 in the third embodiment;

FIG. 26 shows an example of time-sharing blocks;

FIG. 27 is a diagram showing an example of the frequency transition of superimposed powers in the case where the time-sharing assignment of frequency is combined with frequency hopping;

FIG. 28 is a diagram showing an example of assigning the phases of superimposed powers to respective power electronics devices by time-sharing;

FIG. 29 is a diagram showing the configuration of a power electronics system 4 in a fourth embodiment;

FIG. 30 is a diagram showing the configuration of a power electronics device 14 in the fourth embodiment;

FIG. 31 is a diagram showing the configuration of a power electronics system 5 in a fifth embodiment;

FIG. 32 is a diagram showing the configuration of a power electronics device 15 in the fifth embodiment;

FIG. 33 is a diagram showing the configuration of a power electronics system 6 in a sixth embodiment;

FIG. 34 is a diagram showing the configuration of a power electronics device 16 in the sixth embodiment;

FIG. 35 is a diagram showing the configuration of a power electronics device 161 in a modification of the sixth embodiment;

FIG. 36 is a diagram showing the configuration of a power electronics system 7 in a seventh embodiment;

FIG. 37 is a diagram for illustrating the arrangement of power electronics devices 17a to 17c and the composition of sounds output from the power electronics devices 17a and 17b;

FIG. 38 is a diagram showing the configuration of a power electronics device 17c in the seventh embodiment;

FIG. 39 is a diagram showing the configuration of a power electronics device 171c in a modification of the seventh embodiment;

FIG. 40 is a diagram showing the configuration of a power electronics system 8 in an eighth embodiment;

FIG. 41 is a diagram showing the configuration of a power electronics device 18 in the eighth embodiment;

FIG. 42 is a diagram showing the configuration of a power electronics system 9 in a ninth embodiment;

FIG. 43 is a diagram showing the configuration of a power electronics device 19c in the ninth embodiment;

FIG. 44 is a diagram showing a configuration example of a micro grid; and

FIG. 45 is a diagram showing a configuration example of a dispersed power supply plant.

### DETAILED DESCRIPTION

According to one embodiment, a power electronics device has an output connected to an output of a different power electronics device by a power line.

The power electronics device includes a detector to detect, from the power line or a space around the power electronics device, an electric power that the different power electronics device superimposes onto an output power. Or, the detector detects at least one of an electric power, a sound, and an electromagnetic wave, each having a frequency of a carrier wave that the different power electronics device uses for power conversion.

The power electronics device includes a determiner to determine a state of the different power electronics device based on a detection signal obtained through detection performed by the detector.

Below, embodiments will be described with reference to the drawings. In a power electronics system in each embodiment, power electronics devices each have a communicating function by which the plurality of devices operate while exchanging information with one another.

The power electronics device in each embodiment is a device such as an inverter, converter, transformer, which converts DC/AC, voltage, current, frequency, the number of phases, and the like, while consuming no or very little electric power in the device itself. Inverters are devices each of which typically converts a DC power supply into an AC power supply, and some inverters have a function of converting an AC power supply into a DC power supply by switching an operation mode. In addition, the power electronics devices also include devices such as circuit breakers and power routers which break or alter power transmission routes. A local system may include a plurality of power electronics devices present therein, and these power electronics devices can control their outputs under instructions from an EMS (Energy Management System) or a central control device, or through cooperative actions among the power electronics devices. Not only the power electronics devices, but also various devices such as generators to be exemplified below can join this cooperative action. In addition, the power electronics devices also include a PCS (Power Conditioning System) each of which includes a power electronics element and a controller integrated therein. The control facility of a PCS may have a communicating function.

In each embodiment, a power electronics device is connected to at least one or more power lines at the input and output of electric power. Furthermore, the power line is formed by a plurality of wires, and the number of wires depends on the number of phases handled by the power electronics device. The number of core wires is often two in direct current or single-phase alternating current, but some power lines have a ground wire besides them, which serves as both a shield and a ground in some cases. The same is true for a three or more phase power line, which includes basically wires of the number of phases and may include a ground wire. Additionally, in a power distribution network, a power line may include a communication line/signal line such as an optical fiber. Each embodiment will be described below assuming that, as an example, a power line is of a three-phase three-wire system, and the number of wires in a power line is three.

### First Embodiment

### Superimposed Power/Frequency Assignment Scheme

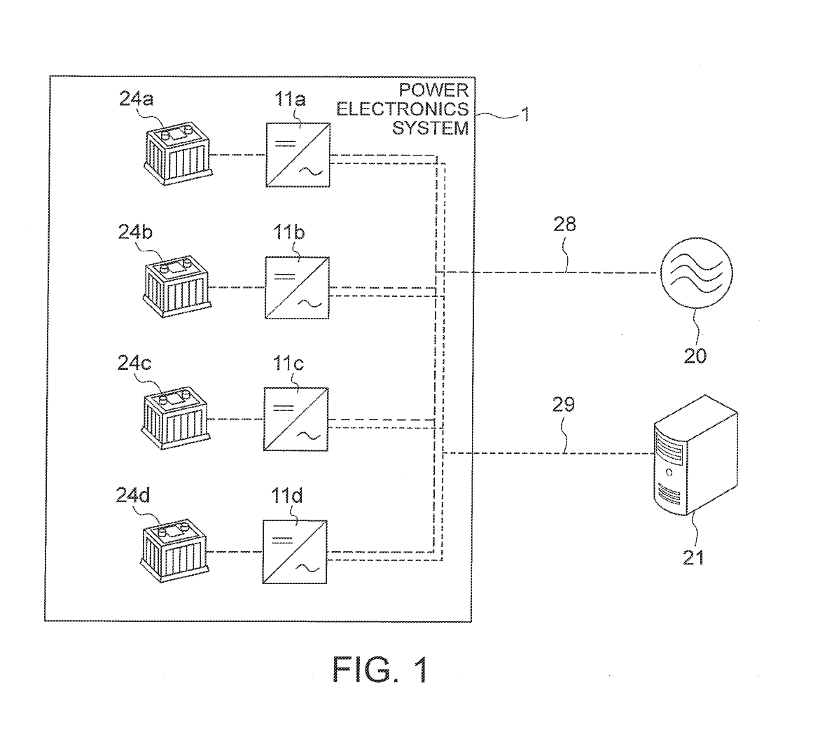

The configuration of a power electronics system 1 in a first embodiment will be described with reference to FIG. 1.

FIG. 1 is a diagram showing the configuration of the power electronics system 1 in the first embodiment. As shown in FIG. 1, the power electronics system 1 includes energy storage devices 24a, 24b, 24c, and 24d and power electronics devices 11a, 11b, 11c, and 11d.

The energy storage devices 24a to 24d are devices for storing electrical energy after converting into the other energy forms, and typically refer to batteries. The energy storage devices can include battery and electric vehicles (EVs) having battery installed therein and can include dry cells, which are supposed to only discharge electricity once manufactured. An energy storage device may include a control system configured by transforming components such as a microprocessor, regulator, and inverter that are installed therein for the management of a charging/discharging speed, battery deterioration, and a lifetime, and an energy storage device including a PCS and an energy storage integrated therein may be called a BESS (Battery Energy Storage System). A PCS may come with not only energy storages, but also photovoltaic generators or other small generators. The energy storage devices include water towers that can be considered to conserve electrical energy in the form of potential energy, and flywheels that can extract electric power from accumulated kinetic energy and they have application examples to uninterruptible power supplies. In addition, a recharging energy storage can be considered to be a kind of load, and a discharging energy storage can be considered to be a kind of generator.

The power electronics device 11a has an input that is connected to the output of the energy storage device 24a by a power line and has an output that is connected to the outputs of the power electronics devices 11b to 11d and an electric power system 20 by a power line. In addition, the power electronics device 11a is connected to the power electronics devices 11b to 11d and the central control device 21 via a communication line 29. As described above, a power line 28 in the present embodiment is of, for example, a three-phase three-wire system. The power electronics devices 11b to 11d similarly have inputs that are connected to the outputs of the respective energy storage devices 24b to 24d by power lines, have outputs that are connected to the electric power system 20 by the power line, and are connected to the central control device 21 via the communication line 29. The power electronics devices 11a to 11d in the present embodiment are, for example, inverter for converting DC power into AC power.

The four power electronics devices 11a to 11d act in a cooperative manner so as to make the value of AC power to be output to the electric power system 20 a given power value. Hereafter, this action will be referred to as cooperative action. This AC power thereby flows reversely to the electric power system 20. Here, the power electronics device 11a converts DC power discharged from the energy storage device 24a into, for example, AC power of 1 kW and outputs the AC power. It is assumed that the power electronics devices 11b to 11d each similarly convert DC power discharged from the respective energy storage devices 24b to 24d into, for example, AC power of 1 kW and output the AC power.

The power electronics device 11a in the first embodiment superimposes an electric power having a frequency fa onto its output power. Here, the frequency fa is a frequency that is different from a frequency f0 of the electric power output from the electric power system 20 (hereafter, referred to as a system frequency). In another respect, the frequencies of the electric powers that the other power electronics devices (i.e., different power electronics devices) superimpose onto their output powers are different from the fundamental frequency f0 of the output powers from the other power electronics devices. The fundamental frequency is a frequency of a fundamental wave.

Here, the electric power to be superimposed may be produced in the form of either voltage or current. The amplitude of the electric power to be superimposed (hereafter, also referred to as superimposed power) may have a value smaller than that of the amplitude of the system frequency f0, and the electric energy of the electric power to be superimposed is desirably not as high as to become a disturbance factor to the electric power system 20 or the power electronics system 1.

The power electronics devices 11b to 11d continuously monitor the frequency fa component of the voltage or current on the power line 28. If the frequency fa component in the power line 28 varies (e.g., disappears, rapidly decreases), the power electronics devices 11b to 11d can immediately detect that the state of the power electronics device 11a has been changed. Here, the changes in the state include stop, partial or entire abnormality, partial or entire failure, and deterioration, and this is also applied to the following embodiments.

Each power electronics device may suddenly stop owing to failure, but upon detecting the stop of the power electronics device 11a, the power electronics devices 11b to 11d immediately increase the respective outputs from 1 kW to 1.33 kW, enabling a stable reverse power flow of 4 kW as the power electronics system 1.

In a similar manner, the power electronics devices 11b to 11d superimpose electric powers at frequencies fb to fd, which are different from one another, onto the respective output powers. Here, the frequencies fb to fd are frequencies different from the system frequency f0 and the frequency fa. Here, the superimposed powers may be produced in the form of either voltage or current.

The power electronics devices 11a, 11c, and 11d continuously monitor the frequency fb component of the voltage or current on the power line 28. If the frequency fb component in the power line 28 disappears or rapidly decreases, the power electronics devices 11a, 11c, and 11d can immediately detect that an abnormality (e.g., stop) has occurred in the power electronics device 11b.

In a similar manner, the power electronics devices 11a, 11b, and 11d continuously monitor the frequency fc [Hz] component of the voltage or current on the power line 28. If the frequency fc component of the power line 28 disappears or rapidly decreases, the power electronics devices 11a, 11b, and 11d can immediately detect that an abnormality (e.g., stop) has occurred in the power electronics device 11c.

In a similar manner, the power electronics devices 11a, 11b, and 11c continuously monitor the frequency fd [Hz] component of the voltage or current on the power line 28. If the frequency fd component of the power line 28 disappears or rapidly decreases, the power electronics devices 11a, 11b, and 11c can immediately detect that an abnormality (e.g., stop) has occurred in the power electronics device 11d. Hereafter, the power electronics devices 11a to 11d may be collectively referred to as a power electronics device 11.

### (Choice of Frequency)

As described above, the frequency fa of the superimposed power used in the present embodiment is different from the system frequency f0 that is applied to the electric power system 20 and the power line 28. The system frequency f0 may fluctuate by about several percent, and thus a frequency f1 of a superimposed power to be used is chosen avoiding not only the system frequency f0 but also frequencies within this margin across the system frequency f0.

To choose the frequency f1 of the superimposed power, it is desirable to exclude frequencies that are the multiples of frequencies included within range (e.g., f0±5 Hz) the reference of which is the system frequency f0. Although the use of the frequencies of these multiples is not impossible, the use of not the most suitable for the detection of the superimposed power used in the present embodiment because electric power having such frequencies of the multiples may occur without being intentionally injected.

For example, if an output waveform is distorted, the output contains harmonics having frequency components that are triple, quintuple, and the like of the fundamental frequency. For this reason, assuming that the fundamental frequency is 50 Hz, it is not desirable to use frequencies of 150 Hz or 250 Hz as the frequency of an electric power to be superimposed. In addition, if the power line 28 is, in particular, of AC in a three-phase three-wire system, it is required to pay attention to a phenomenon that voltages having frequencies of the multiples of three of the system frequency f0 are cancelled owing to three-phase connection, and thus it is desirable to use, as the frequency fa, a frequency of a magnification that is not an integral multiple of the system frequency f0. In another respect, the frequencies of electric powers that the other power electronics devices superimposed onto their output powers are desirably different from the frequencies of an integral multiple of the fundamental frequency of the output powers of the other power electronics devices.

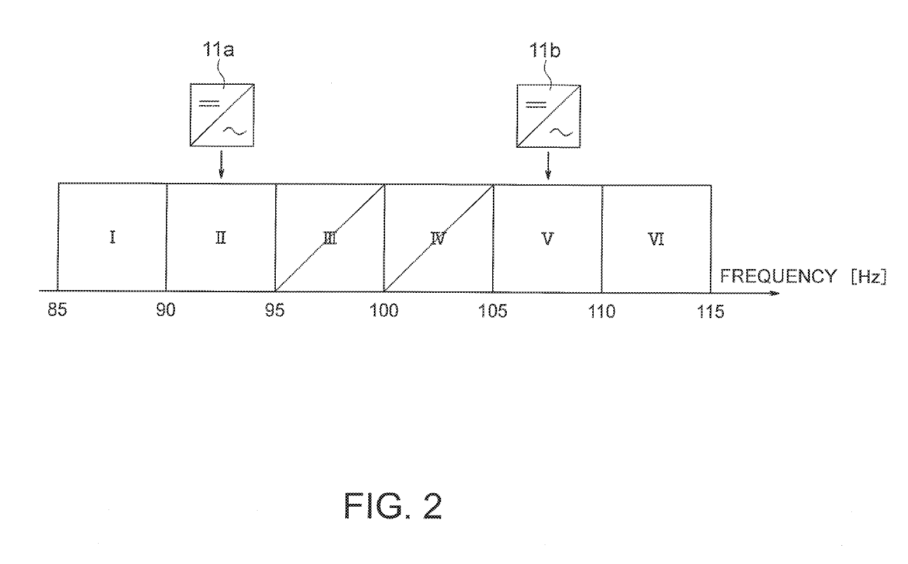

For example, 1.85×f0 or the like is used as the frequency fa. The magnification at this point is a number that satisfies the above condition, and may be selected at random such that the frequency fa becomes a frequency within a range in which the power electronics device can analyze the frequency. At this point, as shown in FIG. 2, with respect to a frequency band in which the power electronics device can analyze the frequency, the frequency band may be divided into blocks having a frequency width for which the frequency analysis resolution of the power electronics devices or the margin of fluctuations in the system frequency is taken into account. Then, from among the blocks, unused blocks from among blocks excluding blocks containing the system frequency f0 or frequencies positioned within a given percentage (e.g., several percent) across the system frequency f0, and the multiples thereof may be assigned to the power electronics devices 11a to 11d.

FIG. 2 is a diagram for illustrating an example of frequency assignment of high frequencies. FIG. 2 shows six blocks into which a frequency band between 85 Hz and 115 Hz is divided using a frequency width of 5 Hz. As shown in FIG. 2, frequencies across 100 Hz that is a multiple of system frequency 50 Hz are avoided, and a block II is assigned to the power electronics device 11a. In this case, the power electronics device 11a superimposes, for example, an electric power at 92.5 Hz that is the center frequency of the block II onto the output thereof.

The frequency fb of the electric power superimposed by the power electronics device 11b is elected using an electing algorithm that is similar to that used for the frequency fa of the electric power superimposed by the power electronics device 11a. Note that superimposing two or more kinds of electric powers is subject to the condition that these frequencies are different from one another and these frequencies are sufficiently separated by the frequency analysis resolution of the power electronics devices or the volatility of the system frequency. For example, in FIG. 2, as an example in which the above-described condition is met, an unused block V is assigned to the power electronics device 11b. In this case, the power electronics device 11b superimposes, for example, an electric power at 107.5 Hz that is the center frequency of the block V onto the output thereof.

If a frequency filter circuit, a transformer, and the like are included between the power electronics system 1 and the electric power system 20, and these elements are difficult to pass specified frequencies, such frequencies may be preferentially assigned. It is thereby possible to reduce high-frequency components that are output to the electric power system 20.

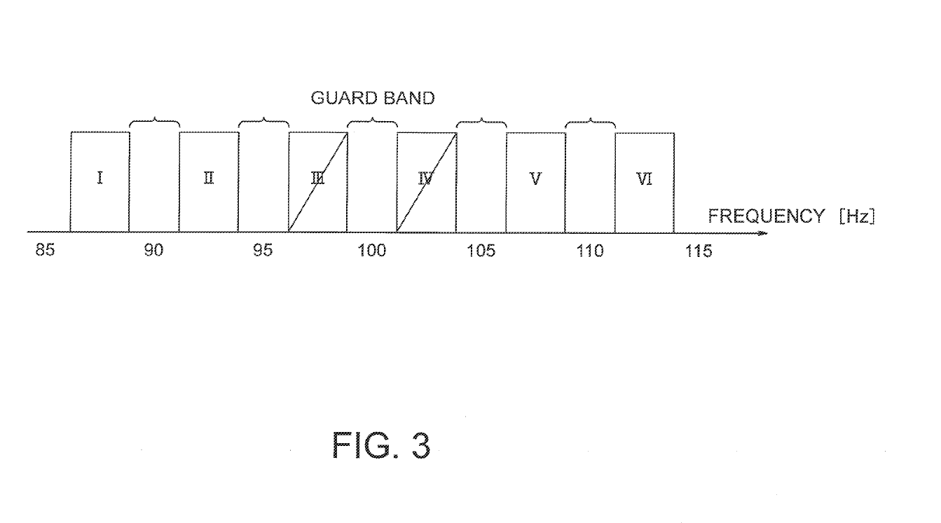

To prevent available frequency bands from overlapping among the power electronics devices, unavailable frequency bands (guard bands) may be provided between the blocks. FIG. 3 is a diagram showing an example in which the unavailable frequency bands are provided between the blocks. As shown in FIG. 3, the blocks are provided at intervals of the unavailable frequency band.

Note that the power electronics devices 11a to 11d may have a function of carrier sense that monitors, before actually outputting superimposed powers, whether any superimposed power at the same frequency is already present in the power line 28 for a certain period of time. In particular, in the case where a power electronics device to which the present embodiment is not applied or the other devices coexist in the power electronics system 1, it is desirable to perform the carrier sense in advance because frequencies, on which the power electronics devices 11a to 11d in the present embodiment reach an agreement through communication, may be already used for an application such as a single operation detection.

### (Configuration of Power Electronics Device 11)

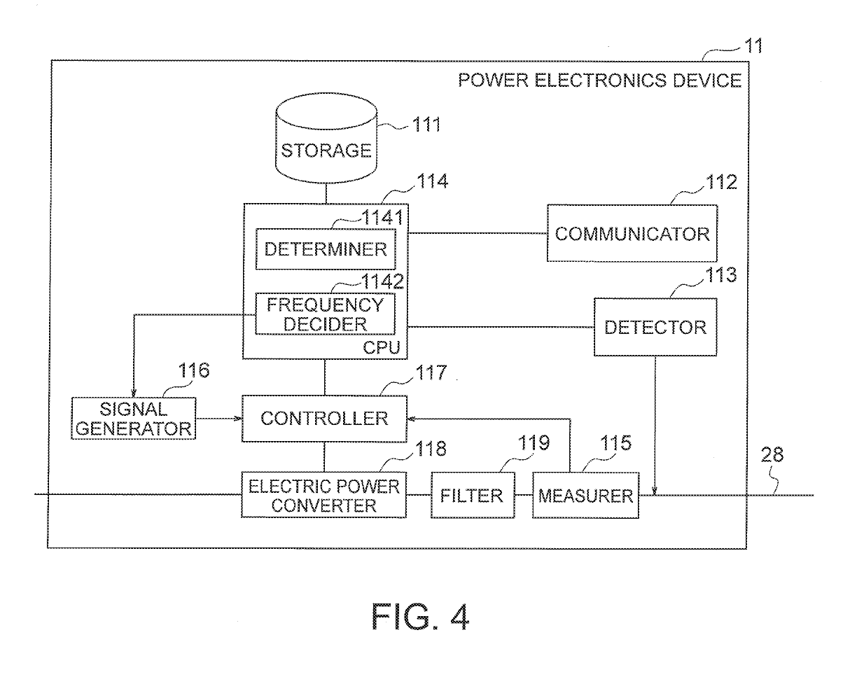

Subsequently, the configuration of the power electronics device 11 will be described. FIG. 4 is a diagram showing the configuration of the power electronics device 11 in the first embodiment. As shown in FIG. 4, the power electronics device 11 includes a storage 111, a communicator 112, a detector 113, a CPU (Central Processing Unit) 114, a measurer 115, a signal generator 116, a controller 117, an electric power converter 118, and a filter 119.

In the storage 111, various programs to be read and executed by the CPU 114 are stored. In addition, in the storage 111, for example, a frequency list containing four available frequencies f1, . . . , f4 is stored. In addition, each power electronics device has an identification number assigned thereto, as an example of device identifying information to identify each power electronics device, and the storage 111 holds the identification number.

The communicator 112 communicates with the other power electronics devices and the central control device 21.

The detector 113 detects electric powers at frequencies of electric powers that the other power electronics devices superimpose onto their output electric powers, from the power line 28, and obtains a detection signal through the detection. Then, the detector 113 outputs the obtained detection signal to the CPU 114. The detector 113 may be configured by circuitry. The circuitry may include a circuit, a plurality of circuits or a system of circuits.

The CPU 114 reads programs from the storage 111 and executes the programs, functioning as a determiner 1141 and a frequency decider 1142. The CPU 114 is one example of processing circuitry and another processor other than the CPU 114 may be employed. The determiner 1141 and the decider 1142 can be implemented by the processing circuitry. The processing circuitry may include a circuit, a plurality of circuits or a system of circuits.

The determiner 1141 determines the states of the other power electronics devices based on this detection signal.

More specifically, for example, the determiner 1141 determines that the above other power electronics device has been stopped if the frequency component of the electric power, contained in the detection signal, that the other power electronics device superimposes onto the electric power output therefrom is less than a predetermined threshold value. In this case, the determiner 1141 may cause a response request to be transmitted from the communicator 112 to the power electronics device and may determine that the power electronics device is stopping or in failure if there is no response with respect to the response request. In addition, the communicator 112 may notifies the central control server 21 of an alive status indicating that the power electronics device is in action or stopping.

The frequency decider 1142 assigns frequencies of electric powers superimposed by the power electronics devices 11a to 11d through communication performed by the communicator 112.

There will be described the case where, for example, there is a power electronics device, in the power electronics system 1, which acts as a master for determining the assignment of the frequencies of electric powers to be superimposed. The frequency decider 1142 of the master may assign available frequencies such that a power electronics device having a smaller identification number is assigned a lower frequency. Then, the communicator 112 of the master may notify the power electronics devices 11b to 11d of the assigned frequencies through communication.

In contrast, in the case where there is no power electronics device, in the power electronics system 1, which acts as the master, the communicator 112 of each power electronics device may obtain the identification numbers of the other power electronics devices from the other power electronics devices in a group through communication. Then, the frequency decider 1142 of each power electronics device may determine which order the identification number of the device itself is in an ascending order and select a frequency corresponding to the determined order.

The frequency decider 1142 notifies the signal generator 116 of the obtained frequency of a superimposed power.

The measurer 115 measures a three-phase current flowing through the power line 28 and outputs a current signal that indicates the measured current to the controller 117.

The signal generator 116 generates a superimposed power signal that indicates the superimposed power having a frequency notified from the frequency decider 1142 and outputs the generated superimposed power signal to the controller 117.

The controller 117 can be implemented by circuitry such as a control circuit. The circuitry may include a circuit, a plurality of circuits or a system of circuits. The controller 117 generates a gate driving signal corresponding to a target output power and outputs the generated gate driving signal to the electric power converter 118. This causes a semiconductor element in the electric power converter 118 to drive by the gate driving signal. In addition, the controller 117 performs control so as to superimpose an electric power at a second frequency, different from a first frequency being the frequency of an electric power that the other power electronics device superimposes onto the output power, onto the output power from the power electronics device. More specifically, the controller 117 performs control so as to superimpose this superimposed power signal onto an electric power output from the electric power converter 118. In this case, the determiner 1141 determines the state of the other power electronics device based on a first frequency component in the detection signal.

The electric power converter 118 converts input electric power (e.g., DC power) and outputs the converted electric power (e.g., AC power). For example, the electric power converter 118 converts the input DC power into AC power by an internal semiconductor element being driven by the gate driving signal input from the controller 117.

The filter 119 removes electromagnetic noise contained in the AC power output from the electric power converter 118. For example, the filter 119 applies a given low-pass filter to the AC power output from the electric power converter 118 to allow the electric power at the system frequency to pass therethrough and the superimposed power and removes the electric power at the other frequencies. Note that, in some of the following embodiments, in the case of determining the state of the other power electronics device using electromagnetic noise, the filter 119 may be configured not to reduce electromagnetic noise or to reduce only a portion of electromagnetic noise. In addition, in this case, the filter 119 may be configured to reduce the superimposed power. In contrast, in some of the following embodiments, in the case of not determining the state of the other power electronics device using the superimposed power, the filter 119 may be configured to reduce the superimposed power.

Then, the filter 119 outputs the passing electric power via a circuit breaker (not shown) to the electric power system 20. The filter 119 includes, as an example, an inductor having one end connected in series to the output of the electric power converter 118 and the other end connected to one end of the circuit breaker (not shown), and a capacitor having one end connected to one phase of the output of the electric power converter and other end connected to another phase of the output.

The elements 112 to 119 shown in FIG. 4 can be implemented by circuitry such as a processor, an integrated circuit and other kinds of circuits, as examples. The elements are different physical circuitry or all or a part of them may be same physical circuitry.

### (Superimposing Circuit of Superimposed Power)

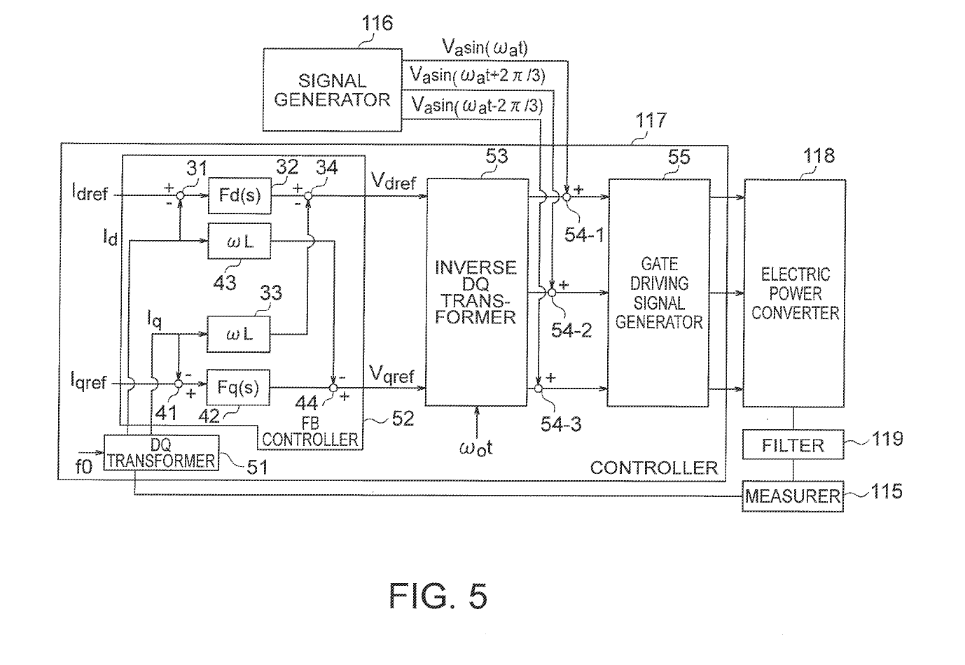

Subsequently, the configuration of the controller 117 will be described in detail. FIG. 5 is a diagram showing the configuration of the controller 117 in the first embodiment. Since the power electronics device outputs three-phase alternating-current power, as shown in FIG. 5, the controller 117 subjects the three-phase current measured by the measurer 115 to dq transformation and uses a value obtained through the dq transformation for feedback control.

As shown in FIG. 5, the controller 117 includes a dq transformer 51, a FB controller 52, an inverse dq transformer 53, adders 54-1, 54-2, and 54-3, and a gate driving signal generator 55.

The dq transformer 51 subjects the three-phase current measured by the measurer 115 to the dq transformation and outputs a d-axis component I_{d} and a q-axis component I_{q} obtained through the dq transformation to the FB controller 52.

The FB controller 52 performs PI control on the d-axis component I_{d} and the q-axis component I_{q} and outputs a target voltage V_{dref} on a d axis and a target voltage V_{qref} on a q axis to the inverse dq transformer 53.

The inverse dq transformer 53 performs inverse dq transformation on the target voltage V_{dref} on the d axis and the target voltage V_{qref} on the q axis, to obtain a three-phase voltage command value.

The adders 54-1, 54-2, and 54-3 add a superimposed power to be injected to voltage command values of the respective phases output from the inverse dq transformer 53. For example, to a first phase, Vₐ sin(ωₐt) output from the signal generator 116 is added, to a second phase, Vₐ sin(ωₐt+2π/3) output from the signal generator 116 is added, and to a third phase, Vₐ sin(ωₐt−2π/3) output from the signal generator 116.

The gate driving signal generator 55 subjects a value obtained through the superimposed power addition and a carrier wave to composing calculation to generate a gate driving signal. Here, the carrier wave is a modulated wave to determining a pulse width of output voltage in the inverter in PWM (Pulse Width Modulation) control scheme. More specifically, for example, the gate driving signal generator 55 generates, as the gate driving signal, a high-level signal if the value obtained through the superimposed power addition is equal to or higher than the value of the carrier wave or a low-level signal if the value obtained through the superimposed power addition is lower than the value of the carrier wave. Then, the gate driving signal generator 55 outputs the generated gate driving signal to the electric power converter 118. A power switch included in the electric power converter 118 is thereby driven, causing the electric power converter 118 to output the AC power.

Here, the FB controller 52 includes a subtractor 31, a multiplier 32, a multiplier 33, a subtractor 34, a subtractor 41, a multiplier 42, a multiplier 43, and a subtractor 44.

The subtractor 31 subtracts the d-axis component I_{d} from the target current I_{dref} in the d axis and outputs the subtracted value to the multiplier 32.

The multiplier 32 multiplies the subtracted value input from the subtractor 31 by a given transmission function Fd(s) and outputs the obtained value to the subtractor 34.

The multiplier 33 multiplies the d-axis component I_{d} by ωL and outputs the obtained value to the subtractor 34. Here, ω is an angular frequency, and L is the inductance of an inductor included in the filter 119.

The subtractor 34 subtracts the value input from the multiplier 33 from the value input from the multiplier 32 and outputs the obtained value to the inverse dq transformer 53, as the target voltage V_{dref} on the d axis.

The subtractor 41 subtracts the q-axis component I_{q} from the target current I_{qref} on the q axis and outputs the subtracted value to the multiplier 42.

The multiplier 42 multiplies the subtracted value input from the subtractor 41 by a given transmission function Fq(s) and outputs the obtained value to the subtractor 44.

The multiplier 43 multiplies the q-axis component I_{q} by ωL and the obtained value to the subtractor 44. Here, ω is the angular frequency, and L is the inductance of the inductor included in the filter 119.

The subtractor 44 subtracts the value input from the multiplier 43 from the value input from the multiplier 42 and outputs the obtained value to the inverse dq transformer 53, as the target voltage V_{qref} on the q axis.

Note that the points at which the superimposed power is added are not limited to those shown in the drawing, and for example, the superimposed power may be directly added to the current target values I_{dref} and I_{qref}. In addition, rather than superimposing the superimposed power by the control, a superimposed power output from a power supply for an superimposed power that is separately prepared may be superimposed using a capacitor or transformer separately provided at the output end the power electronics device 11.

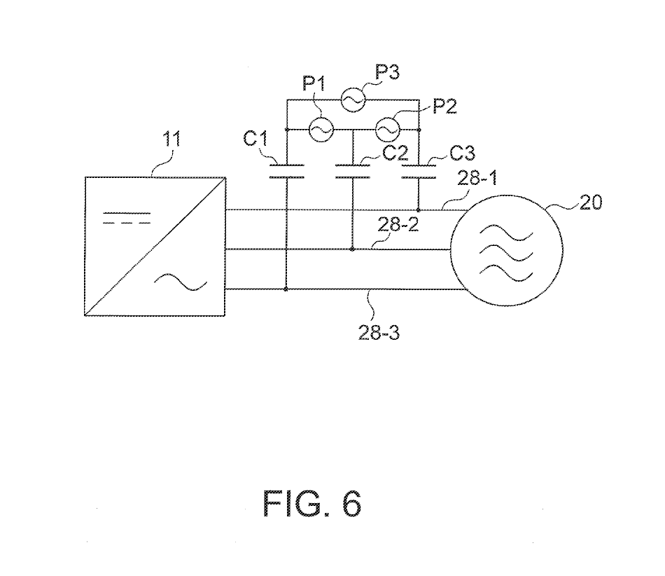

FIG. 6 is a configuration example in the case of superimposing electric powers using capacitors that are separately provided at the output end of the power electronics device 11. As shown in FIG. 6, the power line 28 is formed by a first power line 28-1, a second power line 28-2, and a third power line 28-3. One end of a capacitor C1 is connected to one end of a superimposed power supply P1 and one end of a superimposed power supply P3, and the other end of the capacitor C1 is connected to the third power line 28-3. Electric powers output from the superimposed power supplies P1 and P3 are thereby superimposed via the capacitor C1 onto the third power line 28-3.

Similarly, one end of a capacitor C2 is connected to the other end of the superimposed power supply P1 and one end of a superimposed power supply P2, and the other end of the capacitor C2 is connected to the second power line 28-2. Electric powers output from superimposed power supplies P1 and P2 are thereby superimposed via the capacitor C2 onto the second power line 28-2.

In addition, similarly, one end of a capacitor C3 is connected to the other end of the superimposed power supply P2 and the other end of the superimposed power supply P3, and the other end of the capacitor C3 is connected to the first power line 28-1. Electric powers output from superimposed power supplies P2 and P3 are thereby superimposed via the capacitor C3 onto the first power line 28-1.

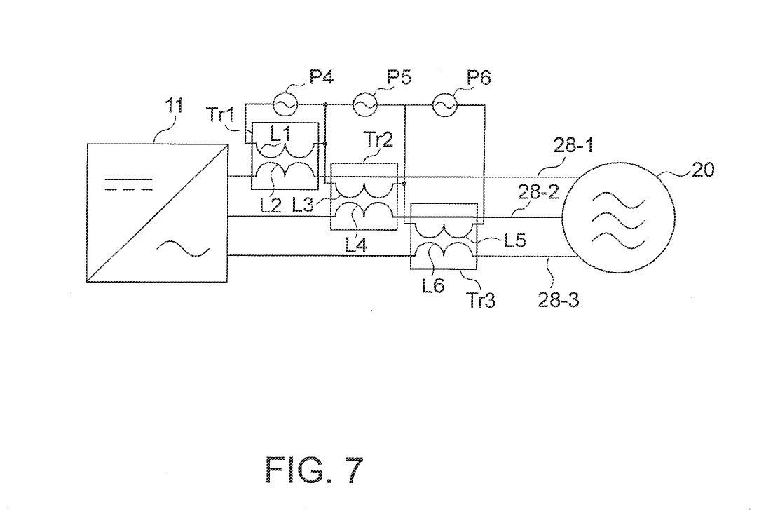

FIG. 7 is a configuration example in the case of superimposing electric powers using transformers that are provided at the output end of the power electronics device 11. As shown in FIG. 7, the power line 28 is formed by a first power line 28-1, a second power line 28-2, and a third power line 28-3.

A transformer Tr1 is connected to a first output of the power electronics device 11. Here, the transformer Tr1 has a coil L1 and a coil L2. High-frequency current is supplied from a high-frequency power supply P4 to the coil L1, generating a varying magnetic field, which is transmitted to the coil L2 coupled by mutual inductance and converted into current in the coil L2. An electric power is thereby superimposed onto the first power line 28-1.

Similarly, a transformer Tr2 is connected to a second output of the power electronics device 11. Here, the transformer Tr2 has a coil L3 and a coil L4. High-frequency current is supplied from the a high-frequency power supply P5 to the coil L3, generating a varying magnetic field, which is transmitted to the coil L4 coupled by mutual inductance and converted into current in the coil L4. An electric power is thereby superimposed onto the second power line 28-2.

Similarly, a transformer Tr3 is connected to a third output of the power electronics device 11. Here, the transformer Tr3 has a coil L5 and a coil L6. High-frequency current is supplied from a high-frequency power supply P6 to the coil L5, generating a varying magnetic field, which is transmitted to the coil L6 coupled by mutual inductance and converted into current in the coil L6. An electric power is thereby superimposed onto the third power line 28-3.

In the case of a power electronics device the output of which has three or more phases, an electric power may be superimposed onto only two of the phases. Then, if a failure occurs in either of the two phases onto which high frequency is superimposed, an electric power leaks out into a phase onto which an electric power is not at first superimposed. Using this phenomenon, the determiner 114 may determine a phase in which the failure has occurred. For example, assume the case where at a first frequency, an electric power is superimposed onto a first phase and a second phase, at a second frequency different from the first frequency, an electric power is superimposed onto the second phase and a third phase, and at a third frequency different from the first frequency and the second frequency, an electric power is superimposed onto the first phase and the third phase. For example, if a superimposed power leaks out into the third phase at the first frequency, a superimposed power leaks out into the first phase at the second frequency, and no superimposed power leaks out into the second phase at the third frequency, the determiner 114 may determine that a failure has occurred in the second phase.

### (Detecting Method of Frequency Component)

Subsequently, there will be described a method of detecting a specified frequency component from current or voltage measured on the power line 28. The current or voltage measured on the power line 28 has a composite waveform of waveforms having a plurality of frequencies including the system frequency f0, and thus any processing is needed to obtain the amplitude or energy value of a specified frequency component from this current or voltage. Hence, the detector 113 may pass and detect only current or voltage at a desired frequency using, for example, a filter circuit such as a band-path filter.

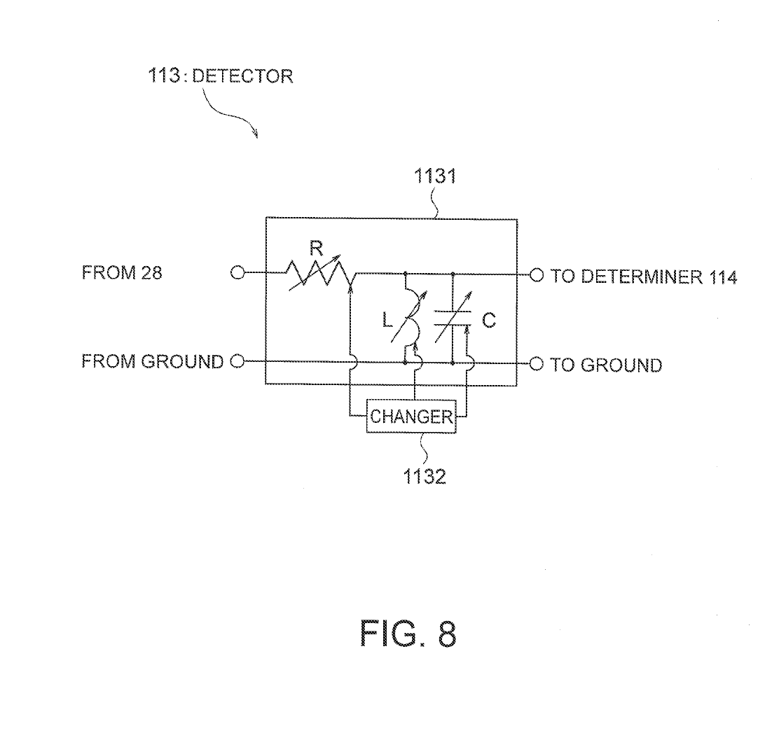

FIG. 8 is a configuration example of the detector 113 in the first embodiment. The detector 113 in FIG. 8 includes a band-path filter 1131 and a changer 1132. The band-path filter 1131 is an RLC circuit that has a variable resistor Rv one end of which is connected to the power line 28, a variable inductor Lv one end of which is connected to the other end of the variable resistor Rv, and a variable capacitor Cv one end of which is connected to the other end of the variable resistor Rv. Using this band-path filter 1131 enables a desired frequency component to be extracted from a waveform in which AC voltages at a plurality of frequencies coexist.

A transmission function G(s) of this circuit is expressed by the following Expression (1).

$$\begin{matrix}[ Expression 1 ] & \\ {G}_{RLC} ( s ) = \frac{( \frac{1}{RC} ) s}{{s}^{2} + ( \frac{1}{RC} ) s + \frac{1}{LC}} & ( 1 )\end{matrix}$$

Here, “R” denotes the resistance value of the variable resistor Rv, “L” denotes the inductance value of the variable inductor Lv, and “C” denotes the capacitance of the variable capacitor Cv. This circuit functions as a band-path filter that passes only a frequency band the center of which is a frequency “f_{RLC}” in the following Expression (2).

$$\begin{matrix}[ Expression 2 ] & \\ {f}_{RLC} = \frac{1}{2 π \sqrt{LC}} & ( 2 )\end{matrix}$$

The Q value of this filter is expressed by the following Expression (3).

$$\begin{matrix}[ Expression 3 ] & \\ {Q}_{RLC} = \frac{1}{R} \sqrt{\frac{L}{C}} & ( 3 )\end{matrix}$$

Here, when the block division is performed, the width of a block should be larger than the bandwidth of the filter (e.g., the Q value).

In addition, the changer 1132 switches the frequency f_{RLC} that passes this band-path filter 1131 between frequencies fa, fb, fc, and fd, by rapidly varying the value of at least one of the variable inductor Lv and the variable capacitor Cv. The detector 113 can thereby extract the superimposed power components of the frequencies fa, fb, fc, and fd.

This enables the determiner 114 to determine, for example, that the power electronics device 11a is in normal working if the amplitude of the AC voltage at the frequency fa passing the filter is higher than a certain threshold value and determine that the power electronics device 11a is stopped if this amplitude is lower than the threshold value.

Similarly, the determiner 114 can determine, for example, that the power electronics devices 11b, 11c, and 11d are in normal working if the amplitudes of the AC voltages at the frequencies fb, fc, and fd passing the filter are higher than the certain threshold value and determine that the power electronics devices 11b, 11c, and 11d are stopped if these amplitudes are lower than the threshold value.

Note that, in the present embodiment, the configuration is to rapidly switch between the constants of the filter to monitor the plurality of frequencies with one filter circuit, but is not limited to this. For example, the detector 113 may include filter circuits by the number of power electronics devices 11a, 11b, 11c, and 11d, that is, four and cause the respective filter circuits to pass the AC voltages at the frequencies fa, fb, fc, and fd.

Subsequently, there will be described another method of detecting a specified frequency component from the current or voltage measured on the power line 28. The detector 113 may detect a desired frequency component from a waveform in which voltages or currents containing a plurality of frequencies coexist, using Fourier analysis (spectral analysis). More specifically, for example, the detector 113 may perform Fourier transform on a signal that indicates current or voltage measured on the power line 28 to detect the ratios of the frequencies fa, fb, fc, and fd.

At this point, the ratios of the above-described frequencies fa, fb, fc, and fd may be detected by subjecting a digital signal obtained by performing AD conversion on the signal indicating the current or voltage measured on the power line 28 to Fast Fourier Transform (FFT).

Note that the detector 113 may detect the frequency component of the superimposed power using methods other than those using the band-path filter circuit and the spectral analysis. For example, in the case where the power electronics device is an inverter having a system interconnecting function, the power electronics device may have a harmonics detecting function for the single operation detection, and the power electronics device may detect the frequency component of the superimposed power using this function.

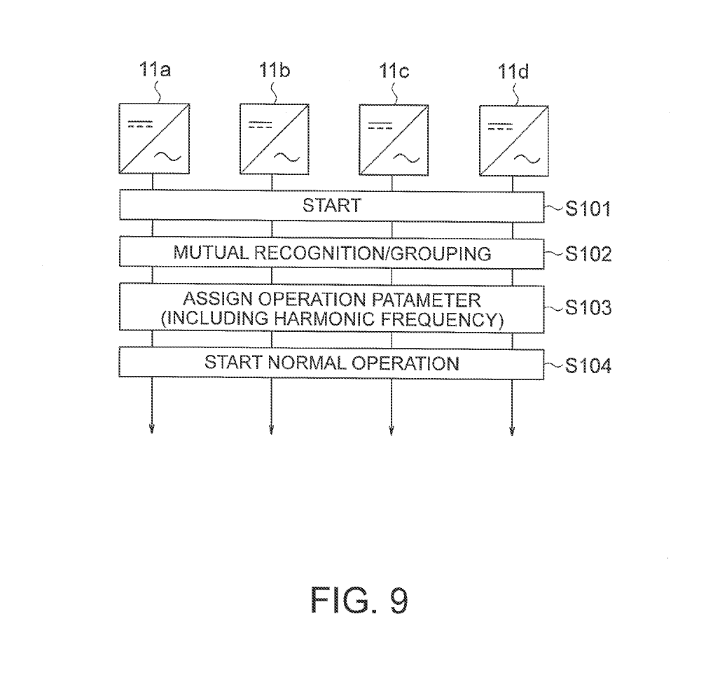

Subsequently, assuming the case where the four power electronics devices 11a to 11d perform cooperative action, there will be described the flow of processing in which they perform initialization through communication, with reference to FIG. 9. FIG. 9 is a diagram showing an example of the flow in execution processing of the initialization in the first embodiment.

(Step S101) First, the power electronics devices 11a to 11d start.

(Step S102) After starting, the power electronics devices 11a to 11d each perform mutual recognition to recognize how many power electronics devices are present therearound. This recognition may be based on a value that is hard coded as an initial set value, or the mutual recognition may be automatically completed using a communication protocol such as UPnP without the initial setting.

In such a manner, by mutually recognizing the presence of the other power electronics devices, a plurality of the power electronics devices form a group. In forming the group, a master for assigning an operation parameter may be elected from among the plurality of power electronics devices, and the remaining devices may be made to be slaves. Any algorithm may be used to as this algorithm to elect the master.

In addition, at this point, the master may be elected from among the plurality of power electronics devices 11a to 11d and the central control server 21. If the central control server 21 is present, the central control server 21 may be made to be a node of the highest master device priority in a communication system. Note that the central control server 21 is not necessary to act as the master.

(Step S103) When the grouping processing in step S102 is completed, the operation parameter such as an output target value is determined. For example, when the power electronics devices 11a to 11d are connected in parallel and an output of P [W] is required of the four devices in total, the master may assign the output target value to each power electronics device such that the total output becomes P [W].

In addition, at this point, the frequencies of superimposed powers that the respective power electronics devices use to determine the states are assigned. The master may associate an available frequency with device identifying information for each power electronics device. Alternatively, the association may be established by the power electronics devices 11a to 11d using communication. Alternatively, the association may be established in a fixed manner by reading a setting file or hard coding.

(Step S104) Thereafter, the power electronics devices 11a to 11d start normal operation.

### (Detection of Abnormal Stop)

Subsequently, there will be described a method of detecting a power electronics device that suddenly stops due to abnormality in the power electronics system 1. Here, as an example, assume the case where the power electronics device 11a suddenly stops due to some abnormality. In this case, the power electronics device 11a cannot transmit an advance stop notice massage before stopping, and thus the power electronics devices 11b, 11c, and 11d determines whether the power electronics device 11a is operating or stopping based on the presence/absence of a power component superimposed by the power electronics device 11a. More specifically, the power electronics devices 11b, 11c, and 11d determine that the power electronics device 11a is operating if a power component superimposed by the power electronics device 11a is present. On the other hand, the power electronics devices 11b, 11c, and 11d determine that the power electronics device 11a is stopping if a power component superimposed by the power electronics device 11a is absent.

The power electronics devices 11a to 11d in the present embodiment adjust the fundamental frequency of their outputs to the system frequency (e.g., 50 Hz) of the electric power system 20 that is interconnected thereto and superimpose electric powers onto their outputs. Here, the power electronics devices 11a, 11b, 11c, and 11d have the frequencies fa, fb, fc, and fd assigned thereto that are different from one another, as frequencies of the electric powers to be superimposed.

If the power electronics device 11a superimposing the voltage at the frequency fa onto the output voltage stops, the frequency fa component rapidly decreases in a voltage waveform measured on the power line 28. The other power electronics devices 11b, 11c, and 11d detect that the fa Hz component has been fluctuated from the result of continuously performed frequency detection and recognizes that the power electronics device 11a has stopped.

At this point, the power electronics devices 11b to 11d may transmit a signal to request a response to the power electronics device 11a and confirm that the power electronics device 11a has certainly stopped by confirming that no response can be received in response to the signal from the power electronics device 11a. Such communication may be implemented by ping.

In addition, when the stop of the power electronics device 11a is detected, the power electronics devices 11b to 11d may notify the other power electronics devices in the group or the central control server 21 of the stop information through communication. In such a manner, the power electronics devices 11a to 11d in the present embodiment detect whether the other power electronics devices is operating or stopping by the aforementioned mechanism based on monitoring the superimposed power and at the same time request responses from the other power electronics devices through communication as needed, so as to reliably and rapidly detect the stop of the other power electronics device.

The power electronics system 1 in the present embodiment may be formed together with a device, other than the power electronics devices, which includes means for measuring a superimposed power. For example, in the case where the central control server 21 includes means for measuring a superimposed power, the central control server 21 may obtain alive information on the plurality of power electronics devices under its control in real time. Moreover, the central control server 21 may be a server that obtains information on a superimposed power (in the following embodiments, electromagnetic noise, or sonic or radio wave noise) or alive information, through communication with a sensor, a wattmeter, or a slave device for measuring a superimposed power. These matters are also applied to the embodiments other than the present embodiment.

After detecting the stop of the other power electronics device in the group, the power electronics devices 11a to 11d in the present embodiment perform regrouping processing. This regrouping processing includes deleting the entry of the stopping power electronics device from the storage 111, electing a master again, and the like.

In the storages 111 of the power electronics devices 11a to 11d, the details of regrouping processing according to the combinations of stopping one or more power electronics devices may be stored in advance. Then, if a power electronics device in the group stops, the CPU 114 may read the details of regrouping processing according to the combinations of the stopping one or more power electronics devices from the storage 111 and execute the read detail of regrouping processing. This enables the action to be changed without communication.

When the regrouping after the stop is completed, the master reassigns the operation parameter with the lack of the power electronics device in the group. Then, the power electronics devices in the group operate according to the reassigned operation parameter. The power electronics devices in the group thereby return to a normal operation state. Here, the parameter is, for example, the output electric energy of each power electronics device. Each power electronics device may continue the operation under the original parameter during a period between the stop detection to the reassignment of the parameter or may pause the outputting.

As described above, the power electronics device 11 in the first embodiment has an output that is connected to the output of the other power electronics device by the power line 28. Then, the controller 117 performs control so as to superimpose an electric power at the second frequency, different from the first frequency being the frequency of an electric power that the other power electronics device superimposes onto its output power, onto an electric power to be output to the power line 28. Then, the determiner 1141 determines the state of the other power electronics device based on the first frequency component in a detection signal.

This enables the power electronics device 11 to determine that the other power electronics device has stopped if, for example, the first frequency component contained in an electric power flowing through the power line 28 is less than a threshold value.

For this reason, the power electronics device 11 can immediately detect that the other power electronics device has stopped by monitoring the first frequency component contained in the electric power flowing through the power line 28. Therefore, according to the power electronics device 11 in the first embodiment, it is possible to shorten a time taken to determine the state of the other power electronics device without increasing a load to communications equipment.

### Second Embodiment

### Superimposed Power/Cancelling Scheme

Subsequently, a second embodiment will be described. In the first embodiment, a plurality of power electronics devices superimposes electric powers at frequencies different from one another onto their output powers. In contrast, in the second embodiment, the plurality of power electronics devices superimpose electric powers at the same frequency and at phases different from one another onto their output powers such that the superimposed powers cancel out one another. To make the phases different from one another, the plurality of power electronics devices have a function of synchronizing their time among the other power electronics devices in the group and superimpose the superimposed powers onto their output power while controlling the phases and the amplitudes of the superimposed powers such that the superimposed powers cancel out one another.

By operating in such a manner, in the normal operation state, the components of the superimposed powers hardly appear in the voltage or current in the power line to which the outputs of the plurality of power electronics devices are connected. In the normal operation state, it is thereby possible to minimize disturbance to an output destination. In addition, since the number of kinds of frequencies to be monitored can be limited to one in the case of detecting the component of the superimposed power using a filter circuit, this filter circuit can be simplified as compared with the first embodiment.

If one or more power electronics devices among the plurality of power electronics devices stop, the balance of harmonics is lost, and thus the power electronics devices that continues operate can detect that one or more of the other power electronics devices have stop. The stopping power electronics device is identified based on the phase and the amplitude of the disappearing harmonics or identified by performing alive check communication. Here, the alive check communication is communication by which a signal to request a response is transmitted to a power electronics device to be an alive check object, and the response is checked.

As compared with the first embodiment, in the first embodiment, harmonics occur during a normal period and disappear during a stopping period. In contrast, in the second embodiment, harmonics cancel out one another during the normal period and the occurrence of the harmonics as their composite wave is suppressed, but the cancellation is broken during the stopping period and synthesized harmonics occur.

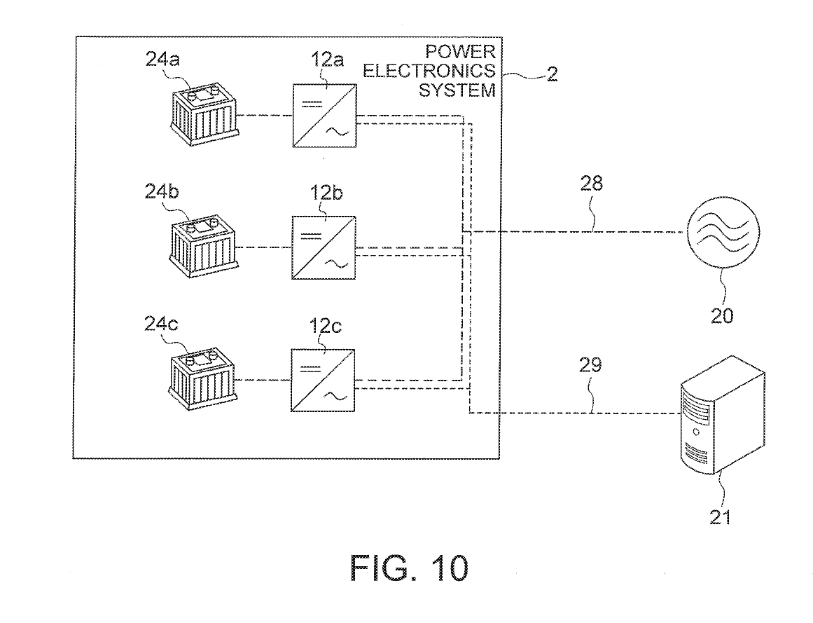

Subsequently, the configuration of a power electronics system 2 in the second embodiment will be described with reference to FIG. 10. FIG. 10 is a diagram showing the configuration of the power electronics system 2 in the second embodiment. Note that components common to those of FIG. 1 will be denoted by the same reference characters, and the specific descriptions thereof will not be described. The configuration of the power electronics system 2 in the second embodiment is a configuration in which, as compared with the configuration of the power electronics system 1 in the first embodiment, the four power electronics devices 11a to 11d are changed to three power electronics devices 12a, 12b, and 12c, and the four energy storage devices 24a to 24d are changed to three power electronics device 24a, 24b, and 24c. Hereafter, the power electronics devices 12a, 12b, and 12c are collectively referred to as a power electronics device 12.

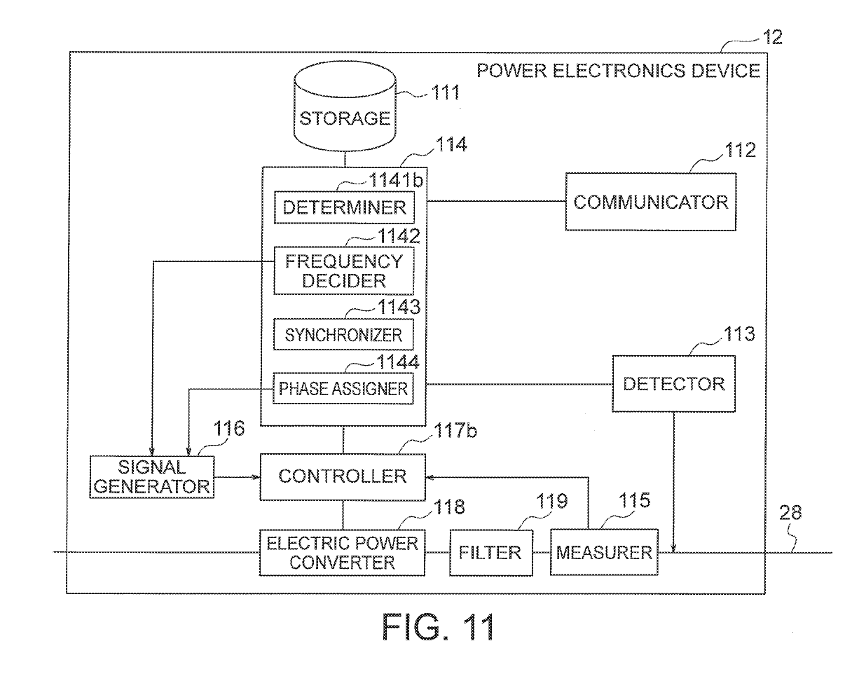

Subsequently, the configuration of the power electronics device 12 in the second embodiment will be described with reference to FIG. 11.

FIG. 11 is a diagram showing the configuration of the power electronics device 12 in the second embodiment. Note that components common to those of FIG. 4 will be denoted by the same reference characters, and the specific descriptions thereof will not be described. The configuration of the power electronics device 12 in the second embodiment is a configuration in which, as compared to the configuration of the power electronics device 11 in the first embodiment, the determiner 1141 is changed to a determiner 1141b, the controller 117 is changed to a controller 117b, and a synchronizer 1143 and a phase assigner 1144 are added. As stated above, the CPU 114 is one example of processing circuitry and another processor other than the CPU 114 may be employed. The determiner 1141b, the decider 1142, the synchronizer 1143 and the phase assigner 1144 can be implemented by the processing circuitry. The processing circuitry may include a circuit, a plurality of circuits or a system of circuits. The controller 117b can be implemented by circuitry such as a control circuit. The elements 112 to 116, 117b, 118 and 119 shown in FIG. 11 can be implemented by circuitry such as a processor, an integrated circuit and other kinds of circuits, as examples. The elements are different physical circuitry or all or a part of them may be same physical circuitry.

The determiner 1141b determines the states of the other power electronics devices based on the frequency component of a first harmonic in a detection signal. In the present embodiment, the determiner 1141b determines, for example, the state of one of the plurality of other power electronics devices in the power electronics system 2. Then, when determining that one of the plurality of other power electronics devices is in a stopping state, the determiner 1141b identifies a power electronics device in the stopping state.

The frequency decider 1142 determines a frequency of harmonics to be used. Here, the frequency of the harmonics to be used in the second embodiment is determined by a method similar to the selecting method for the frequencies in the first embodiment. The frequency of the harmonics may be statically determined by hard coding or a setting file, or may be dynamically determined by distribution through communication. The available frequency may be dynamically changed, or a plurality of available frequencies may be used one by one by applying spread spectrum.

The synchronizer 1143 performs processing of synchronizing the timings of a phase to be a reference (e.g., phase zero) to generate the harmonics. This is performed in order to cause the phases of the harmonics superimposed by the three power electronics devices 12a, 12b, and 12c to shift by 120 degrees from one another. As an example of this, the synchronizer 1143 may perform processing of synchronizing in time with the other power electronics devices in the power electronics system 2 through communication using the communicator 112. Alternatively, the synchronizer 1143 may share, for example, a reference clock signal among the three power electronics devices 12a, 12b, and 12c through a dedicated line (not shown).

Note that, the synchronizer 1143 may only synchronize the timings of the phase to be the reference (e.g., phase zero) that the three power electronics devices 12a, 12b, and 12c uses to generate the harmonics, and may implement the synchronization using any means.

The phase assigner 1144 assigns the phase of the harmonic to be output. In the present embodiment, the three power electronics devices 12a, 12b, and 12c perform the cooperative action. The three power electronics devices 12a, 12b, and 12c in the present embodiment share the same frequency f2 [Hz] as the frequency of superimposed powers. The power electronics devices 12a, 12b, and 12c superimpose harmonics the phases of which shift by 120 degrees from one another onto their outputs with a common amplitude V₂ [V]. This makes the sum of the output voltages of the harmonics output from the three power electronics devices 12a, 12b, and 12c zero. At this point, the sum of the output voltages of the harmonics output from the three power electronics devices 12a, 12b, and 12c is zero as expressed by the following Expression (4).

$$\begin{matrix}[ Expression 4 ] & \\ {V}_{2} sin {ω}_{2} t + {V}_{2} sin ( {ω}_{2} t + \frac{2}{3} π ) + {V}_{2} sin ( {ω}_{2} t - \frac{2}{3} π ) = 0 & ( 4 )\end{matrix}$$

Note that an angular frequency ω₂=2πf₂. Here, the frequency “f₂” is a value determined by the frequency decider 1142.

For example, assume the case where the power electronics device 12a acts as a master, and the frequency decider 1142 of the power electronics device 12a determines the phase assignment. In this case, the communicator 112 of the power electronics device 12a may distribute the determined phase assignment to the other power electronics devices 12b and 12c through communication. Alternatively, the phase assignment may be hard coded in advance in a program stored in the storages 111 of the power electronics devices 12a to 12c. Alternatively, the phase assignment may be shared by a setting file, in which the phase assignment is written, stored in advance in the storages 111 of the power electronics devices 12a to 12c.

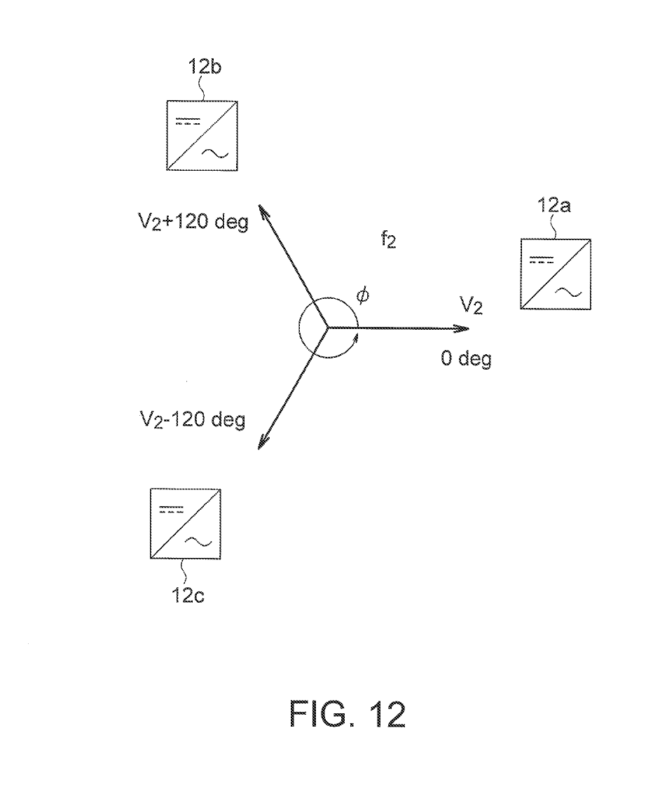

The aforementioned example can be drawn into a vector diagram, which is shown in FIG. 12. FIG. 12 is a vector diagram of the voltages of the superimposed powers output from the power electronics devices 12a to 12c. As shown in FIG. 12, the power electronics device 12a outputs the first harmonic having the amplitude V₂. In contrast, the power electronics device 12b outputs a second harmonic having the amplitude V₂ and a phase lead to the first harmonic by 120 degrees. In addition, the power electronics device 12c outputs a third harmonic having the amplitude V₂ and a phase lag to the first harmonic by 120 degrees. The vector of the first harmonic, the vector of the second harmonic, and the vector of the third harmonic are subjected to vector composition to be zero.

The signal generator 116 generates a three-phase superimposed power signal based on the frequency of superimposed power determined by frequency decider 1142 and the phase assigned by the phase assigner 1144 and outputs the generated superimposed power signal to the controller 117b.

The controller 117b controls a first electric power to be superimposed onto the output power of the power electronics device such that a plurality of second electric powers that the plurality of other power electronics devices superimpose onto their output powers and the first electric power cancel out partially or totally.

The configuration of the controller 117b is similar to the configuration of the controller 117 shown in FIG. 5 and will not be described.

Then, the determiner 1141b determines the state of at least one of the other power electronics devices based on the frequency components of the second electric powers in detection signal.

### (Identifying Method of Stopping Power Electronics Device)

Subsequently, an identifying method of a stopping power electronics device will be described. Consider the case where the power electronics devices 12a to 12c output, as shown in FIG. 12, superimposed powers. During the normal period, the superimposed powers output from the three power electronics devices 12a to 12c cancel out one another, and the superimposed powers cannot be detected from the composite wave of voltages output to the power line 28.

Here, consider the case where the power electronics device 12c stops. At this point, a superimposed power having a phase of −120 deg output from the power electronics device 12c is lost from the composite wave, and thus a superimposed power having the amplitude V₂ and a phase of +60 deg is observed on the power line. At this point, since the phase of the observed superimposed power is +60 deg, the determiners 1141b of the two remaining power electronics devices 12a and 12b can identify the power electronics device 12c assigned with the phase of −120 deg as a stopping power electronics device.

In addition, at this point, the stopping power electronics device may be identified by the remaining power electronics devices performing the alive check communication triggered by the start of observing the superimposed power, without identifying the phase of the observed superimposed power. It is thereby possible to minimize communication during the normal period, and if a power electronics device stops, to quickly identify the stopping power electronics device.

Note that although the three power electronics devices 12a, 12b, and 12c here output the superimposed powers having the common amplitude V₂ [V], the amplitudes may be different from one another as long as the three power electronics devices 12a, 12b, and 12c can at least partially cancel out the superimposed powers. In this case, the amplitude of the observed superimposed power may be different according to the stopping power electronics device. By making use of this, the determiners 1141b may identify the stopping power electronics device based on the magnitude of the amplitude of the observed superimposed power, if, for example, one of the three power electronics devices has stopped.

As described above, in the power electronics devices 12a, 12b, and 12c in the second embodiment, the controller 117b controls the first electric power that the power electronics device superimposes onto its output power such that the first electric power and the plurality of second electric powers that the plurality of other power electronics devices superimpose onto their output powers cancel out one another partially or totally, the second electric powers having a frequency equal to that of the first electric power. The determiner 1141b determines the state of at least one of the plurality of other power electronics devices based on the frequency component of the second electric powers in the detection signal.

This reduces, in addition to the effect of the first embodiment, the frequency component of the superimposed powers in the voltage or current on the power line 28 to which the outputs of the power electronics devices 12a, 12b, and 12c are connected when the power electronics devices 12a, 12b, and 12c are in the normal operation state. It is thereby possible to reduce disturbances to the electric power system 20 being the output destination when the power electronics devices 12a, 12b, and 12c are in the normal operation state. In addition, in the case where the detector 113 includes a filter circuit to detect the frequency component of the first electric power, the filter circuit can be simplified because since the number of kinds of frequencies to be monitored can be limited to one.

Note that in the case where the number of power electronics devices included in the power electronics system 1 is not three but two, the controller 117b may control the first electric power to be superimposed onto the output power from the power electronics device such that the second electric powers that the other power electronics devices in the group superimpose onto their output powers and the first electric power cancel out one another partially or totally, the second electric powers having a frequency equal to that of the first electric power. More specifically, for example, the controller 117b may perform control so as to superimpose the first electric power onto the electric power to be output to the power line 28, the first electric power having a phase different by 180 degrees from the phase of the second electric powers that the other power electronics devices superimpose onto their electric powers to be output to the power line 28. In this case, the determiner 1141b may determine the states of the other power electronics devices based on the frequency components of the second electric powers in the detection signal.

### First Modification of Second Embodiment

Subsequently, a first modification of the second embodiment will be described. In the first modification, assume that four power electronics devices perform the cooperative action.

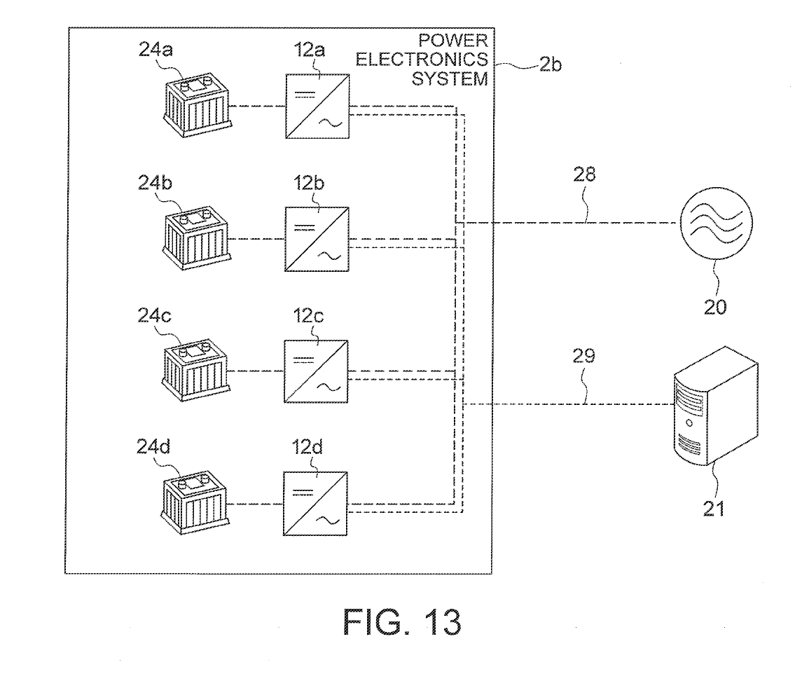

FIG. 13 is a diagram showing the configuration of a power electronics system 2b in the first modification of the second embodiment. As shown in FIG. 13, as compared with the second embodiment, an energy storage device 24d and a power electronics device 12d that has an input connected to the output of an energy storage device 24d and an output connected to the power line 28 are further included. The power electronics device 12d is connected to the power electronics devices 12a to 12c and the central control server 21 via the communication line 29 and can communicate with the power electronics devices 12a to 12c and the central control server 21.

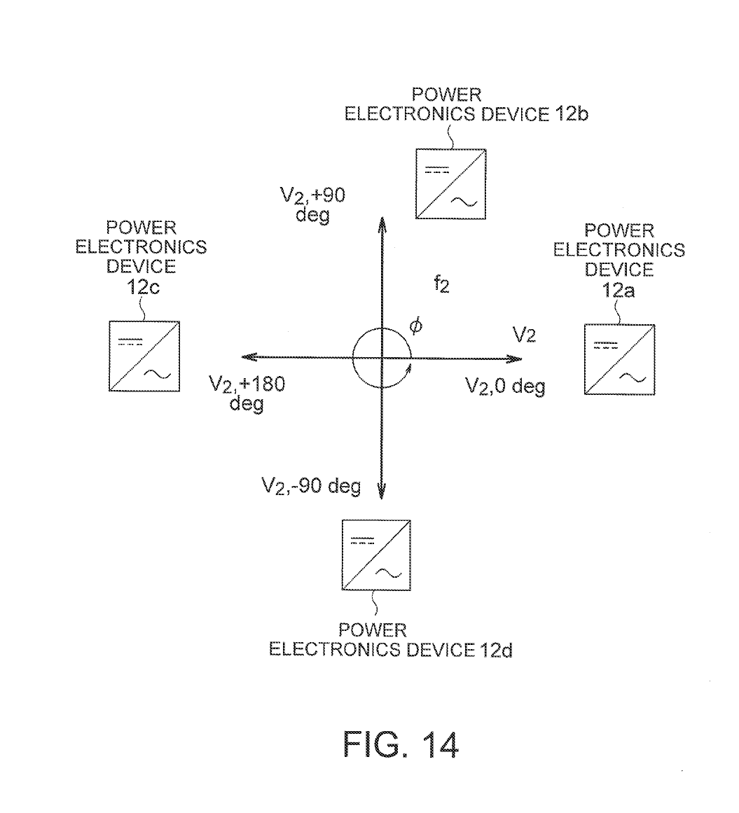

In the case where the four power electronics devices 12a to 12d share a frequency and an amplitude, and the phase assignment is equally given as in the above-described second embodiment, the assignment of the frequencies is as shown in FIG. 14.

FIG. 14 is a vector diagram showing a first example of the voltages of superimposed powers output from the power electronics devices 12a to 12d in the first modification of the second embodiment. As shown in FIG. 14, the power electronics device 12a outputs a superimposed power having the amplitude V₂ and a phase of 0 deg. The power electronics device 12b outputs a superimposed power having the amplitude V₂ and a phase of 90 deg. The power electronics device 12c outputs a superimposed power having the amplitude V₂ and a phase of 180 deg. The power electronics device 12d outputs a superimposed power having the amplitude V₂ and a phase of −90 deg.

When such an assignment is given, the four devices appear to cancel out the superimposed powers, but the four devices actually form two pairs of devices, a pair of the power electronics devices 12a and 12c and a pair of the power electronics devices 12b and 12d, in each of which the superimposed powers cancel out. In this case, if the paired two power electronics devices, for example, the power electronics device 12a and the power electronics device 12c simultaneously stop, no change appears in the sum value of the superimposed powers. That is, the balance between the superimposed powers of the remaining power electronics device 12b and power electronics device 12d in working is not broken and thus the stop of the other power electronics devices cannot be detected.

To avoid such a problem, in an operation by the four power electronics devices, the amplitudes and the phases of superimposed powers are assigned to the power electronics devices 12a to 12d so as to prevent the cancellation of superimposed powers from occurring in each pair.

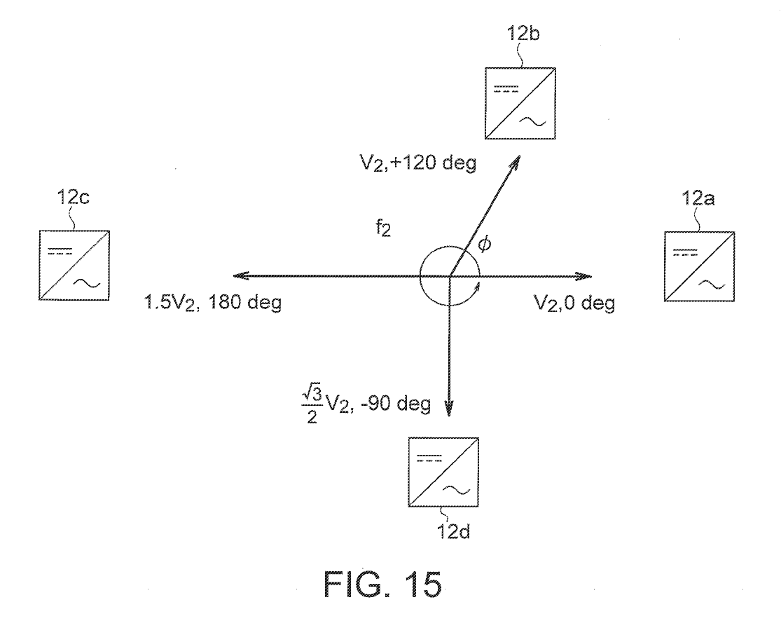

Subsequently, an example of assigning the amplitude and phases of superimposed powers will be described with reference to FIG. 15. FIG. 15 is a vector diagram showing a second example of the voltages of superimposed powers output from the power electronics devices 12a to 12d in the first modification of the second embodiment. As shown in FIG. 15, the power electronics device 12a outputs a superimposed power having the amplitude V₂ and a phase of 0 deg. The power electronics device 12b outputs a superimposed power having the amplitude V₂ and a phase of 120 deg. The power electronics device 12c outputs a superimposed power having an amplitude of 1.5V₂ and a phase of 180 deg. The power electronics device 12d outputs a superimposed power having an amplitude of (√3/2)V₂ and a phase of −90 deg. Adding up the superimposed powers output from the devices results in a sum of zero as expressed by the following Expression (5), and thus the superimposed powers cancel out one another.

$$\begin{matrix}[ Expression 5 ] & \\ {V}_{2} sin {ω}_{2} t + {V}_{2} sin ( {ω}_{2} t + \frac{1}{3} π ) + 1.5 {V}_{2} sin ( {ω}_{2} t + π ) + \frac{\sqrt{3}}{2} {V}_{2} sin ( {ω}_{2} t - \frac{1}{2} π ) = 0 & ( 5 )\end{matrix}$$

By assigning the phases and the amplitudes in such a manner, the cancellation of the superimposed powers is broken when two power electronics devices even in any combination among the plurality of power electronics devices stops, and thus the detector 113 can detect the superimposed powers. For this reason, when the two power electronics device even in any combination stop, the determiner 1141b can detect the stop thereof.

### (Assignment of Phases and Amplitudes)

To choice amplitudes and phases such that a plurality of power electronics devices cancel out their superimposed powers, drawing a composite diagram makes it easy to understand, the composite diagram showing vectors each having an angle and a length corresponding to the phase and the amplitude (hereafter, referred to as a superimposed power vector). For example, the phase assigner 1144 may determine whether the superimposed powers output from the plurality of power electronics devices cancel out based on whether a graph connecting superimposed power vectors of the respective power electronics devices forms a loop.

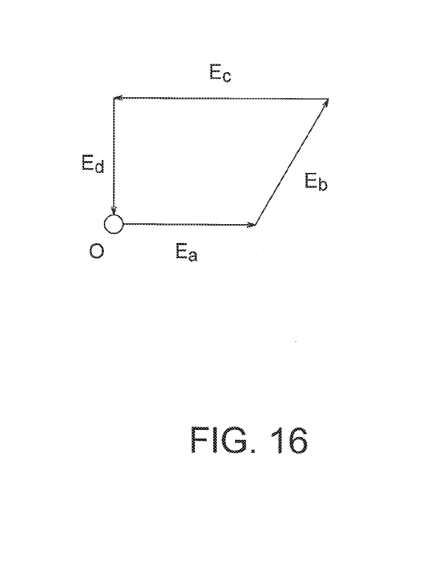

FIG. 16 is a diagram into which the vector diagram of FIG. 15 is redrawn, where the superimposed power vectors of the respective power electronics devices are connected. Vectors Ea to Ed are vector having directions and lengths corresponding to the phase and the amplitude of the superimposed powers output from the power electronics devices 12a to 12d. When the vectors Ea to Ed are drawn being connected, if the starting point of the first vector Ea and the ending point of the last vector Ed is the same point, it can be considered that the superimposed powers output from the four devices cancel out one another.

In the example of FIG. 16, Ea to Ed forms a closed loop, which means that the superimposed powers cancel out. The determination of whether the starting point and the ending point of the loop is the same point is equivalent to the determination of whether the composite vector of the used vectors makes zero. For this reason, the phase assigner 1144 desirably determines whether the superimposed powers output from the plurality of power electronics devices cancel out by determining whether the composite vector makes zero.

### (Partial Superimposed Power Cancellation)

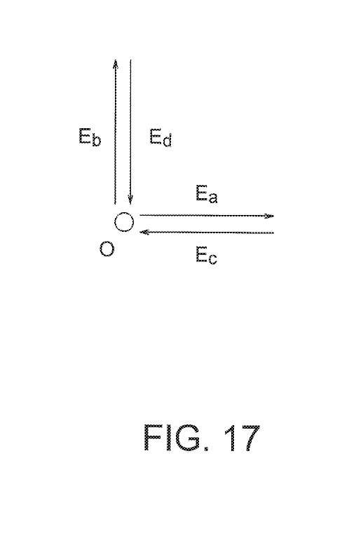

The occurrence of the cancellation by only two power electronics devices among the plurality of power electronics device can be determined by extracting and connecting the superimposed power vectors of only the two devices. In the example of FIG. 14, the vectors Ea and Ec of two power electronics device are extracted and connected into FIG. 17 showing the assignment of the phases and frequencies.

FIG. 17 is a diagram into which the vector diagram of FIG. 14 is redrawn, where the superimposed power vectors of the respective power electronics devices are connected. As shown in FIG. 17, since only the two vectors Ea and Ec form a partial close loop, a simultaneous stop of the power electronics device 12a and the power electronics device 12c has no influence on the cancellation of the superimposed powers by the remaining power electronics device 12b and power electronics device 12d. This means that a system in FIG. 14 consists of two independent partial systems, a pair of the power electronics device 12a and the power electronics device 12c, and a pair of the power electronics device 12b and the power electronics device 12d. The phase assigner 1144 may determine this fact by making a chart or calculating the composite vector.

In such a manner, the phase assigner 1144 may extract a plurality of any power electronics devices from among the plurality of power electronics devices that cancel out their superimposed powers to determine the presence/absence of a partial close loop formed. This enables the prediction of influence in the case where the plurality of power electronics devices simultaneously stop on the cancellation of the superimposed powers in the entire group.

Hereafter, the combination of a plurality of power electronics devices that forms such a close loop is referred to as a partial superimposed power cancellation group. Even in the case where the partial close loop is not formed, a partial loop having a starting point and an ending point within a predetermined range means that the independence of the partial system is high, an accurate determination of which may be difficult depending on the precision of the detector 113 or a processing system.

The calculation of such an assignment of the phases and amplitudes to the superimposed powers may be performed by the phase assigner 1144 of the power electronics device elected as a master or the central control server 21, or performed through negotiation among the power electronics devices using communications. Alternatively, the assignment of the phases and amplitudes to the superimposed powers may be determined by hard coding or an initial setting file. In addition, a similar technique can be applied even when the number of power electronics devices is five or more.

### (First Example of Cancelling Superimposed Powers Using Plurality of Frequencies)

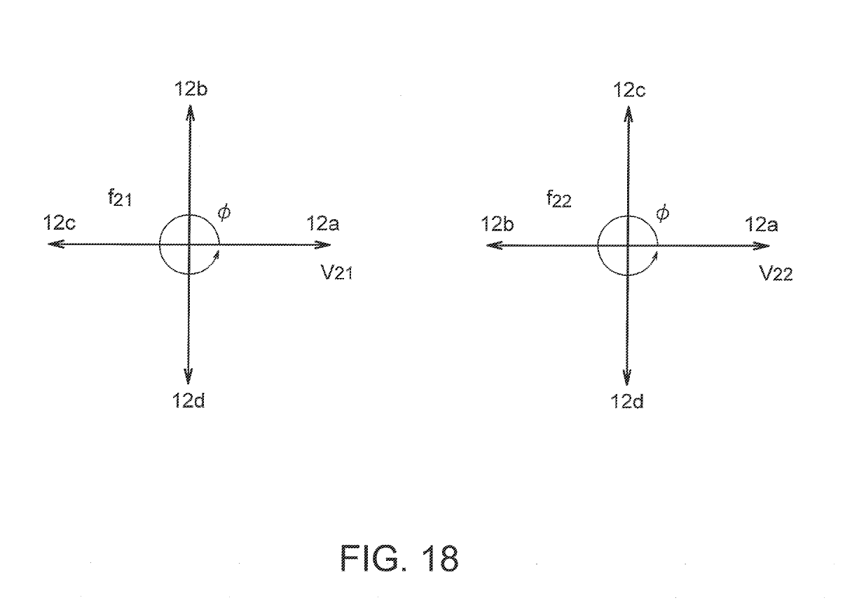

When the number of power electronics devices is large, it may be difficult to assign the amplitudes and phases of the superimposed powers so as to form no group performing partial superimposed power cancellation in any combinations of power electronics devices. In such a case, a plurality of frequencies of superimposed powers may be provided to be used for the cancellation. For example, assume the case where phases are assigned for two frequencies f21 and f22 in a system where four power electronics devices 12a, 12b, 12c, and 12d perform the cooperative action, as shown in FIG. 18.

FIG. 18 is a diagram showing an example of assigning the phases of superimposed powers at the two frequencies f21 and f22. As shown in FIG. 18, at the first frequency f21, a pair of the power electronics device 12a and the power electronics device 12c, and a pair of the power electronics device 12b and the power electronics device 12d form partial superimposed power cancellation groups, respectively. In contrast, at the second frequency f22, a pair of the power electronics device 12a and the power electronics device 12b, and a pair of the power electronics device 12c and the power electronics device 12d form partial superimposed power cancellation groups, respectively.

In such a combination, if the power electronics device 12a and the power electronics device 12c simultaneously stop, the cancellation of the superimposed powers by power electronics devices 12b and 12d still continues in the system of the first frequency f21. For this reason, since the detector 113 cannot detect the superimposed powers at the frequency f21, the determiner 1141b cannot detect the stop of the power electronics device 12a and the power electronics device 12c from the detection signal.

In contrast, in the system of the second frequency f22, the vectors of the power electronics device 12a and the power electronics device 12c are linearly independent. For this reason, if the power electronics device 12a and the power electronics device 12c simultaneously stop, the superimposed power output from the power electronics device 12b is not cancelled out, and the superimposed power output from the power electronics device 12d is not cancelled out either. As a result, the detector 113 detects the superimposed power at the frequency f22, and thus the determiner 1141b can detect the stop of the power electronics device 12a and the power electronics device 12c from the detection signal.

In this example, the phase assigner 1144 assigns, at the first frequency f21, the phase of the superimposed power for each of the plurality of power electronics devices 12a to 12d. As a result of assigning the phases of the superimposed powers, if the superimposed powers output from some of the plurality of power electronics devices among the plurality of power electronics devices 12a to 12d cancel out one another, at the second frequency f22, the phases of the superimposed powers are assigned such that the superimposed powers output from these power electronics devices do not cancel out one another. Note that the phase assigner 1144 may assign the phases of the superimposed powers using three or more kinds of frequencies as needed.

For example, there will be described processing, in the case where the power electronics device 12a is elected as a master, in which the phase assigner 1144 of the power electronics device 12a assigns the phases of the superimposed powers. The phase assigner 1144 assigns, at the first frequency f21, the phases of the superimposed powers to the power electronics device 12a and the plurality of other power electronics devices 12b to 12d. As a result of assigning the phases of the superimposed powers, if the superimposed powers output from some of the plurality of power electronics devices among the power electronics device 12a and the plurality of other power electronics devices 12b to 12d cancel out one another, the phase assigner 1144 assigns, at the second frequency f22 different from the first frequency f21, the phases of superimposed powers to the power electronics device and the plurality of other power electronics devices such that the superimposed powers output from these power electronics devices do not cancel out one another.

In this case, the controller 117b of the power electronics device 12a performs control so as to superimpose the superimposed power at the first frequency f21 having the phase that the phase assigner 1144 assigns to the power electronics device 12a at the first frequency f21 onto the output power from the power electronics device 12a. Furthermore, the controller 117b of the power electronics device 12a perform controls so as to superimpose the superimposed power at the second frequency f22 having the phase that the phase assigner 1144 assigns to the power electronics device 12a at the second frequency f22 onto the output power from the power electronics device 12a.

In addition, the communicator 112 transmits the phases assigned by the phase assigner 1144 at the first frequency f21 to the corresponding other power electronics devices 12b to 12d. In addition, the communicator 112 transmits the phases assigned by the phase assigner 1144 at the second frequency f22 to the corresponding other power electronics devices 12b to 12d.

Then, the controllers 117b of the power electronics device 12b to 12d perform control so as to superimpose electric powers at the first frequency f21 having the phases that the phase assigner 1144 assigns to the power electronics device 12b to 12d at the first frequency f21 onto the power line 28. Furthermore, the controllers 117b of the power electronics device 12b to 12d perform control so as to superimpose electric powers at the second frequency f22 having the phases that the phase assigner 1144 assigns to the power electronics device 12b to 12d at the second frequency f22 onto the power line 28.

### (Second Example of Cancelling Superimposed Powers Using Plurality of Frequencies)

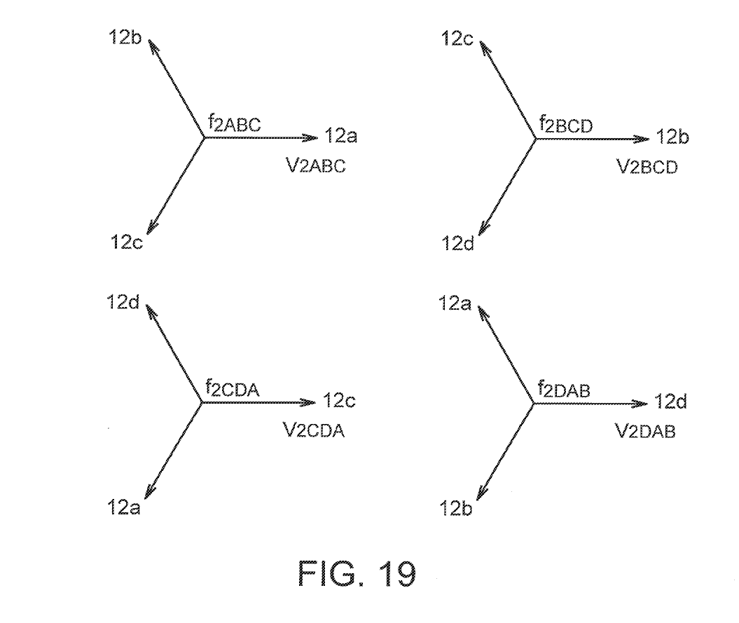

Subsequently, there will be described a second example in which superimposed powers cancel out by a plurality of frequencies with reference to FIG. 19. FIG. 19 is a vector diagram showing an example of the voltages of superimposed powers output from the power electronics devices 12a to 12d at the plurality of frequencies. In the example of FIG. 19, four frequencies f_{2ABC}, f_{2BCD}, f_{2CDA}, and f_{2DAB} are used. Superimposed powers at the frequency f_{2ABC} [Hz] are output from only the power electronics devices 12a, 12b, and 12c, and the power electronics device 12d does not output the superimposed power at the frequency f_{2ABC}. The superimposed powers at the frequency f_{2ABC} [Hz] output from the power electronics devices 12a, 12b, and 12c share an amplitude of V_{2ABC} but have phases that shift from one another by 120 degrees. The superimposed powers at the frequency f_{2ABC} [Hz] output from the power electronics devices 12a, 12b, and 12c are thereby cancelled out. A similar thing is applied to the other three frequencies, at each of which only three power electronics devices output their superimposed powers, and the superimposed powers output from these three power electronics devices share an amplitude but have phases that shift from one another by 120 degrees.

Focusing on the frequency f_{2ABC}, three power electronics devices 12a, 12b, and 12c form a partial superimposed power cancellation group. In contrast, since the power electronics device 12d does not output the superimposed power at the frequency f_{2ABC}, which can be considered that the single device forms a partial superimposed power cancellation group.

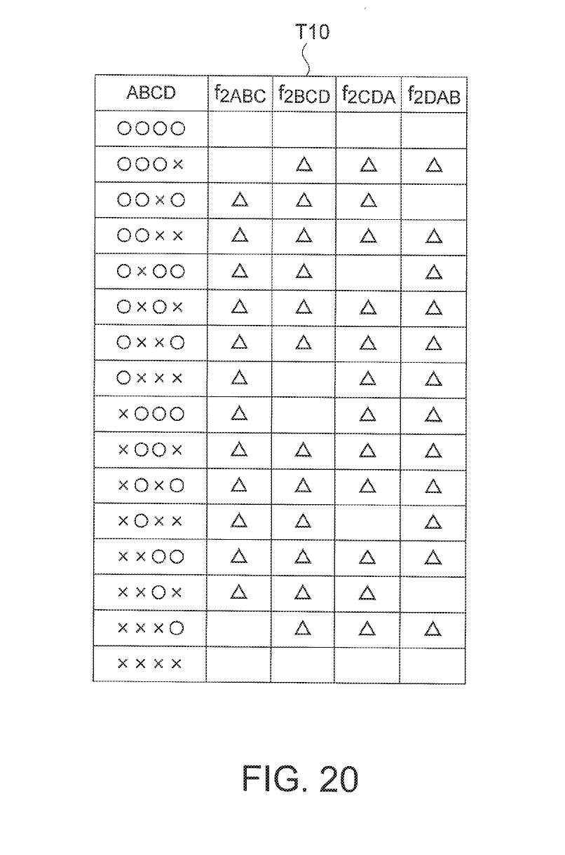

FIG. 20 is a table showing the work/stop statuses of the four power electronics devices 12a to 12d and the cancelling statuses of frequencies of the corresponding superimposed powers. In a table T10 of FIG. 20, “W” denotes being in working, and “S” denotes being in stopping. In addition, a column without a mark indicates a status in which the superimposed powers cancel out, and a column with “B” indicates a status in which the cancellation of the superimposed powers is broken.

For example, “WWWS” in the second row indicates that the power electronics devices 12a, 12b, and 12c are in working and the power electronics device 12d is in stopping, when the superimposed powers cancel out at the frequency f_{2ABC} while the cancellation of the superimposed powers is broken at the frequencies f_{2BCD}, f_{2CDA}, and f_{2DAB}.

An identifying method of a stopping power electronics device will be described below assuming that the table T10 is stored in the storage 111.

For example, assume the case where the detector 113 of the power electronics device 12a detects superimposed powers at the frequencies f_{2BCD}, f_{2CDA}, and f_{2DAB}. In this case, the determiner 1141b of the power electronics device 12a refers to the table T10 of FIG. 20 to find that the power electronics device 12d may be in stopping and the three power electronics devices 12a, 12b, and 12c may be in stopping. Here, the three power electronics devices 12a, 12b, and 12c is found not to be in stopping since the device itself is in working, and thus the determiner 1141b of the power electronics device 12a identifies the power electronics device 12d as a power electronics device being in stopping.

In contrast, assume the case where the detector 113 of the power electronics device 12d detects superimposed powers at the frequencies f_{2BCD}, f_{2CDA}, and f_{2DAB}. In this case, the determiner 1141b of the power electronics device 12d refers to the table T10 of FIG. 20 to find that the power electronics device 12d may be in stopping and the three power electronics devices 12a, 12b, and 12c may be in stopping. Here, the power electronics device 12d is found not to be in stopping since the device itself is in working, and thus the determiner 1141b of the power electronics device 12d identifies the three power electronics devices 12a, 12b, and 12c as power electronics devices being in stopping.

In such a manner, if the number of stopping power electronics devices is one or three, the determiner 1141b can immediately identify the stopping power electronics device(s) by referring to the table T10 in the storage 111.

If the number of stopping power electronics devices is two, the determiner 1141b cannot identify the stopping power electronics devices only by referring to the table T10 in the storage 111. Even in this case, the occurrence of any abnormality can be detected since the cancellation of frequencies is broken, and thus when the detector 113 detects a superimposed power at any frequency, the communicator 112 transmits a request signal to request a response to the plurality of other power electronics devices, using this detection as a trigger. If the communicator 1121 cannot receive a response signal corresponding to the request signal from a certain power electronics device, the determiner 1141b identifies this power electronics device as a stopping power device. The stopping power device can be thereby quickly identified.

Note that, in the example of FIG. 19, the four frequencies are used for the four power electronics devices, the number of frequencies may be five or more, or three or less. In addition, in the example of FIG. 19, the description has been made about the example where the number of power electronics devices is four, but the example can be applied to the case of five or more power electronics devices and the case of three or less power electronics devices.

In this case, for example, the frequency decider 1142 selects N combinations from a number N−1 of power electronics devices from among a number N of power electronics devices, such that the combinations are different from one another. Then, the frequency decider 1142 assigns a different frequency as a frequency of a superimposed power for each of the combinations from the number of N−1 power electronics devices. A number N of different frequencies are thereby assigned since the number of combinations from the number N−1 of power electronics devices is N.

Then, the phase assigner 1144 determines, for each of the combinations from the number N−1 of power electronics devices, the phases and the amplitudes of the superimposed powers output from these power electronics devices such that the superimposed powers output from these power electronics devices cancel out one another.

### (Feedback Control of Cancellation of Superimposed Powers)

In the case of intending the cancellation of superimposed powers using a plurality of power electronics devices, it may be difficult to completely cancel out the superimposed powers by open-loop control. Hence, power electronics devices in a second modification of the second embodiment perform feedback control on their superimposed powers so as to completely cancel out their superimposed powers.

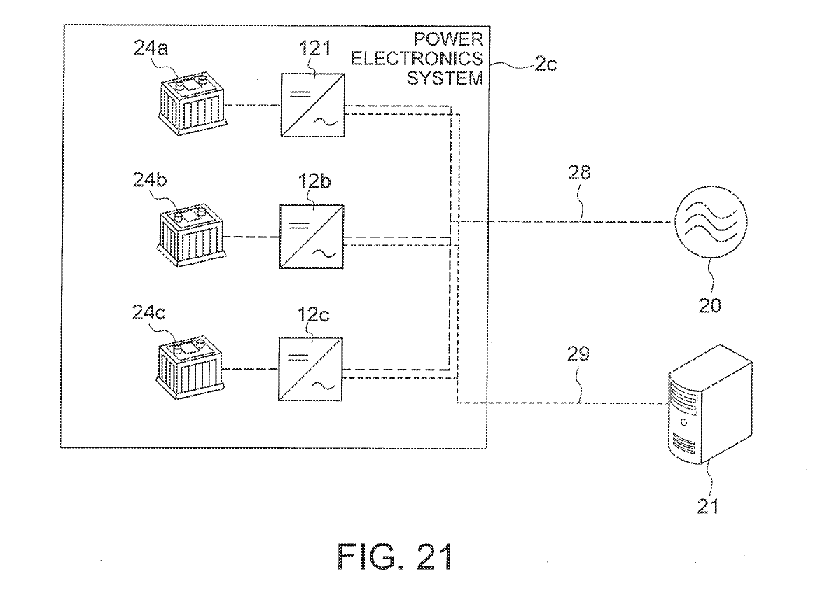

FIG. 21 is a diagram showing the configuration of a power electronics system 2c in the second modification of the second embodiment. Note that components common to those of FIG. 13 will be denoted by the same reference characters, and the specific descriptions thereof will not be described. As shown in FIG. 21, the configuration of the power electronics system 2c in the second modification of the second embodiment is a configuration in which, as compared with the configuration of the power electronics system 2 in the second embodiment of FIG. 13, the power electronics device 12a is changed to a power electronics device 121. That is, the power electronics device 12b and the power electronics device 12c do not perform control on the superimposed powers, but the incorporated controllers 117b perform control so as to superimpose their electric powers. In contrast, the power electronics device 121 performs the feedback control on the superimposed powers so as to cancel out the superimposed powers. In addition, in this second modification, the superimposed powers cancel out with the assignment of phases and amplitudes similar to FIG. 12.

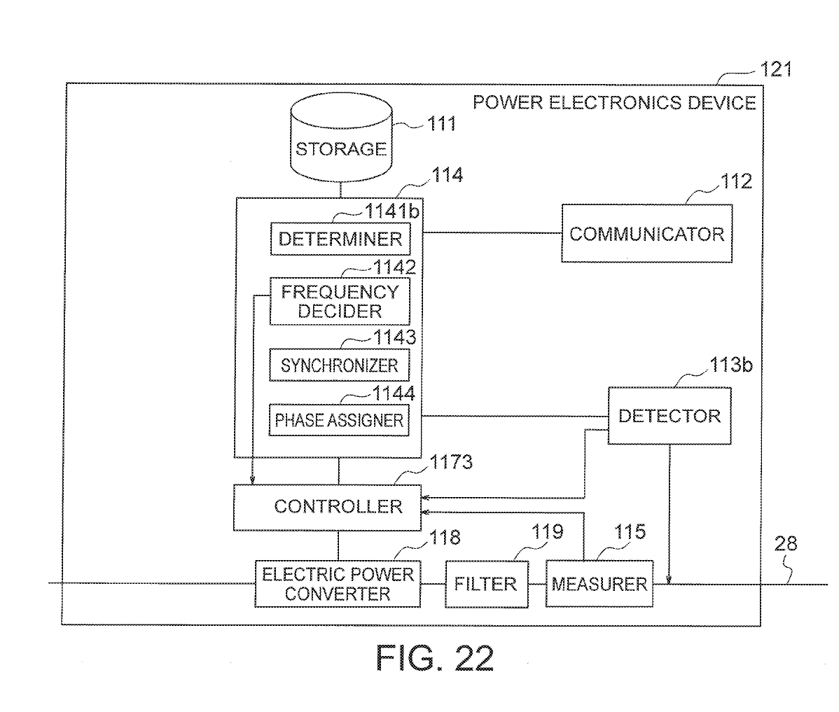

Subsequently, the configuration of the power electronics device 121 will be described with reference to FIG. 22. FIG. 22 is a diagram showing the configuration of the power electronics device 121 in the second modification of the second embodiment. Note that components common to those of FIG. 11 will be denoted by the same reference characters, and the specific descriptions thereof will not be described. As shown in FIG. 22, the configuration of the power electronics device 121 is a configuration in which, as compared with the configuration of the power electronics device 12 of FIG. 11, the detector 113 is changed to a detector 113b, and the controller 117b is changed to a controller 1173.

The detector 113b has a function similar to that of the detector 113 in the second embodiment and further has the following function. The detector 113b detects the voltage of a three-phase superimposed power on the power line 28 and outputs a voltage signal indicating the voltage of the three-phase superimposed power to the controller 1173.

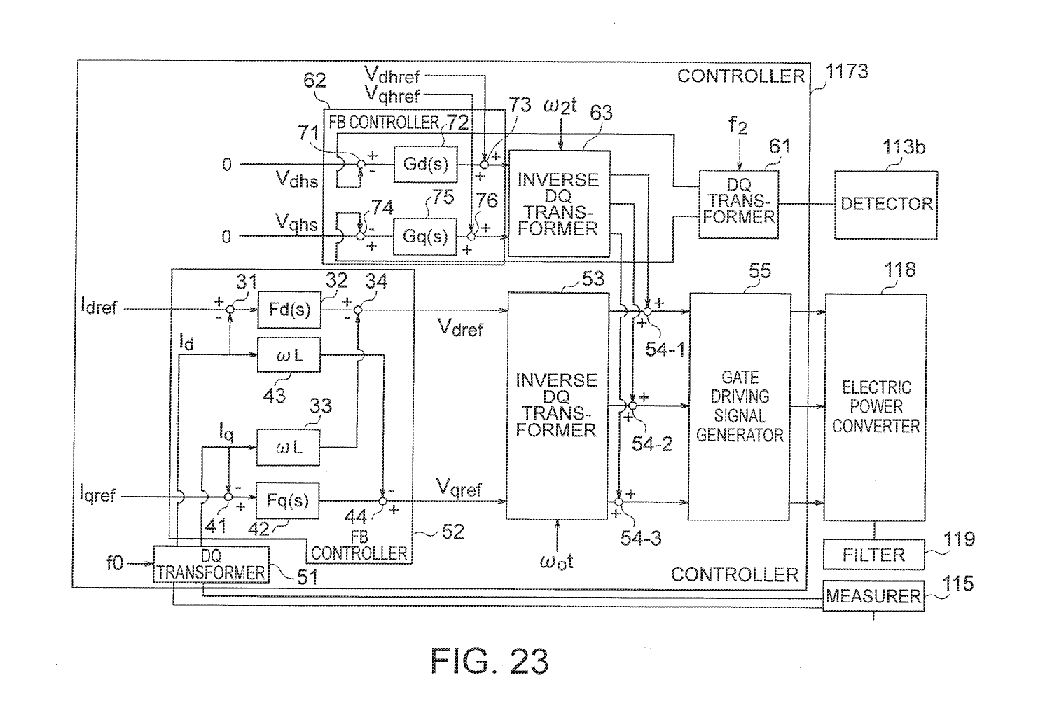

In addition to the function that the controller 117b in the second embodiment has, the controller 1173 performs the feedback control such that the frequency components of electric powers, detected by the detector 113b, which the other power electronics devices superimpose onto their output power make zero. Here, the configuration of the controller 1173 will be described with reference to FIG. 23. FIG. 23 is a diagram showing the configuration of the controller 1173 in the second modification of the second embodiment. Note that components common to those of FIG. 5 will be denoted by the same reference characters, and the specific descriptions thereof will not be described. The configuration of the controller 1173 of FIG. 23 has a configuration, as compared with the configuration of the controller 117 of FIG. 5, in which a dq transformer 61, a FB controller 62, and an inverse dq transformer 63 are added.

The dq transformer 61 subjects the three-phase superimposed voltage indicated by the voltage signal input from the detector 113b to dq transformation using the frequency f₂ of the superimposed voltage, into a detected value V_{dhs} of the d-axis component of the superimposed voltage (hereafter, referred to as a d-axis detected value) and a detected value V_{qhs} of the q-axis component of the superimposed voltage (hereafter, referred to as a q-axis detected value). The dq transformer 61 outputs these d-axis detected value V_{dhs} and the q-axis detected value V_{qhs} to the FB controller 62.

Here, when the superimposed powers properly cancel out, the composite wave of the superimposed powers output from the three power electronics devices 121, 12b, and 12c makes zero. At this point, the d-axis detected value V_{dhs} and the q-axis detected value V_{qhs} are both zero. Therefore, the target value of the d-axis component of the superimposed voltage and the target value of the q-axis component of the superimposed voltage are both set at zero.

The FB controller 62 performs the feedback control such that the frequency component of the electric powers that the other power electronics devices superimpose onto their output powers contained in the detection signal becomes the target value (here, zero as an example). For example, the FB controller 62 performs, for example, PI control on the difference value between the target value of the superimposed voltage and the detected value of the superimposed voltage for each of the d-axis component and the q-axis component. Here, the FB controller 62 includes a subtractor 71, a multiplier 72, an adder 73, a subtractor 74, a multiplier 75, and an adder 76.

The subtractor 71 subtracts the d-axis detected value V_{dhs} from zero that is the target value of the d-axis component of the superimposed voltage input from the dq transformer 61 and outputs a difference value obtained by the subtraction to the multiplier 72.

The multiplier 72 multiplies the difference value input from the subtractor 71 by a transmission function Gd(s) and outputs a value obtained by the multiplication to the adder 73.

The adder 73 adds a feedforward term V_{dhref} to the value input from the multiplier 72 and outputs a value obtained by the addition to the inverse dq transformer 63. Here, this feedforward term V_{dhref} is the d-axis component of a voltage corresponding to the superimposed power vector of the power electronics device 11a of FIG. 12. Note that this feedforward term V_{dhref} is dispensable.

The subtractor 74 subtracts the q-axis detected value V_{qhs} input from the dq transformer 61 from zero that is the target value of the q-axis component of the superimposed voltage and outputs a difference value obtained by the subtraction to the multiplier 75.

The multiplier 75 multiplies the difference value input from the subtractor 74 by a transmission function Gq(s) and outputs a value obtained by the multiplication to the adder 76.

The adder 76 adds a feedforward term V_{qhref} to t the value input from the multiplier 75 and a value obtained by the addition to the inverse dq transformer 63. Here, this feedforward term V_{qhref} is the q-axis component of the voltage corresponding to the superimposed power vector of the power electronics device 11a of FIG. 12. Note that this feedforward term V_{dhref} is dispensable.

The inverse dq transformer 63 performs inverse dq transformation using the value input from the adder 73, the value input from the adder 76, and a phase ω₂t. This yields a three-phase superimposed voltage. Here, ω₂ (=2πf₂) is an angular frequency of the superimposed voltage.

The inverse dq transformer 63 outputs the superimposed voltage of a first phase out of the obtained three-phase superimposed voltage to an adder 54-1, outputs the superimposed voltage of a second phase to an adder 54-2, and outputs the superimposed voltage of a third phase to an adder 54-3.

Note that the configuration of the controller 1173 is not limited to this. Without the inverse dq transformer 63, an output in the d axis out of the output of the FB controller 62 may be added to a current target value I_{dref}, and an output in the q axis out of the output of the FB controller 62 may be added to a current target value I_{qref}.

In such a manner, the controller 1173 performs the feedback control such that the frequency component of the electric powers, contained in the detection signal, which the other power electronics devices superimpose onto their output powers becomes the target value. Harmonics can be thereby continuously reduced if all the three power electronics devices 121, 12b, and 12c properly work. As a result, in the second modification of the second embodiment, as compared with the main body of the second embodiment, it is possible to continuously reduce disturbances to the electric power system 20.

### Third Embodiment

### Superimposed Power/Time-Sharing Scheme

Subsequently, a third embodiment will be described. In the first embodiment, a plurality of power electronics devices superimpose electric powers at frequencies different from one another. In contrast, in the third embodiment, a plurality of power electronics devices superimpose electric powers at the same frequency at time points different from one another. At the same time, the plurality of power electronics devices continuously monitor the presence/absence of any electric power at the above-described frequency.

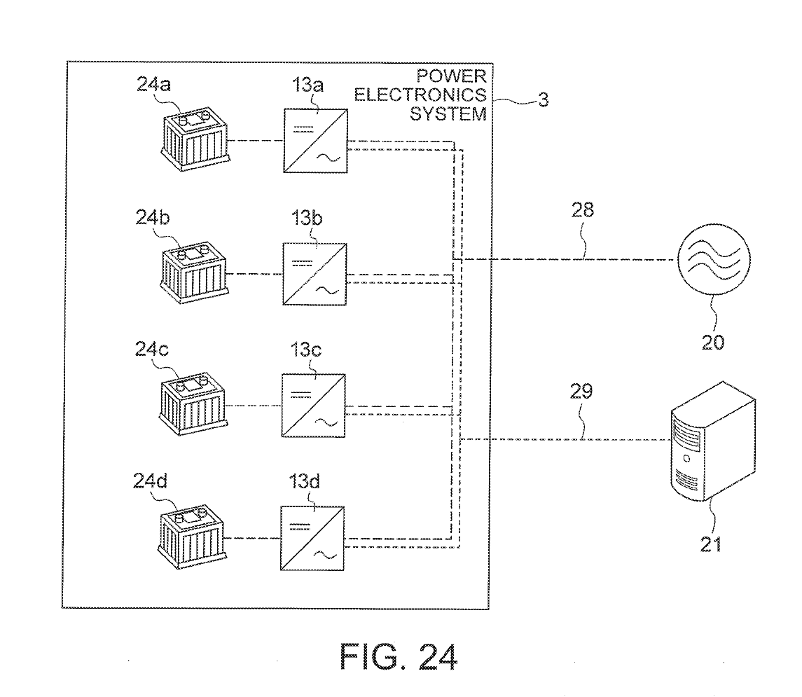

Subsequently, the configuration of a power electronics system 3 in the third embodiment will be described with reference to FIG. 24. FIG. 24 is a diagram showing the configuration of the power electronics system 3 in the third embodiment. Note that components common to those of FIG. 1 will be denoted by the same reference characters, and the specific descriptions thereof will not be described. As shown in FIG. 24, the configuration of the power electronics system 3 in the third embodiment is a configuration in which, as compared with the configuration of the power electronics system 1 in the first embodiment of FIG. 1, the power electronics devices 11a to 11d are changed to power electronics devices 13a to 13d, respectively. Hereafter, the power electronics devices 13a to 13d are collectively referred to as a power electronics device 13.

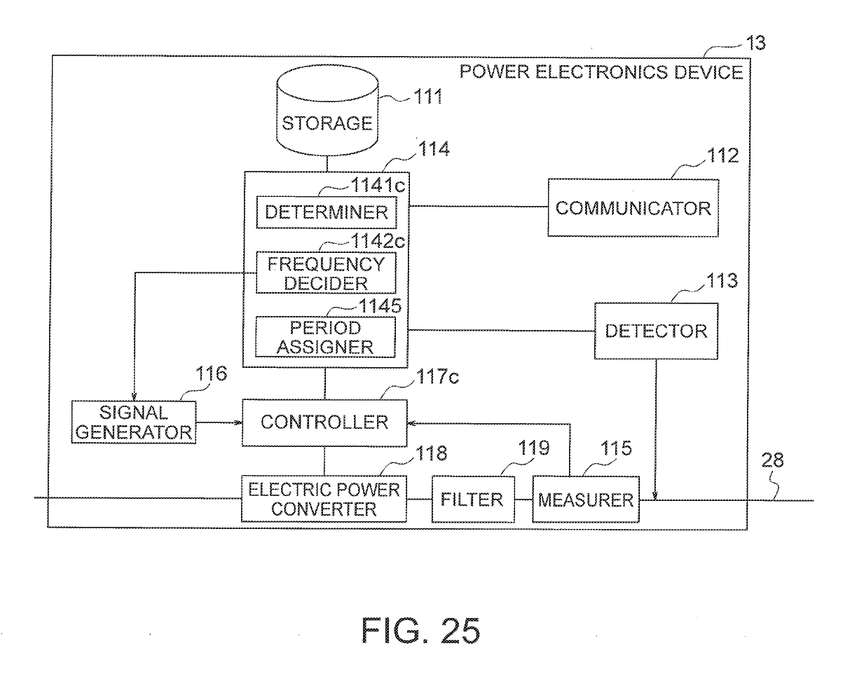

Subsequently, the configuration of the power electronics device 13 will be described with reference to FIG. 25. FIG. 25 is a diagram showing the configuration of the power electronics device 13 in the third embodiment. Note that components common to those of FIG. 4 will be denoted by the same reference characters, and the specific descriptions thereof will not be described. As shown in FIG. 25, the configuration of the power electronics device 13 in the third embodiment is a configuration in which, as compared with the configuration of the power electronics device 11 in the first embodiment of FIG. 4, the frequency decider 1142 is changed to a frequency decider 1142c, the controller 117 is changed to a controller 117c, the determiner 1141 is changed to a determiner 1141c, and a period assigner 1145 is added.

The frequency decider 1142c of the power electronics device 13a determines a frequency identical to the frequency of a superimposed power output from the power electronics device 13a as the frequency of superimposed powers output from the other power electronics devices 13b to 13d. The power electronics device 13a shares the determined frequency of the superimposed power with the other power electronics devices 13b to 13d. A sharing method may be one in which the frequency of the superimposed power is directly written in a program in the storage 111 by hard coding. Alternatively, the power electronics devices 13a to 13d each may hold a setting file in which the frequency of the superimposed power is written in advance in the storage 111. Alternatively, the communicator 112 may share the frequency of the superimposed power with the other power electronics devices 13b to 13d using communications. This causes the same information indicating the frequency of the superimposed power to be stored in the storages 111 of power electronics devices 13a to 13d.

The controller 117c performs control so as to superimpose a second electric power onto the output power of the power electronics device during a second period different from a first period during which the other power electronics devices superimpose first electric powers onto their output powers. In the present embodiment, as an example, the frequency of the first electric powers superimposed during the first period and the frequency of the second electric power superimposed during the second period are the same. In this case, the determiner 1141c determines the states of the other power electronics devices based on a harmonic component during the first period contained in the detection signal.

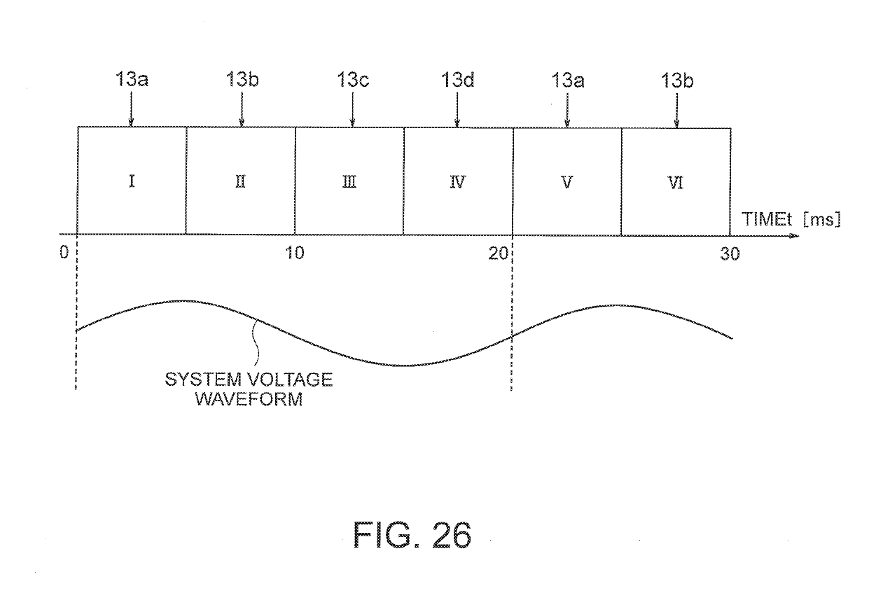

The period assigner 1145 divides an output duration during which the output of superimposed powers is continued into a plurality of periods and assigns the divided periods to the power electronics devices 13a to 13d, respectively. More specifically, for example, the period assigner 1145 may create, as shown in FIG. 26, time-sharing blocks and assign the time-sharing blocks to the corresponding power electronics devices 13a to 13d.

FIG. 26 shows an example of the time-sharing blocks. As shown in FIG. 26, setting the system voltage of the electric power system 20 as a reference, the output duration is divided into the plurality of time-sharing blocks, setting a time period (5 ms), into which one cycle (20 ms) of the system voltage is divided by four that is the number of power electronics devices 13a to 13d, to one time-sharing block. Then, the assignment of the time-sharing blocks to the power electronics devices 13a, 13b, 13c, and 13d in turn is repeated. More specifically, a time-sharing block I is assigned to the power electronics device 13a, the next time-sharing block II is assigned to the power electronics device 13b, the next time-sharing block III is assigned to the power electronics device 13c, and the next time-sharing block IV is assigned to the power electronics device 13d. From this point forward, the time-sharing blocks are repeatedly assigned in turn starting from the power electronics device 13a.

The period assigner 1145 outputs a period signal indicating the period of the time-sharing block assigned to the device itself to the controller 117c. This causes the controller 117c to perform control so as to superimpose the second electric power onto its electric power during the period indicated by the period signal. Then, the controller 117c of each power electronics device superimposes the second electric power (e.g., at a frequency f3 [Hz]) onto an electric power to be output to the power line 28 during the period of the time-sharing block assigned to the device itself. In addition, the determiner 1141c of each power electronics device concurrently and continuously monitors the presence/absence of an electric power at the frequency f3 [Hz] in the detection signal obtained through the detection performed by the detector 113.

If there is no power component of frequency f3 [Hz] in the detection signal detected by the detector 113, the determiner 1141c determines that a power electronics device to which the time-sharing block containing the timing of detection is assigned is stopping. By applying the time-sharing in such a manner, alive information on a plurality of power electronics devices can be carried on one kind of frequency. Note that the technique of the above-described time-sharing may be used in combination with embodiments to be described hereafter.

Note that, at the time of outputting the superimposed powers or the block division, guarding periods may be provided such that the output timings of the superimposed powers do not overlap. At the time of the division into time-sharing blocks, the system voltage is not necessarily set as the reference. In particular, in uses such as a DC system or a motor driving system, where the system voltage cannot be set as a reference, the other voltage may be set as the reference.

In addition, the amount of a time-sharing block assignment and/or the duration of the time-sharing block may be variable according to the amount of output or the importance of each power electronics device 13. This time-sharing block assignment may be performed by the period assigner 1145 of the power electronics device elected as the master, or a central control server (not shown). Alternatively, each power electronics device 13 may autonomously determine a time-sharing block to be assigned to the device itself under a predetermined volatility.

As described above, in the third embodiment, the controller 117c performs control so as to superimpose the second electric power onto the output power from the power electronics device during the second period different from the first period during which the other power electronics devices superimpose the first electric powers onto their output powers. Then, the determiner 1141c determines the states of the other power electronics devices based on the frequency component of the above-described first electric powers in the first period contained in the detection signal. Here, the frequency of the first electric powers superimposed during the first period and the frequency of the second electric power superimposed during the second period are the same. This enables both the determination of states of the other power electronics devices by the device itself and the determination of the state of the device itself by the other power electronics devices, using one frequency.

### (Spread Spectrum)

Note that, the power electronics devices in the present embodiment may employ spread spectrum (SS) to high frequencies. Employing the spread spectrum enables enhanced immunity to noise or interfering frequencies mixing in from the surrounding environment.

For example, in the case of using frequency hopping (FHSS), which is an example of the spread spectrum, the power electronics device 13a shares the changing schedule (hopping sequence) of frequencies of superimposed powers to be output with the other power electronics devices 13b to 13d.

A sharing method may be one in which the same hopping sequence is directly written in a program in the storage 111 by hard coding. Alternatively, the power electronics devices 13a to 13d each may hold a setting file in which the same hopping sequence is written in advance in the storage 111. Alternatively, the power electronics device 13a may generate the hopping sequence using random numbers and share the hopping sequence with the other power electronics devices 13b to 13d using communications. This causes the same information on the hopping sequence to be stored in the storages 111 of the power electronics devices 13a to 13d.

When the power electronics device 13a starts its operation, the frequency decider 1142c of the power electronics device 13a changes the frequency of a superimposed power to be output based on, for example, its own hopping sequence every certain period of time. The determiners 1141c of the power electronics devices 13b to 13d each change the frequency to be monitored based on the hopping sequence shared with the power electronics device 13a to determine the state of the power electronics device 13a.

In such a manner, the other power electronics device 13a changes the frequency of the electric power that the other power electronics devices 13a superimposes onto its output power with time according to the prescribed changing schedule.

The determiners 1141c of the power electronics devices 13b to 13d change the frequency to be monitored with this changing schedule and determine the state of the other power electronics devices 13a based on the frequency component to be monitored contained in the detection signal.

It is thereby possible, if noise at a specified frequency is superimposed onto the output power from the surrounding environment, to perform monitoring avoiding the specified frequency by changing the frequency to be monitored with time. For this reason, it is thereby possible to determine the state of the other power electronics device even if the noise at the specified frequency is superimposed onto the output power.

Note that, as a technique similar to direct sequence spread spectrum (DSSS), which is an example of the spread spectrum, the power electronics device 13a may simultaneously superimpose an electric power at two or more kinds of frequencies at the time of superimposing the electric power.

Note that these techniques of the spread spectrum may be applied to embodiments to be described hereafter.

### (Combination of Time-Sharing and Frequency Hopping)

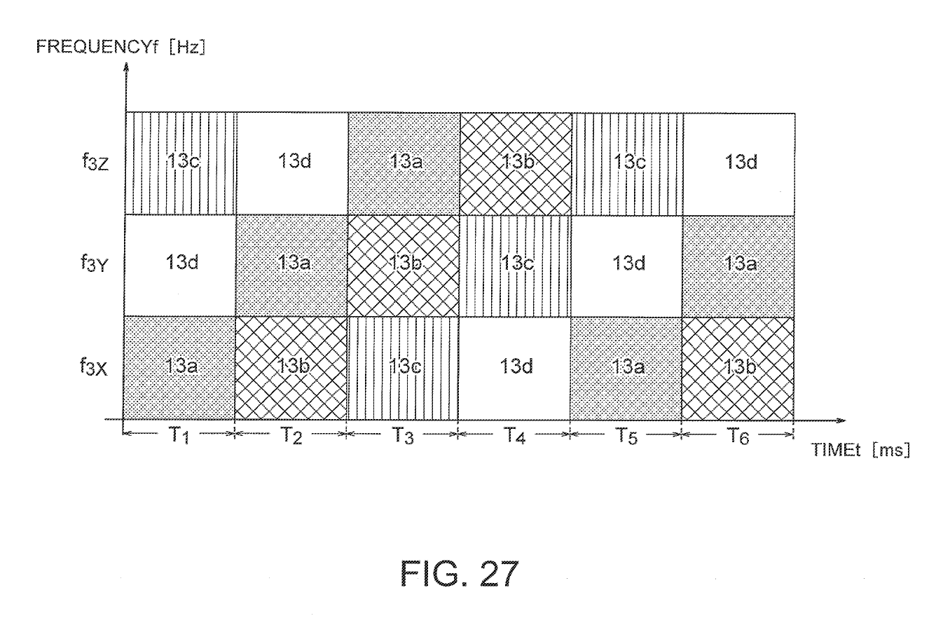

Note that the method of assigning the frequency by the time-sharing may be combined with the spread spectrum. There will be described the transition of frequency in the case of combining the time-sharing assignment of frequency with the frequency hopping with reference to FIG. 27. FIG. 27 is a diagram showing an example of the frequency transition of the superimposed powers in the case where the time-sharing assignment of frequency is combined with the frequency hopping.

As shown in FIG. 27, three kinds of frequencies f_{3X}, f_{3Y}, and f_{3Z} are assigned to three different power electronics devices among the power electronics devices 13a to 13d every certain period. In addition, the frequencies assigned to each power electronics devices are shifted in turn every certain period. For example, during a period T1, the frequency f_{3X} is assigned to the power electronics device 13a, and during the next period T2, the frequency f_{3Y} that is one stage higher than the frequency f_{3X} is assigned to the power electronics device 13a. Then, during the next period T3, the frequency f_{3Z} that is one stage even higher than the frequency f_{3Y} is assigned to the power electronics device 13a, and the next period T4, no frequency is assigned to the power electronics device 13a.

Then, the controller 117c performs control, during a period in which the frequency is assigned thereto, so as to superimpose an electric power at the assigned frequency. On the other hand, the controller 117c performs control, during a period in which no frequency is assigned thereto, so as to superimpose no electric power.

Therefore, by assigning the frequencies as shown in FIG. 27, the four power electronics devices 13a to 13d can superimpose electric powers evenly in terms of both frequency and time. It is thereby possible to determine the state of any power electronics device robustly to noise and evenly in terms of time.

The changing schedule of frequencies of the superimposed powers shown in FIG. 27 is shared among the four power electronics devices 13a to 13d. A sharing method to be used may be one similar to the sharing method of the above-described hopping sequence.

The controller 117c performs control so as to superimpose a second electric power onto an electric power to be output to the power line 28, the second electric power being at a frequency that is changed with time and does not overlap the frequency of first electric powers superimposed by the other power electronics devices during the same period.

In this case, the determiner 1141c changes a frequency to be monitored according to the shared changing schedule of frequencies of the superimposed powers and determines states of the other power electronics devices based on the frequency component to be monitored contained in the detection signal.

It is thereby possible, if noise at a specified frequency is superimposed onto the output power from the surrounding environment, to perform monitoring avoiding the specified frequency by changing the frequency to be monitored with time. Furthermore, since the superimposed electric power is at frequency that is always different from the frequency of the first electric power superimposed by the other power electronics device, it is possible to avoid a situation where the electric power superimposed by the other power electronics device cannot be detected. For this reason, it is possible to determine the state of the other power electronics device even if the noise at the specified frequency is superimposed onto the output power and the other power electronics device superimposes its electric power.

### (Time-Sharing Assignment of Phase)

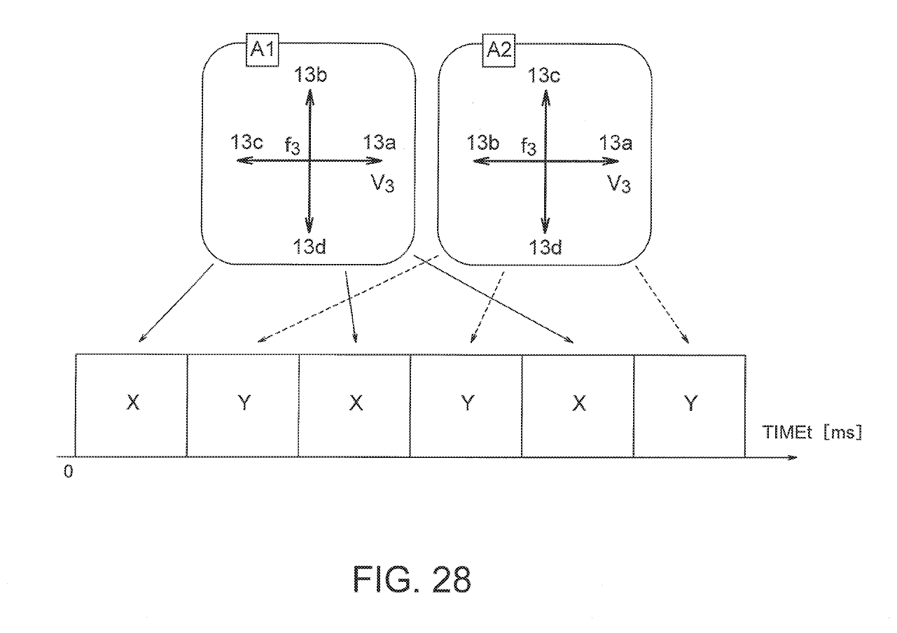

The assignment of frequencies or phases by the time-sharing may be applied to the partial superimposed power cancellation group described in the second embodiment. This will be described with reference to FIG. 28. FIG. 28 is a diagram showing an example of assigning the phases of superimposed powers to the power electronics devices by the time-sharing. The time axis is divided into two kinds of time-sharing blocks X and Y. During the period of a time-sharing block X, the phase assignment to the four power electronics devices 13a to 13d is performed as shown by a vector diagram A1 showing the assignment. That is, the power electronics device 13a and the power electronics device 13c form a partial superimposed power cancellation group, and the power electronics device 13b and the power electronics device 13d form a partial superimposed power cancellation group.

In contrast, in a time-sharing block Y, phase assignment different from that in the time-sharing block X is performed. More specifically, during the period of the time-sharing block Y, the phase assignment to the four power electronics devices 13a to 13d is performed as shown a vector diagram A2 showing the assignment. That is, the power electronics device 13a and the power electronics device 13b form a partial superimposed power cancellation group, and the power electronics device 13c and the power electronics device 13d form a partial superimposed power cancellation group.

In such a manner, the phase assigner 1144 in the second embodiment may assign phases such that a pair of power electronics devices forming a partial superimposed power cancellation group in the time-sharing block X does not form a partial superimposed power cancellation group in the block Y.

In this case, the controller 117b in the second embodiment perform control so as to superimpose an electric power at a phase that is different by 180 degrees from the phase of a first electric power superimposed by a first power electronics device, onto an electric power to be output to the power line 28 during a first period (e.g., during the period of a time-sharing block X). Then, the controller 117b performs control so as to superimpose an electric power at a phase that is different by 180 degrees from the phase of a second electric power superimposed by a second power electronics device, onto the electric power output to the power line 28 during a second period different from the first period (e.g., during the period of the time-sharing block Y).

Then, the determiner 1141c determines the state of the first power electronics device based on the frequency component of the first electric power contained in the detection signal during the first period. In contrast, the determiner 1141c determines the state of the second power electronics device based on the frequency component of the second electric power contained in the detection signal during the second period.

In such a manner, the phase assigner 1144 performs the phase assignments during the time-sharing block X and the time-sharing block Y, and the time-sharing block X and the time-sharing block Y are switched in a short time, which can increase the number of pairs of power electronics devices in which superimposed powers can cancel out while only one kind of frequency is used to the superimposed powers. It is thereby possible to increase the number of power electronics devices the states of which can be determined.

### Fourth Embodiment

### Carrier Wave/Frequency Assignment Scheme

Subsequently, a fourth embodiment will be described. A power electronics devices in the fourth embodiment associates, when performing cooperative action with the other power electronics devices, the frequencies of carrier waves that the other power electronics devices use for power conversion (hereafter, referred to as carrier frequencies) with pieces of device identifying information to identify the other power electronics device and monitors the carrier frequency component in electromagnetic noise contained in an electric power output to the power line to determine the state of the other power electronics device.

In general, in devices using chopper control, switching control, pulse width modulation (PWM control), and the like, high-speed on/off of a gate make electromagnetic noise to be output outside the devices. This electromagnetic noise mainly includes a carrier wave frequency component. The greater part of this electromagnetic noise is normally removed by a noise filter circuit such as a capacitor, but even in a filter-processed output after may contain a little noise remaining, which the power electronics device in the present embodiment is to detect.

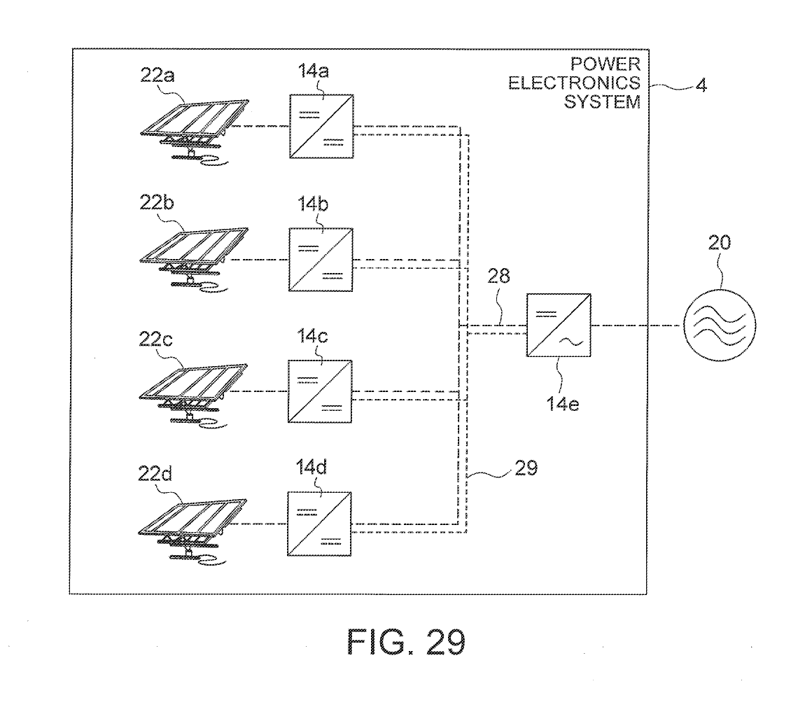

Subsequently, the configuration of a power electronics system 4 in the fourth embodiment will be described with reference to FIG. 29. FIG. 29 is a diagram showing the configuration of the power electronics system 4 in the fourth embodiment. Note that components common to those of FIG. 1 will be denoted by the same reference characters, and the specific descriptions thereof will not be described. As shown in FIG. 29, the configuration of the power electronics system 4 in the fourth embodiment is a configuration in which, as compared with the configuration of the power electronics system 1 in the first embodiment of FIG. 1, the energy storage devices 24a to 24d are changed to generators 22a to 22d, respectively, the power electronics devices 11a to 11d are changed to power electronics devices 14a to 14d, respectively, and a power electronics device 14e is further added.

The generators 22a to 22d are devices that convert various forms of energy into electrical energy, including, for example, photovoltaic (PV) generators using optical energy, hydrogenerators/aerogenerators using fluid energy such as water current and wind flow, thermal generators converting chemical energy such as fossil fuel into electric power, geothermal generators using heat existing in nature, and electric power generators using vibrations or tidal energy. Nuclear power plants or the like are similarly included. The generators often have a configuration in which various energy forms are once converted onto rotary motion, from which electric power is obtained using a synchronous machine, but some electric power generation forms do not depend on kinetic energy, like the photovoltaic generators. The devices may be in a form having a plurality of function, like a device serving both a water heater and a gas thermal generator.

Each of power electronics devices 14a to 14d has an input connected to the corresponding generators 22a to 22d and an output connected to a power electronics device 14e via the power line 28. In addition, the power electronics devices 14a to 14d are connected to one another via the communication line 29 and further connected to the power electronics device 14e via the communication line 29.

The power electronics device 14e has an input connected to the outputs of the power electronics devices 14a to 14d via the power line 28 and an output connected to the electric power system 20.

The power electronics devices 14a to 14d convert DC powers output from the generators 22a to 22d into DC powers (DCDC conversion) and output the converted DC powers to the power line 28. These four converted DC powers are integrated on the power line 28, and the integrated electric power is supplied to the power electronics device 14e.

In contrast, power electronics device 14e converts the DC power input from the power line 28 into an AC power (DCAC conversion) and outputs the converted AC power to the electric power system 20.

The power electronics devices 14a to 14d convert voltages on the generators 22a to 22d side into voltages on the power electronics device 14e side by the chopper control. At this point, the power electronics devices 14a to 14d have specific carrier frequencies f4a to f4d [Hz] that are assigned thereto by some method, respectively, and outputs electric powers containing electromagnetic noises of the carrier frequency components. The carrier frequencies f4a to f4d are, for example, 3.0 [kHz], 3.1 [kHz], 3.2 [kHz], 3.3 [kHz], or the like, respectively. The other power electronics devices 14b to 14e can detect the state of the power electronics device 14a in real time by monitoring the presence/absence of an electromagnetic noise at 3.0 [Hz] emitted by the power electronics device 14a or a change in the ratio of the electromagnetic noise. Hereafter, the power electronics devices 14a to 14e are collectively referred to as a power electronics device 14.

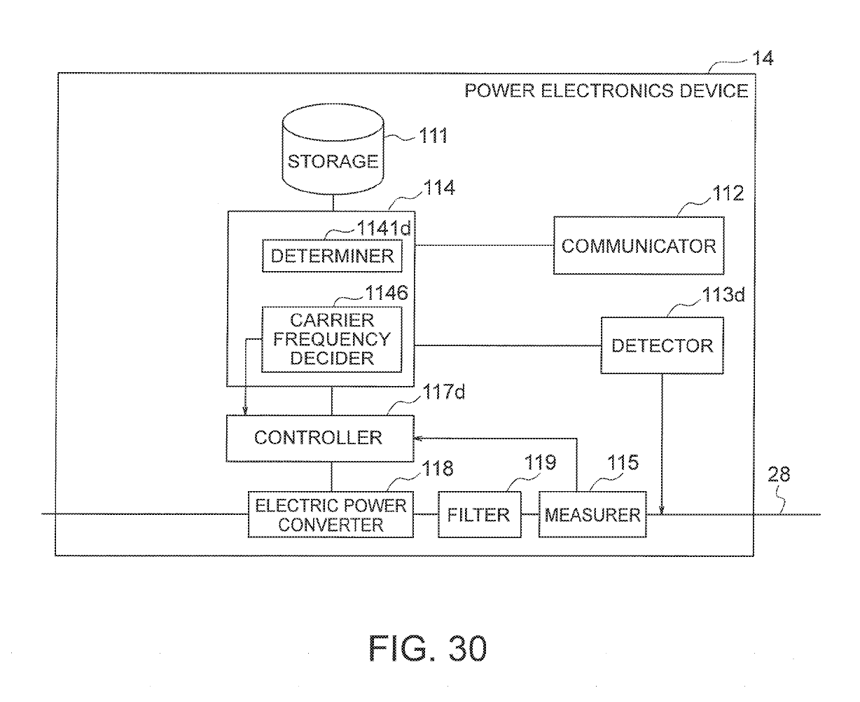

Next, the configuration of the power electronics device 14 in the fourth embodiment will be described with reference to FIG. 30. FIG. 30 is a diagram showing the configuration of the power electronics device 14 in the fourth embodiment. Note that components common to those of FIG. 1 will be denoted by the same reference characters, and the specific descriptions thereof will not be described. As shown in FIG. 30, the configuration of the power electronics device 14 in the fourth embodiment is a configuration in which, as compared with the configuration of the power electronics device 11 in the first embodiment of FIG. 4, the signal generator 116 and the frequency decider 1142 are eliminated, the detector 113 is changed to a detector 113d, the determiner 1141 is changed to a determiner 1141d, a carrier frequency decider 1146 is added, and the controller 117 is changed to a controller 117d.

The detector 113d detects the frequency components of the carrier waves, contained in an electric power flowing in the power line 28, which the other power electronics devices use for the power conversion. The detector 113d outputs a detection signal obtained by the detection to the CPU 114.

The controller 117d controls the output power of the power electronics device, using a carrier wave at a second frequency different from a first frequency of the carrier wave that the other power electronics device uses for the power conversion.

The determiner 1141d determines the state of the other power electronics device based on the first frequency component contained in the electric power detected by the detector 113d. For example, the determiner 1141d determines that the other power electronics device is in a stop state if an electromagnetic noise at the same frequency as the first frequency is less than a threshold value.

The carrier frequency decider 1146 determines the carrier frequency. At this point, the carrier frequency decider 1146 determines a second frequency such that it differs from the first frequency of the carrier wave that the other power electronics device uses for the power conversion. In the present embodiment, as an example, the power electronics device 14a acts as a master device, and the carrier frequency decider 1146 of the power electronics device 14a determines the carrier frequencies of the power electronics devices 14a to 14e such that they do not overlap one another. Then, the carrier frequency decider 1146 of the power electronics device 14a stores the carrier frequencies in the storage 111 after associating them with pieces of device identifying information on power electronics devices to which these carrier frequencies are assigned. The determiner 1141d of the power electronics device 14a can thereby detect a power electronics device being in the stop state by referring to a piece of device identifying information corresponding to the frequency of an electromagnetic noise that is less than the threshold value in the detection signal.

In addition, the carrier frequency decider 1146 outputs the determined carrier frequency of the device itself to the controller 117d. This causes the controller 117d to control its electric power output to the power line 28 using the carrier wave at this carrier frequency.

In addition, the communicator 112 of the power electronics device 14a transmits a signal containing information in which the carrier frequencies is associated with pieces of device identifying information to identify power electronics devices to which these carrier frequencies are assigned, to the other power electronics devices 14b to 14e.

When the communicators 112 of the other power electronics devices 14b to 14e receive this signal from the power electronics device 14a, the carrier frequency deciders 1146 of the other power electronics devices 14b to 14e each store the carrier frequencies in the storage 111 after associating them with the pieces of device identifying information to identify the power electronics devices to which these carrier frequencies are assigned. The determiners 1141d of the power electronics devices 14b to 14e can thereby also detect a power electronics device being in the stop state by referring to a piece of device identifying information corresponding to the frequency of an electromagnetic noise that is less than the threshold value in the detection signal.

However, in the case where the power electronics device is an inverter that outputs an alternating current, and the main component of an output frequency is sufficiently separate from the carrier frequency, it is not need to consider whether the carrier frequency is a multiple of the main component. Here, the main component of the output frequency is, for example, a system frequency in system interconnecting, or the driving frequency of a motor in a motor driving system.

In addition, if one power electronics device emits electromagnetic noises at frequencies other than the electromagnetic noise at the carrier frequency, the carrier frequency decider 1146 determines a frequency as the carrier frequency excluding these frequencies. The power electronics system 4 may include a device other than the power electronics devices 14 in the present embodiment, and it is thus desirable that the detector 113d performs carrier sense before the carrier frequency is selected, and the carrier frequency decider 1146 determines the carrier frequency that the device does not use.

As described above, in the power electronics device 14 in the fourth embodiment, the controller 117d controls its electric power to be output to the power line 28 using the carrier wave at the second frequency different from the first frequency of the carrier wave that the other power electronics device uses for the power conversion. The determiner 1141d determines the state of the other power electronics device based on the first frequency component contained in the electric power detected by the detector 113d.

In such a manner, the determiner 1141d can determines the states of the other power electronics devices using the frequency components of the carrier waves, contained in an electric power flowing in the power line 28, which the other power electronics devices use for the power conversion. For this reason, it is possible to shorten a time taken to determine the states of the other power electronics devices without increasing loads on communications equipment.

Note that, in the present embodiment, as an example, the power electronics device 14a acts as the master device, and the carrier frequency decider 1146 of the power electronics device 14a determines the carrier frequencies of the power electronics devices 14a to 14e such that they do not overlap, but the determining method is not limited thereto.

A central control server (not shown) may determine the carrier frequencies of the power electronics devices 14a to 14e such that they do not overlap and notify the power electronics devices 14a to 14e of the frequencies.

Alternatively, each of the power electronics devices 14a to 14e may notify the other power electronics devices of a carrier frequency to be used and, if the carrier frequency overlaps another one, may use the other frequency.

### Fifth Embodiment

### Carrier Wave/Cancelling Scheme

Subsequently, a fifth embodiment will be described. A power electronics device in the fifth embodiment shifts the phase of a carrier wave thereof among a plurality of power electronics devices such that electromagnetic noises due to switching cancel out one another in the normal operation. If one or more power electronics devices among the plurality of power electronics devices stop, the cancellation of the electromagnetic noises is broken, and thus the electromagnetic noise increases in the output power. For this reason, the power electronics device monitors the presence/absence or an abrupt increase of the electromagnetic noise to detect the presence/absence of a power electronics device in a stop state or an abnormal state.

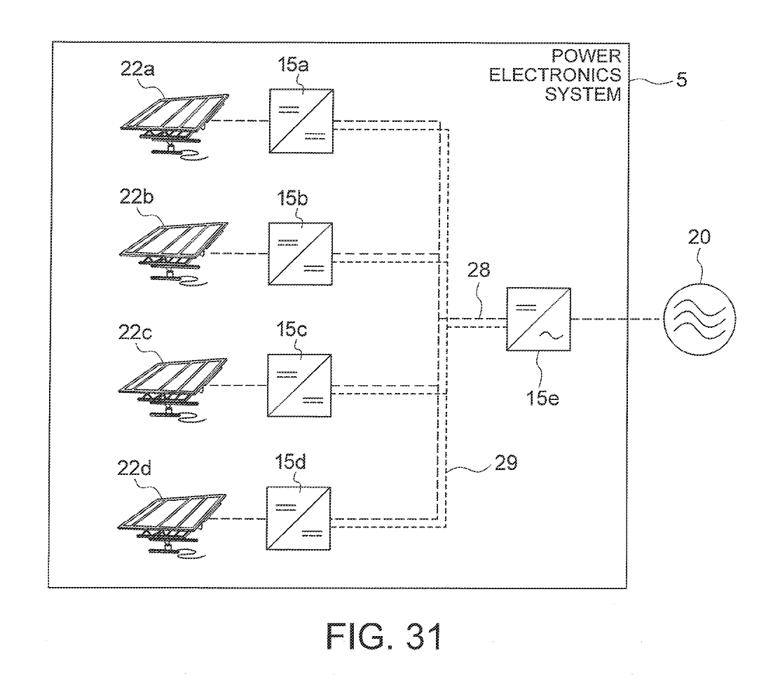

Subsequently, the configuration of a power electronics system 5 in the fifth embodiment will be described with reference to FIG. 31. FIG. 31 is a diagram showing the configuration of the power electronics system 5 in the fifth embodiment. Note that components common to those of FIG. 29 will be denoted by the same reference characters, and the specific descriptions thereof will not be described. As shown in FIG. 31, the configuration of the power electronics system 5 in the fifth embodiment is a configuration in which, as compared with the configuration of the power electronics system 4 in the fourth embodiment in FIG. 29, the power electronics devices 14a to 14e are changed to power electronics devices 15a to 15e, respectively. Hereafter, the power electronics devices 15a to 15e are collectively referred to as a power electronics device 15.

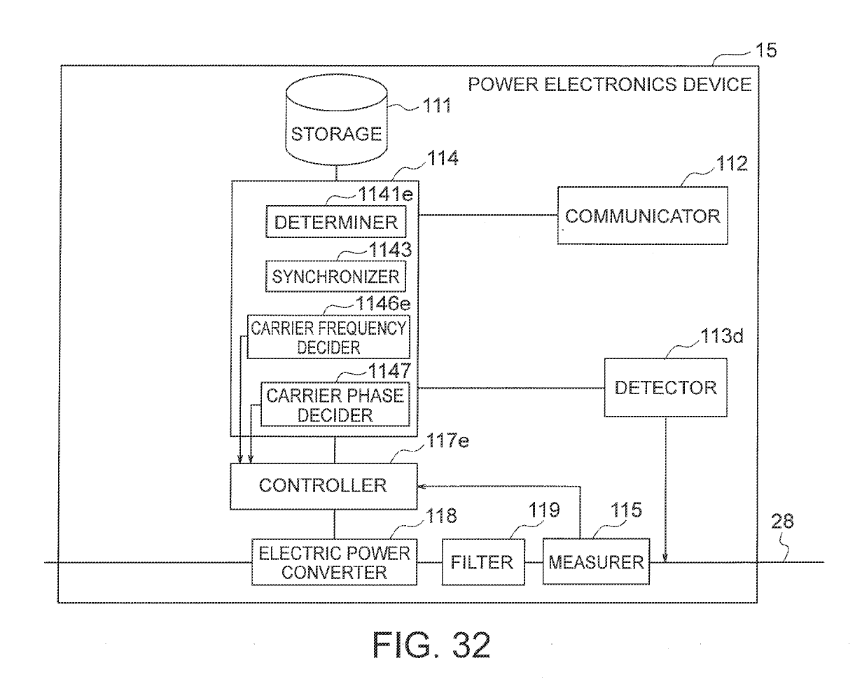

Next, the configuration of a power electronics device 15 in the fifth embodiment will be described with reference to FIG. 32. FIG. 32 is a diagram showing the configuration of the power electronics device 15 in the fifth embodiment. Note that components common to those of FIG. 30 will be denoted by the same reference characters, and the specific descriptions thereof will not be described. As shown in FIG. 32, the configuration of the power electronics device 15 in the fifth embodiment is a configuration in which, as compared to the configuration of the power electronics device 14 in the fourth embodiment in FIG. 30, the determiner 1141d is changed to a determiner 1141e, a synchronizer 1143 is added, the carrier frequency decider 1146 is changed to a carrier frequency decider 1146e, a carrier phase decider 1147 is added, and the controller 117d is changed to a controller 117e.

The synchronizer 1143 performs processing of sharing a timing to be a reference among the power electronics devices in order to shift the phases of the carrier wave among the power electronics devices.

For example, in the case where the power electronics device 15a acts as a master, power electronics device 15a outputs a generated carrier wave to the other power electronics devices 15b to 15e that act as slaves via a copper wire (not shown). This enables the other power electronics devices 15b to 15e to shift the phases of carrier waves used by themselves using this carrier wave as a reference.

Note that any processing may be used as processing to synchronize the carrier waves. For example, the timing of a phase (e.g., phase zero) to be the reference phase of the carrier waves may be transmitted by a radio wave, or the timing of the phase (e.g., phase zero) to be the reference phase of the carrier waves may be transmitted to the other power electronics devices in the form of optical pulses using an optical fiber.

At this point, a first carrier wave (e.g., at a carrier frequency f51=3.0 [kHz]) used for power conversion may be transmitted, and a second carrier wave having an even higher frequency (e.g., at a carrier frequency f52=2.4 [GHz]) may be synchronized using this first carrier wave as the reference.

The carrier frequency decider 1146e determines a carrier frequency to be used such that it becomes the same as a carrier frequency used by the other power electronics devices. For example, if the power electronics device 15a is the master, the power electronics device 15a shares the carrier frequency with the other power electronics devices 15b to 15d. A sharing method is similar to the sharing method of the above-described hopping sequence.

The carrier phase decider 1147 determines the phase of the carrier wave used for the power conversion. For example, if the power electronics device 15a acts as the master, the carrier phase decider 1147 of the power electronics device 15a determines the amplitudes and the phases of the carrier waves used by the power electronics devices 15a to 15d. At this point, the carrier phase decider 1147 of the power electronics device 15a determines the phases of the carrier waves such that electromagnetic noises derived from the carrier waves used by the power electronics devices 15a to 15d partially or totally cancels out one another.

The communicator 112 may distribute the determined phases to the other power electronics devices 15b to 15d through communication. Alternatively, the phases may be hard coded in advance in a program stored in the storages 111 of the power electronics devices 15a to 15d. Alternatively, the phases may be shared by a setting file, in which the phases are written, stored in advance in the storages 111 of power electronics devices 15a to 15d.

The controller 117e controls an electric power to be output to the power line 28 using the second carrier wave such that electromagnetic noises derived from a plurality of first carrier waves that a plurality of other power electronics devices use for the power conversion and an electromagnetic noise derived from the second carrier wave that the power electronics device uses for the power conversion partially or totally cancel out each other. Here, the first carrier wave and the second carrier wave are at the same frequency.

The determiner 117e determines the states of the other power electronics devices based on the frequency component of the first carrier waves contained in the detection signal. For example, if an electromagnetic noise at the same frequency as that of the first carrier waves in the detection signal exceeds a predetermined threshold value, the determiner 117e determines that at least one of the plurality of other power electronics devices is in a stop state or an abnormal state.

As in the present embodiment, in the case where there are a plurality of other power electronics devices and the determiner 117e determines the other power electronics devices are in a stop state or an abnormal state, the determiner 117e may cause the communicator 112 to transmit a request signal to the plurality of other power electronics devices and may identify a power electronics device from which no response with respect to this request signal is received as a power electronics device being in a stop state or an abnormal state.

As described above, in the power electronics device in the fifth embodiment, the controller 117e controls the output power from the power electronics device using the second carrier wave such that the electromagnetic noises derived from the first carrier waves that the other power electronics devices use for the power conversion and the electromagnetic noise derived from the second carrier wave that the power electronics device uses for the power conversion partially or totally cancel out one another. The determiner 1141e determines the states of the other power electronics devices based on the frequency component of the first carrier waves contained in the detection signal.

In such a manner, the determiner 1141e can determine the states of the other power electronics devices. For this reason, it is possible to shorten a time taken to determine the states of the other power electronics devices without increasing a load to communications equipment.

Note that the power electronics system 5 may not include the power electronics device 15c and the power electronics device 15d. In this case, the power electronics device 15a has an output connected to the output of one other power electronics devices 15b by a power line. In this case, the controller 117e of the power electronics device 15a may control an electric power to be output to the power line 28 using a second carrier wave at a phase that is different by 180 degrees from the phase of a first carrier wave that the other power electronics devices 15b uses for the power conversion. Then, the determiner 1141e may determine the state of the other power electronics devices 15b based on the frequency component of the first carrier wave contained in an electric power detected by the detector 113d.

In such a manner, the determiner 1141e can determine the state of the other power electronics devices 15b. For this reason, it is possible to shorten a time taken to determine the state of the other power electronics devices 15b without increasing a load to communications equipment.

### Sixth Embodiment

### Sound/Frequency Assignment Scheme

Subsequently, a sixth embodiment will be described. Power electronics devices in the sixth embodiment, when performing cooperative action among a plurality of power electronics devices, each emit a sound at a specific frequency and monitor sounds emitted by the other power electronics devices. Then, the power electronics device detects that a power electronics device that should emit a sound at a frequency is in a stop state or an abnormal state based on a fact that a sound at the specified frequency disappears or rapidly decreases.

At this point, the power electronics device performs switching action at a carrier frequency, and thus the power electronics device emit a sound at the carrier frequency or a sound at frequencies of harmonics of the carrier frequency in its operation from, for example, a coil or the like. Note that a speaker may be separately provided to emit a sound. In addition, in the present embodiment, as an example, carrier frequencies different from one another are assigned to the power electronics devices, and the power electronics device monitors the sounds at the carrier frequencies assigned to the power electronics devices.

Note that the sound to be monitored may be a beat that occurs by the superposition of sounds at frequencies close to each other.

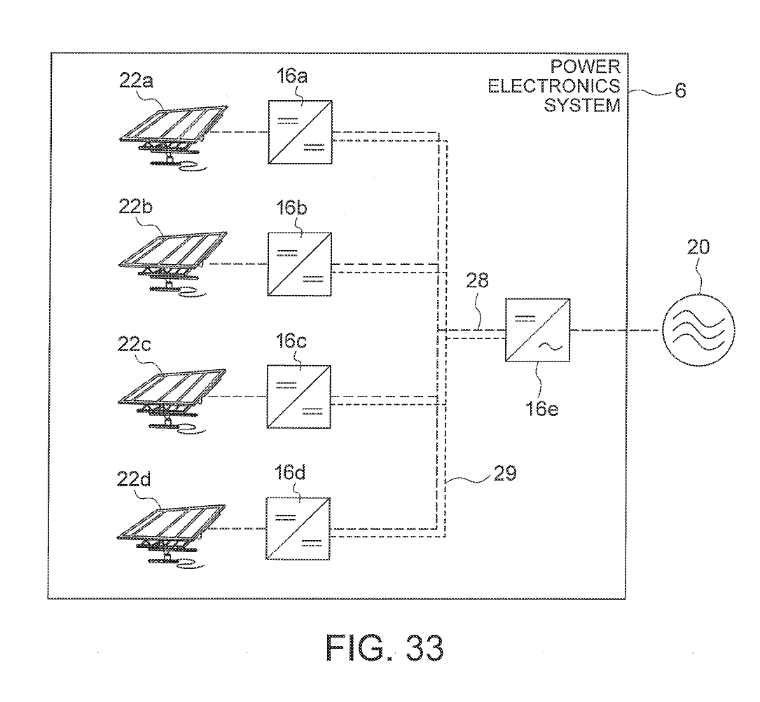

Subsequently, the configuration of a power electronics system 6 in the sixth embodiment will be described with reference to FIG. 33. FIG. 33 is a diagram showing the configuration of the power electronics system 6 in the sixth embodiment. Note that components common to those of FIG. 29 will be denoted by the same reference characters, and the specific descriptions thereof will not be described. As shown in FIG. 33, the configuration of the power electronics system 6 in the sixth embodiment is a configuration in which, as compared with the configuration of the power electronics system 4 in the fourth embodiment in FIG. 29, the power electronics devices 14a to 14e are changed to power electronics devices 16a to 16e, respectively. Hereafter, the power electronics devices 16a to 16e are collectively referred to as a power electronics device 16.

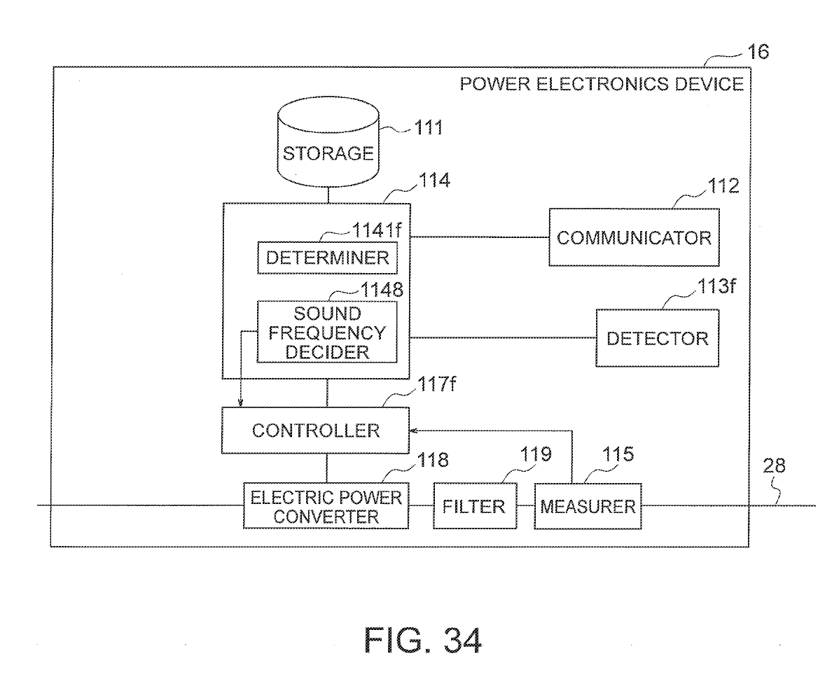

Next, the configuration of a power electronics device 16 in the sixth embodiment will be described with reference to FIG. 34. FIG. 34 is a diagram showing the configuration of the power electronics device 16 in the sixth embodiment. Note that components common to those of FIG. 30 will be denoted by the same reference characters, and the specific descriptions thereof will not be described. As shown in FIG. 34, the configuration of the power electronics device 16 in the sixth embodiment is a configuration in which, as compared with the configuration of the power electronics device 14 in the fourth embodiment in FIG. 30, the detector 113d is changed to a detector 113f, the determiner 1141d is changed to a determiner 1141f, the carrier frequency decider 1146 is eliminated, a sound frequency decider 1148 is added, and the controller 117d is changed to a controller 117f.

The detector 113f detects the sounds emitted by the other power electronics devices. The detector 113f is, for example, a sound collecting device. Then, the detector 113f outputs a detection signal obtained by the detection to the CPU 114.

The sound frequency decider 1148 determines the frequency of the sound such that the frequency does not overlap with the frequencies of the sounds emitted by the other power electronics devices. For example, when the power electronics device 16a acts as a master, the sound frequency decider 1148 of the power electronics device 16a determines the frequencies of the sounds emitted by the power electronics devices 16a to 16e such that the frequencies are different from one another.

The communicator 112 may distribute the determined frequencies to the other power electronics devices 16b to 16e through communication. Alternatively, the frequencies of the sounds may be hard coded in advance in a program stored in the storages 111 of the power electronics devices 16a to 16e. Alternatively, the frequencies of the sounds may be shared by a setting file, in which the frequencies of the sound are written, stored in advance in the storages 111 of the power electronics devices 16a to 16e.

The sound emitted by the power electronics device is desirably suppressed in terms of noise. In contrast, if the carrier frequency is beyond the human audible range, noise is hard to raise a problem, and thus the frequencies of the sounds are desirably made to be ultrasounds of 20 kHz or more. If there is no problem other than noise, the sounds of the carrier waves in an ultrasonic range can be positively used.

In addition, the sound frequency decider 1148 desirably determines the frequencies of the sounds emitted by the power electronics devices such that the frequencies do not overlap the frequencies of ambient sounds. To achieve this, the sound frequency decider 1148 desirably detects the frequencies of the ambient sounds in advance. In addition, the sound frequency decider 1148 may use a plurality of frequencies in turn as the frequency of the sounds by employing the spread spectrum. For example, the sound frequency decider 1148 may change the frequencies of the sounds with time (frequency hopping of the frequencies of the sounds). This enables enhanced immunity to the ambient sounds or interfering sounds.

The controller 117f controls an electric power to be output to the power line 28 by using the frequency of the sound determined by the sound frequency decider 1148 as its carrier frequency.

The determiner 1141f determines the states of the other power electronics devices based on the frequency components of the frequencies of the carrier waves, contained in the detection signal obtained through the detection performed by the detector 113f, which the other power electronics devices use for the power conversion. For example, the determiner 1141f determines, if the frequency component of the carrier wave that the other power electronics device uses for the power conversion is less than a threshold value, that the other power electronics device is in a stop state or an abnormal state. Here, a method of selecting, from the detected detection signal, a detection signal of the frequency of the carrier wave that the other power electronics device uses for the power conversion is common to the methods described in the above-described embodiments.

As described above, in the power electronics device 16 in the sixth embodiment, the determiner 1141f determines the states of the other power electronics devices based on the frequency components of the carrier waves, contained in the detection signal obtained through the detection performed by the detector 113f, which the other power electronics devices use for the power conversion.

In such a manner, it is possible to determine the states of the other power electronics devices using the frequency components of the carrier waves contained in the detection signal obtained through the detection performed by the detector 113f, which the other power electronics devices use for the power conversion. For this reason, it is possible to shorten a time taken to determine the states of the other power electronics devices without increasing a load to communications equipment.

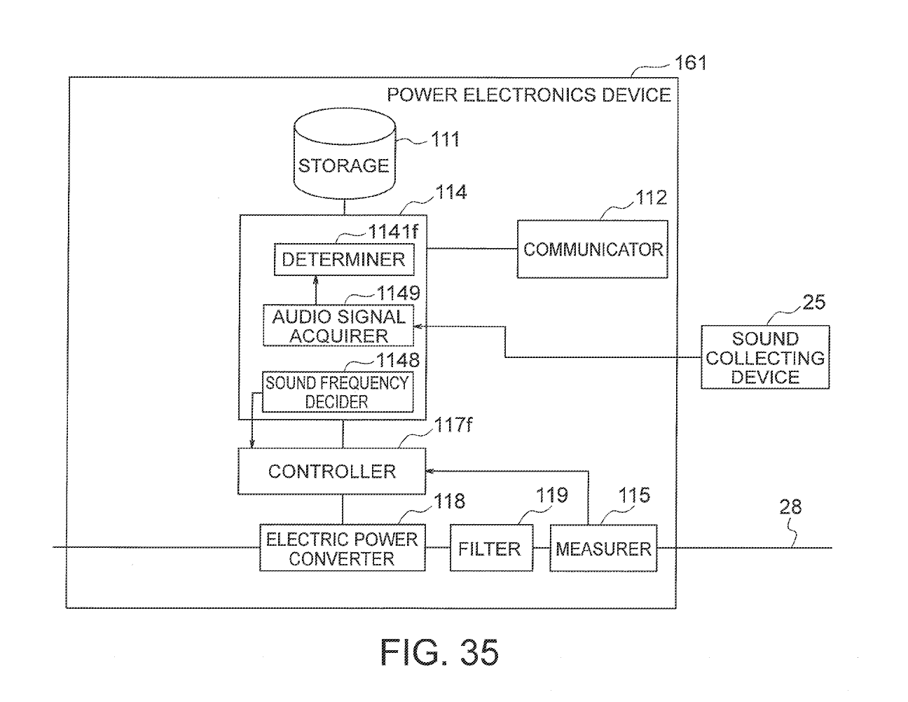

Note that, in the sixth embodiment, the power electronics device 16 includes the detector 113f, but the detector 113f may be installed outside the power electronics device 16 as a sound collecting device. Here, there will be described the configuration of a power electronics device in the case where a sound collecting device is installed outside the power electronics device 16, with reference to FIG. 35. FIG. 35 is a diagram showing the configuration of a power electronics device 161 in a modification of the sixth embodiment. Note that components common to those of FIG. 34 will be denoted by the same reference characters, and the specific descriptions thereof will not be described. As shown in FIG. 35, the configuration of the power electronics device 161 in the modification of the sixth embodiment is a configuration in which, as compared with the configuration of the power electronics device 16 in the main body of the sixth embodiment in FIG. 34, the detector 113f is eliminated, and an audio signal acquirer 1149 is added.

The audio signal acquirer 1149 acquires, from a sound collecting device 25 that detects the sounds emitted by the other power electronics devices, an audio signal obtained by collecting the sounds. Then, the determiner 1141f determines the states of the other power electronics devices based on the frequency components of the carrier waves, contained in this audio signal, which the other power electronics devices use for the power conversion.

### Seventh Embodiment

### Sound/Composite Scheme

Subsequently, a seventh embodiment will be described. A power electronics device in the seventh embodiment emits, with a plurality of power electronics devices, a sound at a common frequency f7 and monitors a composite sound at the frequency. If the magnitude of the monitored sound abruptly varies, the power electronics device determines that one of the power electronics devices emitting the sounds is stopping and performs alive check communication to request responses from the other power electronics devices, and identifies a power electronics device which returns no response as a stopping power electronics device.

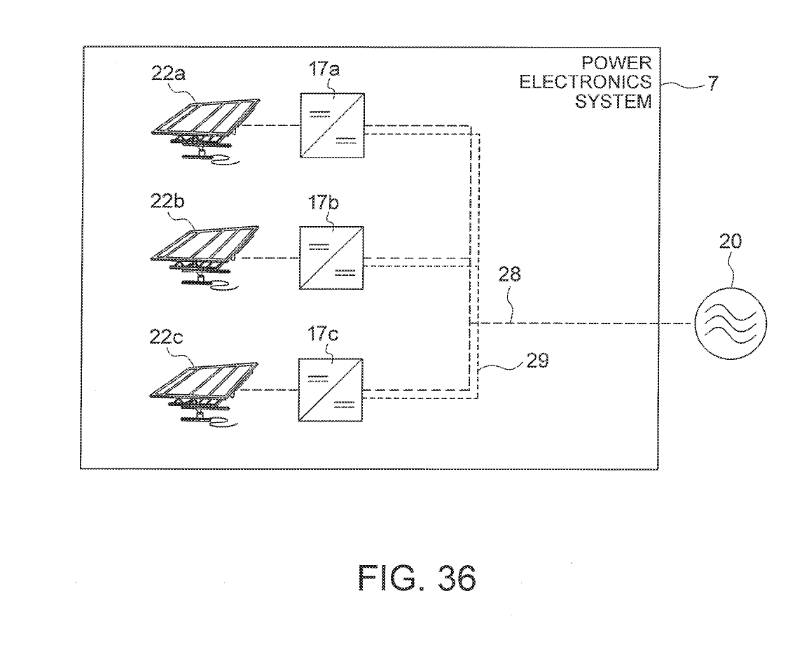

Subsequently, the configuration of a power electronics system 7 in the seventh embodiment will be described with reference to FIG. 36. FIG. 36 is a diagram showing the configuration of the power electronics system 7 in the seventh embodiment. Note that components common to those of FIG. 29 will be denoted by the same reference characters, and the specific descriptions thereof will not be described. As shown in FIG. 36, the configuration of the power electronics system 7 in the seventh embodiment is a configuration in which, as compared with the configuration of the power electronics system 4 in the fourth embodiment in FIG. 29, the generator 22d and the power electronics devices 14d and 14e are eliminated, and the power electronics devices 14a to 14c are changed to power electronics devices 17a to 17c, respectively. Hereafter, the power electronics devices 17a to 17c are collectively referred to as a power electronics device 17.

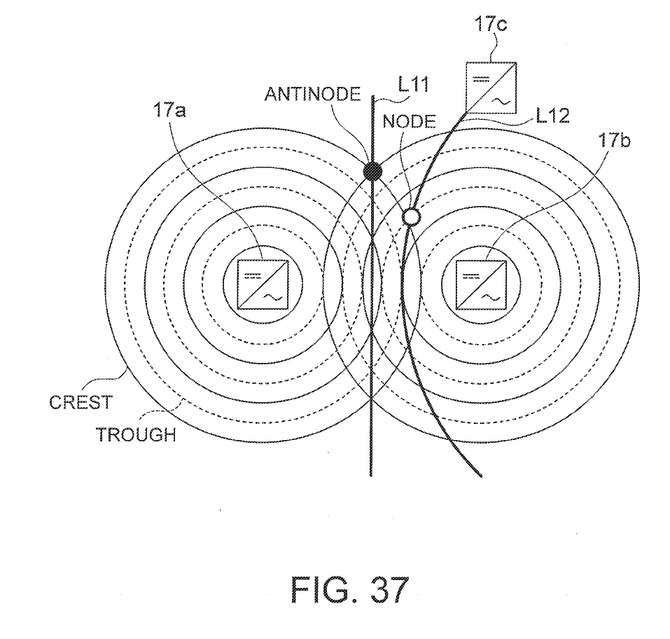

Subsequently, there will be described monitoring of a standing wave performed by the power electronics device in the present embodiment, with reference to FIG. 37. FIG. 37 is a diagram for illustrating the arrangement of the power electronics devices 17a to 17c and the composition of sounds output from the power electronics devices 17a and 17b. The power electronics devices 17a to 17c are arranged at positions shown in FIG. 37.

Here, assume the case where the power electronics devices 17a and 17b perform power conversion using carrier waves at the same frequency f7, and the power electronics device 17c monitors a composite sound emitted by these power electronics devices. At this point, both of the frequency of a first sound output from the power electronics device 17a and the frequency of a second sound output from the power electronics device 17b are the frequency f7.

The first sound output from the power electronics device 17a and the second sound output from the power electronics device 17b each concentrically spread, in a planar view as shown in FIG. 37, and as the sounds spread, crests drown by solid lines and troughs drawn by broken lines alternately appear.

In addition, there are the two sound sources emitting sounds at the same frequency f7, resulting in a standing wave by the superposition of waves. That is, there are antinodes at which the first sound and the second sound constructively interfere and nodes at which the first sound and the second sound destructively interfere. A line L11 is a line connecting the antinodes, and a curve L12 is a curve connecting the nodes. The power electronics device 17c is arranged at the position corresponding to a node of the composite sound (standing wave), as seen being arranged on the curve L12.

As shown in FIG. 37, assume the case where the power electronics device 17c is installed at a position corresponding to a node of the standing wave. When the two power electronics devices 17a and 17b properly act, the sounds emitted by the two power electronics devices 17a and 17b cancel out each other, and thus power electronics device 17c cannot detect the sound at the frequency f7.

On the other hand, when one of the power electronics device 17a and the power electronics device 17b stops, the cancellation of the sounds at the position at which the power electronics device 17c is arranged is broken, and thus the power electronics device 17c detects the sound at the frequency f7 [Hz].

In contrast, assume the case where the power electronics device 17c is installed at a position corresponding to an antinode of the standing wave. When the two power electronics devices 17a and 17b properly act, the power electronics device 17c can detect the sound at the frequency f7. On the other hand, when one of the two power electronics devices 17a and 17b stops, the magnitude of the sound detected by the power electronics device 17c is reduced in half.

In such a manner, the frequencies of the carrier waves that the power electronics device 17a and the power electronics device 17b use for the power conversion are the same. Then, the power electronics device 17c in the present embodiment is arranged at a position corresponding to a node or an antinode of the composite sound of the sound output from the power electronics device 17a and the sound output from the power electronics device 17b. Then, if the magnitude of the observable sound at the frequency f7 [Hz] abruptly varies (e.g., varying by a threshold value or more), the power electronics device 17c determines that one of the power electronics devices 17a and 17b is in a stop state or an abnormal state and perform alive check communication to identify a power electronics device being in the stop state or the abnormal state.

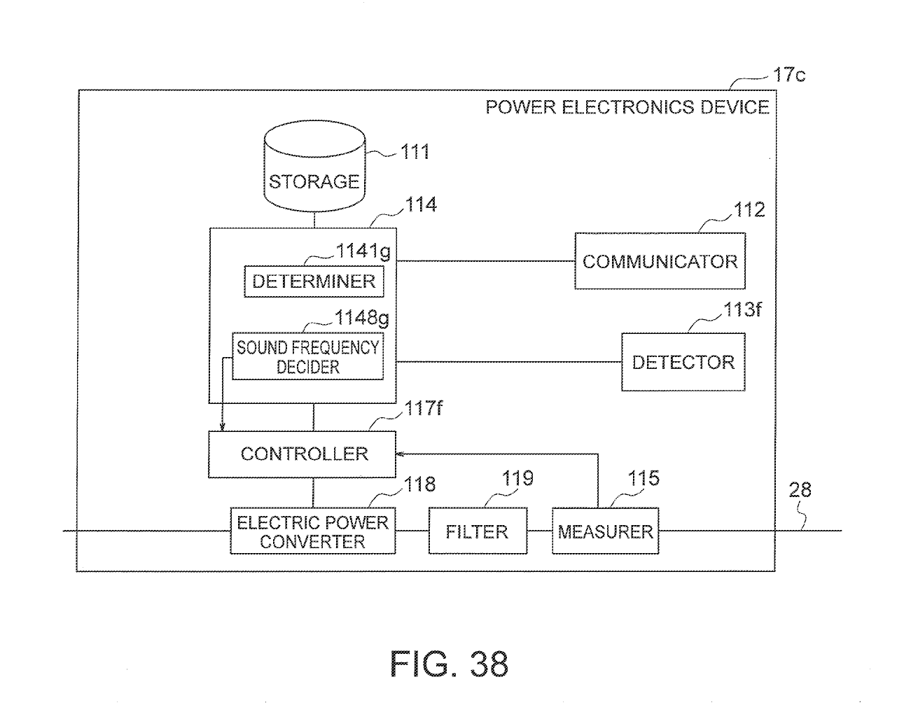

Next, the configuration of a power electronics device 17c in the seventh embodiment will be described with reference to FIG. 38. FIG. 38 is a diagram showing the configuration of the power electronics device 17c in the seventh embodiment. Note that components common to those of FIG. 34 will be denoted by the same reference characters, and the specific descriptions thereof will not be described. As shown in FIG. 38, the configuration of the power electronics device 17c in the seventh embodiment is a configuration in which, as compared with the configuration of the power electronics device 16 in the sixth embodiment in FIG. 34, the determiner 1141f is changed to a determiner 1141g, and the sound frequency decider 1148 is changed to a sound frequency decider 1148g.

The sound frequency decider 1148g determines the common frequency f7 as the frequencies of the carrier waves that the power electronics devices 17a and 17b use for the power conversion. In addition, the sound frequency decider 1148g determines a frequency f8 different from the frequency f7 as the frequency of the carrier wave that power electronics device 17c uses for the power conversion. Then, the sound frequency decider 1148g passes information indicating the frequency f8 to the controller 117f. This causes the controller 117f to control an electric power to be output to the power line 28 using the carrier wave at this frequency f8.

The communicator 112 may distribute the determined frequency f7 to the other power electronics devices 17a and 17b through communication. Alternatively, the frequency f7 of the sounds may be hard coded in advance in a program stored in the storages 111 of the power electronics devices 17a and 17b. Alternatively, the frequency of the sound may be shared by a setting file, in which the frequency f7 of the sound is written, stored in advance in the storages 111 of the power electronics devices 17a and 17b.

The determiner 1141g determines the state of at least one of the power electronics device 17a and the power electronics device 17b based on the frequency component of the carrier waves, contained in the detection signal obtained through the detection performed by the detector 113f, which the power electronics device 17a and the power electronics device 17b use for the power conversion. For example, it is determined that at least one of the power electronics device 17a and the power electronics device 17b is in a stop state or an abnormal state if the amount of change in the frequency component of the carrier waves per unit time, which the power electronics device 17a and the power electronics device 17b use for the power conversion, exceeds a threshold value.

Then, the determiner 1141g transmits a request signal to request a response to the power electronics device 17a and the power electronics device 17b and identifies a power electronics device from which no response is received as a stopping power electronics device.

As described above, in the seventh embodiment, the other power electronics device includes the first power electronics device and the second power electronics device that uses the carrier wave, for the power conversion, the frequency of which being the same as that of the first power electronics device. The detector 113f of the power electronics device 17c detects, from the surrounding space of the power electronics device, the sound at the frequency of the carrier waves that the first power electronics device and the second power electronics device use for the power conversion when being installed at a position corresponding to a node or an antinode of the composite sound of the sound output from the first power electronics device and the sound output from the second power electronics device. Then, the determiner 1141g of the power electronics device 17c determines the state of at least one of the first power electronics device and the second power electronics device based on the frequency component of the carrier waves, contained in the detection signal, which the first power electronics device and the second power electronics device use for the power conversion.

In such a manner, the power electronics device 17c can determine the state of the first power electronics device or the second power electronics device from the sound at the frequency of the carrier waves that the first power electronics device and the second power electronics device use for the power conversion. For this reason, it is possible to shorten a time taken to determine the states of the other power electronics devices without increasing a load to communications equipment.

Note that, if the detector 113f of the power electronics device 17c is positioned at neither a node nor an antinode of the standing wave, the measurable volume of the sound may not vary even if the power electronics device 17a or the power electronics device 17b stops. To deal with such a case, a plurality of detectors 113f may be provided.

Alternatively, an optimum frequency may be sought by adjusting a carrier frequency and/or a carrier phase used for the power conversion. For example, consider the case of using a carrier wave at 3.0 kHz. Since the wavelength of the sound at this carrier wave is about 110 cm in a normal environment, the shortest interval between a node and an antinode of the standing wave formed by the power electronics device 17a and the power electronics device 17b is a quarter of the wavelength, that is, about 27 cm.

Therefore, in the case of using the carrier wave at 3.0 kHz and a plurality of detectors 113f, it is undesirable to arrange the detectors 113f at intervals that is extremely longer or shorter than 27 cm. In addition, since the positions of the antinodes and the nodes of the standing wave change according to the fluctuations of the frequencies or the phases, a standing wave optimal for the power electronics device 17c may be sought through cooperative control by the power electronics device 17a and the power electronics device 17b.

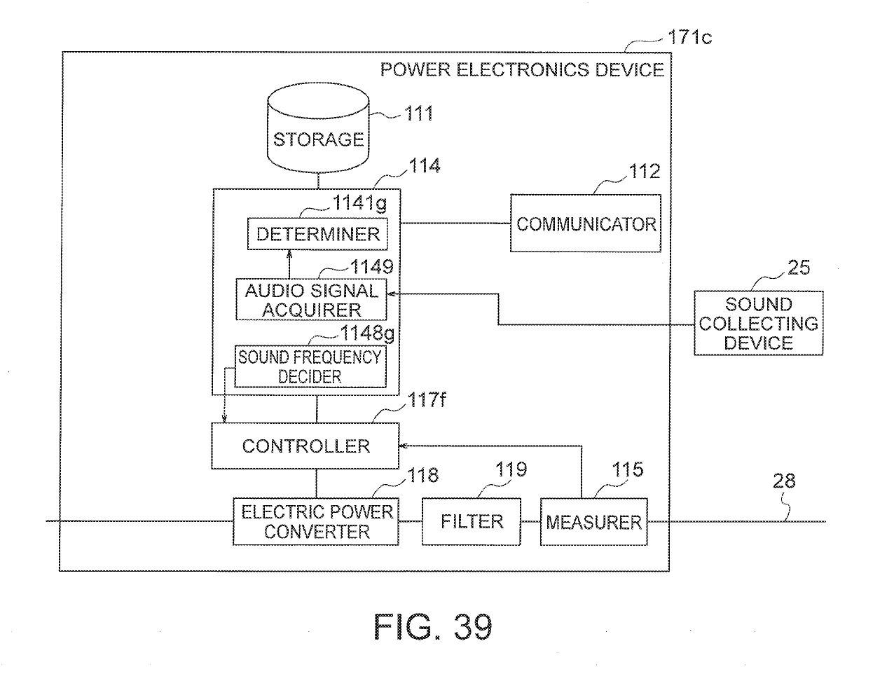

Note that, in the seventh embodiment, the power electronics device 17c includes the detector 113f, but the detector 113f may be installed outside the power electronics device 17c, as a sound collecting device. Here, there will be described the configuration of a power electronics device in the case where a sound collecting device is installed outside the power electronics device 16 with reference to FIG. 39. FIG. 39 is a diagram showing the configuration of a power electronics device 171c in a modification of the seventh embodiment. Note that components common to those of FIG. 38 will be denoted by the same reference characters, and the specific descriptions thereof will not be described. As shown in FIG. 39, the configuration of the power electronics device 171c in the modification of the seventh embodiment is a configuration in which, as compared with the configuration of the power electronics device 17c in the main body of the seventh embodiment in FIG. 38, the detector 113f is eliminated, and an audio signal acquirer 1149 is added.

The audio signal acquirer 1149 acquires, from the sound collecting device 25 that detects the sounds emitted by the other power electronics devices, an audio signal obtained by collecting the sounds. Then, the determiner 1141g determines the state of at least one of the first power electronics device and the second power electronics device based on the frequency components of the carrier waves, contained in this audio signal, which the first power electronics device and the second power electronics device use for the power conversion.

### Eighth Embodiment

### Carrier Electromagnetic Noise/Frequency Assignment Scheme

Subsequently, an eighth embodiment will be described. A power electronics device in the eighth embodiment associates, when performing cooperative action with a plurality of power electronics devices, the frequencies of carrier waves used for power conversion with pieces of device identifying information to identify a power electronics device. Since the power electronics device emits the electromagnetic wave having a carrier frequency component into the space, it is detected whether a power electronics device to which the carrier frequency is assigned is in a stop state or an abnormal state, by monitoring the intensity of the electromagnetic wave having the carrier frequency component among electromagnetic waves observable in the space.

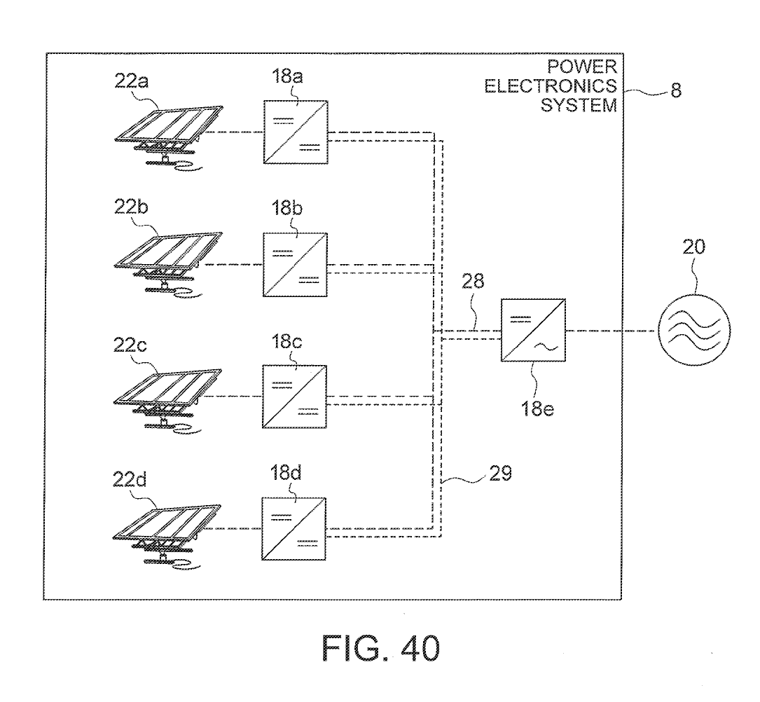

Subsequently, the configuration of a power electronics system 8 in the eighth embodiment will be described with reference to FIG. 40. FIG. 40 is a diagram showing the configuration of the power electronics system 8 in the eighth embodiment. Note that components common to those of FIG. 29 will be denoted by the same reference characters, and the specific descriptions thereof will not be described. As shown in FIG. 40, the configuration of the power electronics system 8 in the eighth embodiment is a configuration in which, as compared with the configuration of the power electronics system 4 in the fourth embodiment in FIG. 29, the power electronics devices 14a to 14e are changed to power electronics devices 18a to 18e, respectively. Hereafter, the power electronics devices 18a to 18e are collectively referred to as a power electronics device 18.

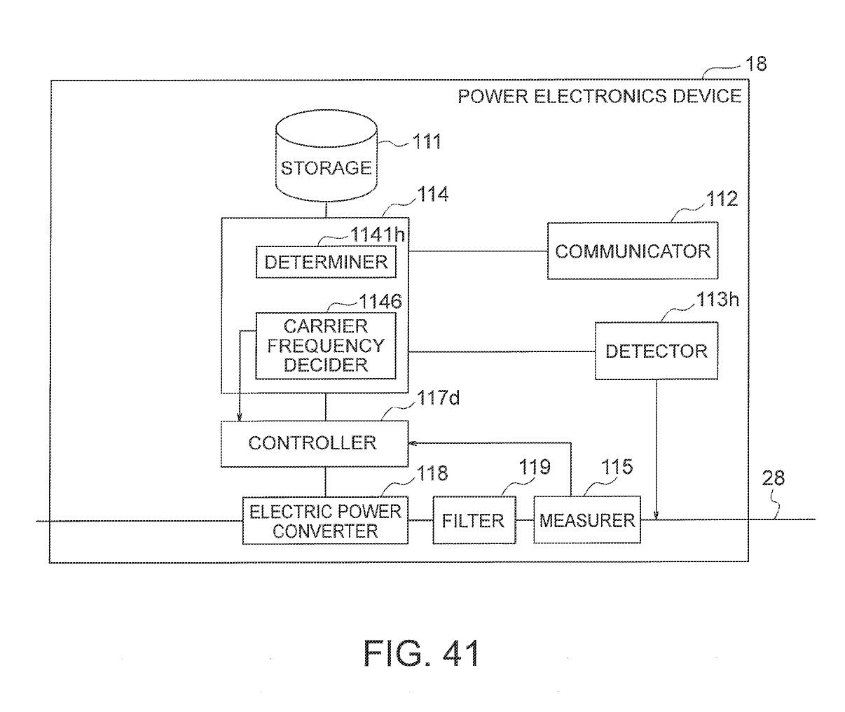

Next, the configuration of a power electronics device 18 in the eighth embodiment will be described with reference to FIG. 41. FIG. 41 is a diagram showing the configuration of the power electronics device 18 in the eighth embodiment. Note that components common to those of FIG. 30 will be denoted by the same reference characters, and the specific descriptions thereof will not be described. As shown in FIG. 41, the configuration of the power electronics device 18 in the eighth embodiment is a configuration in which, as compared with the configuration of the power electronics device 14 in the fourth embodiment in FIG. 30, the detector 113d is changed to a detector 113h, and the determiner 1141d is changed to a determiner 1141h.

The detector 113h detects electromagnetic waves around the power electronics device. The detector 113h includes, for example, an antenna to detect the electromagnetic waves.

The determiner 1141h determines the states of the other power electronics devices based on the frequency components of the carrier waves, contained in the detection signal obtained through the detection performed by the detector 113h, which the other power electronics devices use for the power conversion. For example, the frequency component of the carrier wave that the other power electronics device uses for the power conversion is less than a threshold value, the determiner 1141h determines that the other power electronics device is in a stop state or an abnormal state.

### (Choice and Assignment of Frequencies)

A method of the choice and assignment of the carrier frequencies is subject to the method in the fourth embodiment. In general, electromagnetic waves emitted from a power electronics device are desirably suppressed in terms of electromagnetic noise but it is difficult to completely suppress them. In addition, a method of selecting a specified frequency from collected electromagnetic waves is common to the method described in the fourth embodiment. The carrier frequency decider 1146 desirably determines the carrier frequencies such that the carrier frequencies do not overlap the frequencies of electromagnetic waves originally existing in the surroundings.

Note that the carrier frequency decider 1146 may detect electromagnetic waves in advance by carrier sense and determine a frequency different from the frequencies of the detected electromagnetic waves as the carrier frequency. In addition, the carrier frequency decider 1146 may use a plurality of frequencies in turn as the carrier frequency by employing frequency spreading (spread spectrum). For example, the carrier frequency decider 1146 may change the carrier frequency with time (frequency hopping of the carrier frequency). This enables enhanced immunity to environmental electromagnetic waves or interfering electromagnetic waves.

As described above, in the power electronics device 18 in the eighth embodiment, the detector 113h detects electromagnetic waves around the power electronics device 18. The determiner 1141h determines the states of the other power electronics devices based on the frequency components of the carrier waves, contained in the detection signal obtained through the detection performed by the detector 113h, which the other power electronics devices use for the power conversion.

In such a manner, the power electronics device 18 can determine the states of the other power electronics devices from electromagnetic waves in the surroundings. For this reason, it is possible to shorten a time taken to determine the states of the other power electronics devices without increasing a load to communications equipment.

### Ninth Embodiment

### Carrier Electromagnetic Noise/Composite Wave Scheme

Subsequently, a ninth embodiment will be described. A power electronics device in the ninth embodiment uses a carrier wave at a frequency common to a plurality of power electronics devices. In operating, the power electronics device emits an electromagnetic wave having a carrier frequency component into the space, and thus it is possible to detect that one of the plurality of other power electronics devices stops by monitoring the intensity variations of the composite wave of electromagnetic waves observable in the space. The power electronics device starts alive check communication using this detection as a trigger to identify a stopping power electronics device.

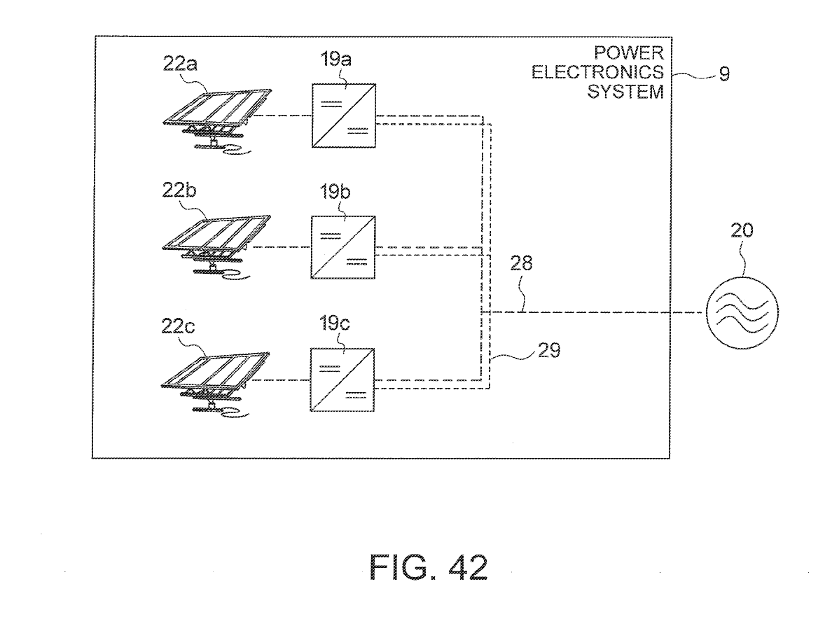

Subsequently, the configuration of a power electronics system 9 in the ninth embodiment will be described with reference to FIG. 42. FIG. 42 is a diagram showing the configuration of the power electronics system 9 in the ninth embodiment. Note that components common to those of FIG. 36 will be denoted by the same reference characters, and the specific descriptions thereof will not be described. As shown in FIG. 42, the configuration of the power electronics system 9 in the ninth embodiment is a configuration in which, as compared with the configuration of the power electronics system 7 in the seventh embodiment in FIG. 36, the power electronics devices 17a to 17c are changed to power electronics device 19a to 19c, respectively. Hereafter, the power electronics devices 19a to 19c are collectively referred to as a power electronics device 19.

Assume that the power electronics devices 19a and 19b performs the power conversion using carrier waves at the same frequency f9, and the power electronics device 19c monitors the composite wave of an electromagnetic wave output from the power electronics device 19a and an electromagnetic wave output from the power electronics device 19b. At this point, both the frequency of a first electromagnetic wave output from the power electronics device 19a and the frequency of a second electromagnetic wave output from the power electronics device 19b are the frequency f9. In such a manner, these are two emitting sources emitting electromagnetic waves at the same frequency f9, resulting in a standing wave by the superposition of waves.

For example, assume the case where the power electronics device 19c is installed at a position corresponding to a node of the standing wave. When the two power electronics devices 19a and 19b properly act, the electromagnetic waves output from the two power electronics devices 19a and 19b cancel out each other, the power electronics device 19c cannot detect the electromagnetic waves at the frequency f9.

On the other hand, when one of the power electronics device 19a and the power electronics device 19b stops, the cancellation of the electromagnetic waves at the position at which the power electronics device 19c is arranged is broken, and thus the power electronics device 19c detects the electromagnetic wave at the frequency f9 [Hz].

In contrast, assume the case where the power electronics device 19c is installed at a position corresponding to an antinode of the standing wave. When the two power electronics devices 19a and 19b properly act, the power electronics device 19c can detect the electromagnetic wave at the frequency f9. On the other hand, when one of the two power electronics devices 19a and 19b stops, the magnitude of the electromagnetic wave detected by the power electronics device 19c is reduced in half.

In such a manner, the frequencies of the carrier waves that the power electronics device (first power electronics device) 19a and the power electronics device (second power electronics device) 19b use for the power conversion are the same. Then, the power electronics device 19c in the present embodiment is arranged at a position corresponding to a node or an antinode of the composite wave of the electromagnetic wave output from the power electronics device 19a and the electromagnetic wave output from the power electronics device 19b. Then, if the magnitude of the observable electromagnetic wave at the frequency f9 [Hz] abruptly varies (e.g., varying by a threshold value or more), the power electronics device 19c determines that at least one of the power electronics devices 19a and 19b is in a stop state or an abnormal state and perform alive check communication to identify a power electronics device in the stop state or the abnormal state.

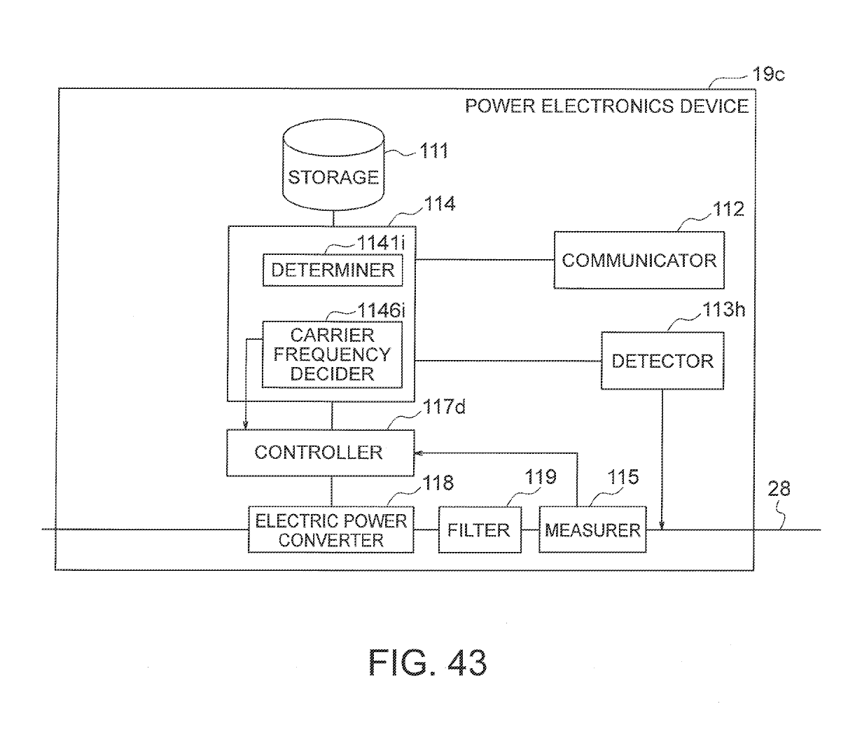

Next, the configuration of a power electronics device 19c in the ninth embodiment will be described with reference to FIG. 43. FIG. 43 is a diagram showing the configuration of the power electronics device 19c in the ninth embodiment. Note that components common to those of FIG. 41 will be denoted by the same reference characters, and the specific descriptions thereof will not be described. As shown in FIG. 43, the configuration of the power electronics device 19c in the ninth embodiment is a configuration in which, as compared with the configuration of the power electronics device 18 in the eighth embodiment in FIG. 41, the determiner 1141h is changed to a determiner 1141i, and the carrier frequency decider 1146 is changed to a carrier frequency decider 1146i.

The carrier frequency decider 1146i determines the common frequency f9 as the frequencies of the carrier waves that the power electronics devices 19a and 19b use for the power conversion. In addition, the carrier frequency decider 1146i determines a frequency f10 different from the frequency f9 as the frequency of the carrier wave that the power electronics device 19c uses for the power conversion. Then, the carrier frequency decider 1146i passes information indicating the frequency f10 to the controller 117d. This causes the controller 117d to control an electric power to be output to the power line 28 using the carrier wave at this frequency f10.

The communicator 112 may distribute the determined frequency f9 to the other power electronics devices 19a and 19b through communication. Alternatively, the frequency f9 may be hard coded in advance in a program stored in the storages 111 of power electronics devices 19a and 19b. Alternatively, the carrier frequency may be shared by a setting file, in which the frequency f9 is written, stored in advance in the storages 111 of the power electronics devices 19a and 19b.

The determiner 1141i determines the state of at least one of the first power electronics device and the second power electronics device based on the frequency components of the carrier waves, contained in the detection signal obtained through the detection performed by the detector 113h, which the power electronics device 19a and the power electronics device 19b use for the power conversion. For example, it is determined that at least one of the power electronics device 19a and the power electronics device 19b is in a stop state or an abnormal state if the amount of change in the frequency component of the carrier waves per unit time, which the power electronics device 19a and the power electronics device 19b use for the power conversion, exceeds a threshold value.

Then, the determiner 1141i transmits a request signal to request a response to the power electronics device 19a and the power electronics device 19b and identifies a power electronics device from which no response is received as a stopping power electronics device.

As described above, in the ninth embodiment, the other power electronics device includes the first power electronics device and the second power electronics device that uses the carrier wave for the power conversion, the frequency of which being the same as that of the first power electronics device. Then, the detector 113h of the power electronics device 19c detects, from the surrounding space of the power electronics device 19c, the electromagnetic wave at the frequency of the carrier waves that the first power electronics device and the second power electronics device use for the power conversion, when being installed at a position corresponding to a node or an antinode of the composite wave of the electromagnetic wave output from the first power electronics device and the electromagnetic wave output from the second power electronics device. Then, the determiner 1141i determines the state of at least one of the first power electronics device and the second power electronics device based on the frequency component of the carrier waves, contained in the detection signal obtained through the detection performed by the detector 113h, which the first power electronics device and the second power electronics device use for the power conversion.

In such a manner, the power electronics device 19c can determine the state of the first power electronics device or the second power electronics device from the electromagnetic waves in the surroundings. For this reason, it is possible to shorten a time taken to determine the state of the first power electronics device or the second power electronics device without increasing a load to communications equipment.

As described above, according to the embodiments, the detector may detect an electric power that the other power electronics device superimposes onto its output power, or an electric power, sound, or electromagnetic wave at a frequency of the carrier wave that the other power electronics device uses for the power conversion, from the power line or a space around the power electronics device.

### Application Examples

Subsequently, application examples of the embodiments will be described with reference to the drawings. As an application example of the power electronics systems, a micro grid is assumed. More specifically, small- or medium-scale power systems of such as ordinary households, stores, factories, buildings, stations, and commercial facilities are included. Units such as a block of a town or the entire town are not referred to a micro grid in general, but large-scale grid systems are included because the components of the systems are similar.

### First Application Example

### Micro Grid

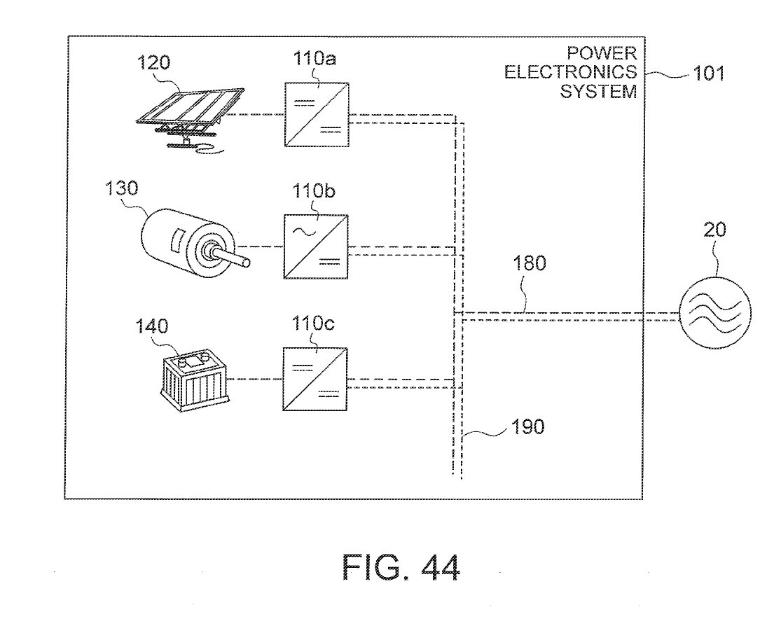

First, a first application example will be described with reference to FIG. 44. FIG. 44 is a diagram showing a configuration example of a micro grid. A power electronics system 101 is an example of a local system. As shown in FIG. 44, the power electronics system 101 includes, as an example, a generator 120, a load 130, an energy storage device 140, power electronics devices 110a and 110c and a power line 180 connecting them, an information communication line 190, and the like as basic components. In FIG. 44, as an example, the power electronics system 101 further includes three power electronics devices 110a and 110c.

Note that, the power electronics system 101 may include, in addition to them, a various sensors 150 (not shown), an EMS server 170 (not shown), and the other devices relating to electric power. Each component has a communicating function, enabling advanced control as the entire system or cooperation with an external system.

The power electronics system 101 is connected to an electric power system 20 by the power line 180 and can receive electric power from the electric power system 20. In addition the power electronics system 101 can perform power transmission to the electric power system 20 (reverse power flow) if surplus power occurs in the power electronics system 101. The power electronics system 101 can consume an electric power created inside the power electronics system 101 and an electric power supplied from the electric power system 20, at the same time. In addition, the power electronics system 101 may have another local system as an internal element or an adjacent element, which may be independent of the electric power system 20. In addition, the local system may be interconnected to a single or a plurality of electric power systems by two or more routes.

In addition to the power electronics device in the above-described embodiments, a wattmeter, and a controller, there may be a power electronics device to which the embodiments are not applied or a load having insufficient controllability from the controller because of not having the communicating function, which coexist as the components of the power electronics system 101, but the benefit of each embodiment can be brought even in such a case.

In addition, in a smart grid or a micro grid, integral control or management may be conducted including not only electric power but also gas and/or water supply, and moreover heat or energy in general, air-conditioning equipment, and the like can be included as control objects.

### Second Application Example

### Dispersed Power Supply Plant

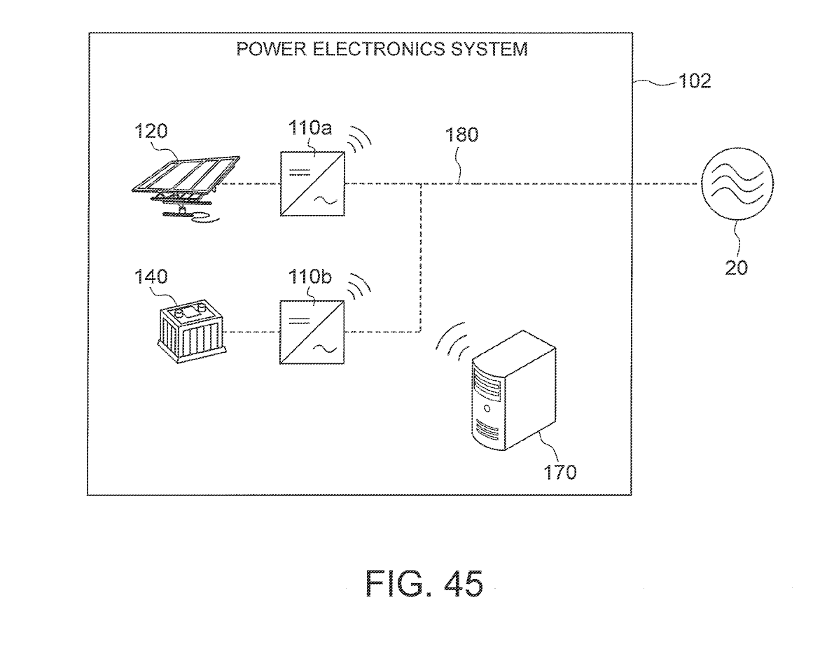

Subsequently, a second application example will be described with reference to FIG. 45. The second application example provides an application to power electronics system including a plurality of system interconnected inverters operating. FIG. 45 is a diagram showing a configuration example of a dispersed power supply plant. As shown in FIG. 45, the power electronics system 102 includes power electronics devices 110a and 110b, a generator 120, an energy storage device 140, and an EMS server 170. The generator 120 and the energy storage device 140 are connected to the electric power system 20 via the power electronics devices 110a and 110b, respectively. Note that, various generators ranging from small-scale one to large-scale one can be applied to the generator 120. The EMS server 170 can wirelessly communicate with power electronics devices 110a and 110b, controlling the power electronics devices 110a and 110b.

Between the power electronics device 110a and the electric power system 20, no particular load or the like is installed but a load or the other device may be connected therein in parallel or in series. In addition, a sensor (not shown) such as a wattmeter is used. The local system is managed by a small- to large-scale EMS, an electric power company, the other aggregator, or the like.

The system interconnected inverters are inverters that supply AC power outputs to the system. The system interconnected inverters are installed and used, in particular, in a mega solar power plant, a small- or middle-scale power plant, an energy storage facility, or the like, as well as a wide variety of places including facilities such as households, buildings, and factories, or a micro grid. Use voltages are as diverse as a single-phase 100 V, a three-phase 200 V, and the like, and include a DC-voltage system. In addition, the power electronics system 102 can support both power flows of a forward power flow and a reverse power flow. In such a system, various devices can has a communicating function, exchanging various kinds of data such as power data through communication.

### Third Application Example

### Railway, Elevator, FA, Motor Driving System

Subsequently, a third application example will be described. The power electronics device in each embodiment may be also applied to a railway vehicle, an elevator, a system of FA (Factory Automation), a motor driving system, and the like. In such a system, a plurality of inverters, motor, sensors, and the like are used in an autonomous cooperative manner through communication or under control of a controller. One railway vehicle or a set of railway vehicles is also a kind of local system, and this local system (power electronics system) is connected to an electric power system via a pantograph. A vehicle includes a load and power electronics device such as air-conditioning equipment running with a motor, a load and power electronics device as a motor for driving wheels, as well as a load such as an illumination. These loads are managed by a controller having a function similar to that of the above-described EMS server.

A railway vehicle often uses a regeneration brakes, and a load acts as an electric power generator in regeneration. This regenerated energy is originally electrical energy that is obtained from the electric power system and converted into the kinetic energy of a vehicle chassis, and thus it is possible to consider that the vehicle itself is an energy storage device and the load of a wheel driving motor is a power electronics device. A device such as an elevator or an escalator has a relationship between a stationary device and a movable device different from that of a railway vehicle but can be considered to be, in terms of power electronics system, a local system formed by a load, an energy storage device, a generator, and a power electronics device, as well as a sensor, a controller, and the like, as with the railway vehicle.

Note that the above-described various processing relating to the CPU and/or controller of the power electronics device in each embodiment may be performed by recording a program to perform each processing of the CPU and/or controller of the power electronics device in each embodiment in a computer-readable recording medium, and causing a computer system to read the program recorded in the recording medium and causing a processor to execute the program.

The terms used in each embodiment should be interpreted broadly. For example, the term “processor” may encompass a general purpose processor, a central processor (CPU), a microprocessor, a digital signal processor (DSP), a controller, a microcontroller, a state machine, and so on. According to circumstances, a “processor” may refer to an application specific integrated circuit (ASIC), a field programmable gate array (FPGA), and a programmable logic device (PLD), etc. The term “processor” may refer to a combination of processing devices such as a plurality of microprocessors, a combination of a DSP and a microprocessor, one or more microprocessors in conjunction with a DSP core.

As another example, the term “storage”, which is used by “storage 111” etc. in the embodiments, may encompass any electronic component which can store electronic information. The “storage” may refer to various types of media such as random access memory (RAM), read-only memory (ROM), programmable read-only memory (PROM), erasable programmable read only memory (EPROM), electrically erasable PROM (EEPROM), non-volatile random access memory (NVRAM), flash memory, magnetic such as an HDD, an optical disc or SSD.

It can be said that the storage electronically communicates with a processor if the processor read and/or write information for the storage. The storage may be integrated to a processor and also in this case, it can be said that the storage electronically communication with the processor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A power electronics device having an output connected to an output of a different power electronics device by a power line, comprising:
a detector to detect, from the power line or a space around the power electronics device,
an electric power that the different power electronics device superimposes onto an output power, or
at least one of an electric power, a sound, and an electromagnetic wave, each having a frequency of a carrier wave that the different power electronics device uses for power conversion; and
processing circuitry to determine a state of the different power electronics device based on a detection signal obtained through detection performed by the detector.

2. The power electronics device according to claim 1, wherein
the detector detects the electric power that the different power electronics device superimposes onto the output power, from the power line, and
a frequency of the electric power that the different power electronics device superimposes onto the output power is different from a fundamental frequency of the output power from the different power electronics device.

3. The power electronics device according to claim 2, wherein the frequency of the electric power that the different power electronics device superimposes onto the output power is further different from a frequency being an integral multiple of the fundamental frequency of the output power from the different power electronics device.

4. The power electronics device according to claim 2, further comprising
a controller to perform control so as to superimpose an electric power having a second frequency different from a first frequency onto an output power of the power electronics device, the first frequency being the frequency of the electric power that the different power electronics device superimposes onto the output power, wherein
the processing circuitry determines the state of the different power electronics device based on a component of the first frequency in the detection signal.

5. The power electronics device according to claim 2, wherein
an output of the power electronics device is connected to one or more of the different power electronics devices by the power line, further comprising
a controller to controls a first electric power to be superimposed onto an output power of the power electronics device such that second electric powers that the different power electronics devices superimpose onto output powers thereof and the first electric power cancel out partially or totally, the second electric powers being having same frequency as that of the first electric power, wherein
the processing circuitry determines a state of at least one of the plurality of other power electronics devices based on a component of the frequency of the one or more second electric powers in the detection signal.

6. The power electronics device according to claim 5, wherein the controller performs feedback control such that a component of the frequency of the electric powers which the one or more other power electronics devices superimpose onto the output powers becomes a target value, the component being contained in the detection signal.

7. The power electronics device according to claim 2, further wherein
the processing circuitry assigns phases of superimposed powers having a first frequency, that the power electronics device and a plurality of other power electronics devices superimpose onto output powers thereof, to the power electronics device and the plurality of other power electronics devices, and when the superimposed powers output from a part of plurality of power electronics devices among the power electronics device and the plurality of other power electronics devices cancel out one another as a result of assigning the phases of the superimposed powers, assigns phases of the superimposed powers having a second frequency different from the first frequency to the power electronics device and the plurality of other power electronics devices such that the superimposed powers output from these power electronics devices do not cancel out one another, wherein
the controller performs control so as to superimpose a superimposed power having the first frequency and having the phase that the processing circuitry assigns to the power electronics device at the first frequency onto an output power of the power electronics device, and performs control so as to superimpose a superimposed power having the second frequency and having the phase that the processing circuitry assigns to the power electronics device at the second frequency onto the output power of the power electronics device.

8. The power electronics device according to claim 2, further comprising
a controller that performs control so as to superimpose a second electric power onto an output power of the power electronics device during a second period that is different from a first period during which the different power electronics device superimposes a first electric power onto the output power, wherein
the processing circuitry determines the state of the different power electronics device based on a component of a frequency of the first electric power contained in the detection signal during the first period.

9. The power electronics device according to claim 8, wherein the frequency of the first electric power superimposed during the first period and a frequency of the second electric power superimposed during the second period are same.

10. The power electronics device according to claim 2, wherein
the different power electronics device changes the frequency of the electric power to be superimposed onto the output power with time according to a prescribed changing schedule, and
the processing circuitry changes a frequency to be monitored according to the changing schedule and determines the state of the different power electronics device based on a component of the frequency to be monitored contained in the detection signal.

11. The power electronics device according to claim 10, further comprising
a controller that performs control so as to superimpose a second electric power onto an electric power to be output to the power line, the second electric power having a frequency that is changed with time and does not overlap a frequency of a first electric power superimposed by the different power electronics device during same period.

12. The power electronics device according to claim 2, further comprising
a controller to perform control so as to superimpose an electric power having a phase different by 180 degrees from a phase of a first electric power, which is superimposed by a first power electronics device, onto an output power of the power electronics device during a first period and performs control so as to superimpose an electric power having a phase different by 180 degrees from a phase of a second electric power, which is superimposed by second power electronics device, onto the output power of the power electronics device during a second period different from the first period, wherein
the processing circuitry determines a state of the first power electronics device based on a component of a frequency of the first electric power contained in the detection signal during the first period and determines a state of the second power electronics device based on a component of a frequency of the second electric power contained in the detection signal during the second period.

13. The power electronics device according to claim 1,
wherein the different power electronics device uses a carrier wave having a first frequency for power conversion,
the power electronics device further comprising
a controller to control an output power of the power electronics device using a carrier wave having a second frequency different from the first frequency, wherein
the detector detects an electric power having the first frequency of the carrier wave that the different power electronics device uses for power conversion, and
the processing circuitry determines the state of the different power electronics device based on a component of the first frequency contained in the detection signal.

14. The power electronics device according to claim 1, wherein
an output thereof is connected to one or more of the different power electronics devices by a power line, and
first carrier waves that the different power electronics devices use for power conversion and a second carrier wave that the power electronics device uses for power conversion have same frequency,
the power electronics device further comprising a controller to control an output power of the power electronics device using the second carrier wave such that electromagnetic noises derived from the first carrier waves and an electromagnetic noise derived from the second carrier wave cancel out one another partially or totally, wherein
the detector detects an electric power having the frequency of the first carrier waves that the different power electronics devices use for power conversion, and
the processing circuitry determines states of the different power electronics devices based on a component of the frequency of the first carrier waves contained in the detection signal.

15. The power electronics device according to claim 1, wherein
the detector detects a sound having a frequency of a carrier wave that the different power electronics device uses for power conversion, from a space around the power electronics device, and
the processing circuitry determines the state of the different power electronics device based on a component of the frequency of the carrier wave, contained in the detection signal, which the different power electronics device uses for power conversion.

16. The power electronics device according to claim 15, wherein
a first of the different power electronics device is a first power electronics device and a second of the different power electronics device is a second power electronics device that uses a carrier wave for power conversion, a frequency of which being the same as a frequency of the first power electronics device,
the detector detects, when being installed at a position corresponding to a node or an antinode of a composite sound of a sound output from the first power electronics device and a sound output from the second power electronics device, a sound having a frequency of carrier waves that the first power electronics device and the second power electronics device use for power conversion, from a space around the power electronics device, and
the processing circuitry determines a state of at least one of the first power electronics device and the second power electronics device based on a component of the frequency of carrier waves, contained in the detection signal, which the first power electronics device and the second power electronics device use for the power conversion.

17. The power electronics device according to claim 1, wherein
the detector detects an electromagnetic wave having a frequency of a carrier wave that the different power electronics device uses for power conversion, from a space around the power electronics device, and
the processing circuitry determines the state of the different power electronics device based on a component of the frequency of the carrier wave, contained in the detection signal, which the different power electronics devices uses for the power conversion.

18. The power electronics device according to claim 17, wherein
a first of the different power electronics device is a first power electronics device, and a second of the different power electronics device is a second power electronics device that uses a carrier wave for power conversion, having same frequency as the first power electronics device,
the detector detects, when being installed at a position corresponding to a node or an antinode of a composite wave of an electromagnetic wave output from the first power electronics device and an electromagnetic wave output from the second power electronics device, an electromagnetic wave having the frequency of the carrier waves that the first power electronics device and the second power electronics device use for power conversion, from a space around the power electronics device, and
the processing circuitry determines a state of at least one of the first power electronics device and the second power electronics device based on a component of the frequency of the carrier waves, contained in the detection signal, which the first power electronics device and the second power electronics device use for the power conversion.

19. A power electronics device having an output connected to an output of a different power electronics device by a power line, comprising:
an audio signal acquirer to acquire, from a sound collecting device that detects a sound having a frequency of a carrier wave that the different power electronics device uses for power conversion, an audio signal obtained through detection; and
a processing circuitry to determine a state of the different power electronics device based on a component of the frequency of the carrier wave, contained in the audio signal, which the different power electronics device uses for power conversion.
